(19) United States
(12) Patent Application Publication
(10) Pub. No.: US 2021/0287451 A1
(43) Pub. Date: Sep. 16, 2021

(54) SYSTEM AND METHOD FOR HANDLING ASSETS FOR FABRICATION

(71) Applicant: Patrick M Baudisch, Berlin (DE)

(72) Inventor: Patrick M Baudisch, Berlin (DE)

(21) Appl. No.: 16/319,230

(22) PCT Filed: Jul. 18, 2017
(86) PCT No.: PCT/US2017/042686

§ 371 Date: Jan. 18, 2019

(51) Int. Cl. G06T 19/20

(52) U.S. Cl. CPC G06T 19/20; G06T 2219/2016; G06T 2219/2004; G06T 2219/2008

(57) ABSTRACT

The present disclosure introduces the concept of 3D editors that treat contents as a set of “assemblies” that interact with each other and the world governed by physics, such as inertia. Based on this general concept we introduce a range of tools for manipulating such assemblies. We then automate several aspects of 3D editing that might otherwise clash with the notion of an interaction based on physics, such as alignment and view management. Some embodiments of the inventive concept target specific fabrication machines. This allows these embodiments to offer smart content elements that embody useful domain knowledge, such as stability and material efficiency. This reduces user interface complexity and allows especially inexperienced users to solve common problems with ease.

### 1 RELATED APPLICATIONS

This application claims the benefit under 35 USC § 119 to U.S. provisional patent application Ser. No. 62/363,735, filed on Jul. 18, 2016, which is incorporated by reference herein in its entirety.

This application claims the benefit under 35 USC § 119 to U.S. provisional patent application Ser. No. 62/517,898, filed on Jun. 10, 2017, which is incorporated by reference herein in its entirety.

### 2 BACKGROUND

Historically, 3D editing used to require substantial up-front training. Professional tools, such as Maya (http://www.autodesk.com/products/maya), Softimage (http://www.autodesk.com/products/softimage), SolidWorks (http://www.solidworks.com) are very powerful, but also take years to master.

The first publicly recognized breakthrough in terms of learnability was probably Sketch-Up (http://www.sketchup.com). Sketch-up allows less experienced users to create and edit 3D models. More recently, TinkerCAD (http://www.sketchup.com) set new standards in learnability. The main user interface strategy behind TinkerCAD is to offer only those tools that are required for manipulating volumetric objects.

In parallel to this main evolution of 3D editors, researchers and software engineers have created 3D editors designed specifically with ease-of-use in mind, such as Teddy [Takeo Igarashi, Satoshi Matsuoka, Hidehiko Tanaka. Teddy: a sketching interface for 3D freeform design. In Proc. SIGGRAPH 1999] and follow-up projects (e.g., Plushy paper [Yuki Mori, Takeo Igarashi. Plushie: an interactive design system for plush toys. In Proc. SIGGRAPH 2007], patent [Takeo Igarashi, Yuki Mori. Three-dimensional shape conversion system, three-dimensional shape conversion method, and program for conversion of three-dimensional shape. US patent number 2009/0040224A1. Feb. 12, 2009] However, these systems fall short in the sense that the set of objects they allow users to create and edit tends to be a small subset of the models other 3D editors are capable of creating. Teddy, for example, is limited to producing rounded objects.

Yet another line of easy-to-use 3D editors is construction kit editors, such as MecaBricks (http://mecabricks.com) for the LEGO universe. Editors of this type allow arranging parts, but do not allow modifying parts of making new parts, which confines users to a universe of premeditated elements. Similarly, the level editor of various video games, such as the Unreal Editor (https://en.wikipedia.org/wiki/Unreal_Engine) or the Portal 2 Editor (https://en.wikipedia.org/wiki/Portal_2) allowed users to assemble worlds easily, but only from the elements previously designed for this particular game world. Also, all simulation tends to take place in a mode that is separate from editing, i.e., the game itself. Similarly, physical window managers, such as bumptop [Anand Agarawala, Ravin Balakrishnan. Keepin' it Real: Pushing the Desktop Metaphor with Physics, Piles and the Pen. In Proceedings of CHI 2006] and sandbox games, such as Gary's Mod (http://www.garrysmod.com) and Minecraft (https://minecraft.net) allow users to create and edit 3D objects/game worlds; they are limited to placing predefined elements though. Unlike game editors, the primary purpose of 3D editors, including the ones presented in this disclosure, is to create objects for use outside the game world. The same holds for configurators and customizers, the primary purpose of which is to define or configure goods in the physical world.

Similar to Teddy, the 3D editor FlatFab (http://www.flatfab.com) is limited to a specific type of 3D model, in particular volumetric 3D objects approximated as intersecting cross sections. FlatFab allows for efficient use, although its gesture language is hard to discover, arguably making it unsuitable for inexperienced users. Similarly, Autodesk 123DMake (http://www.123dapp.com/make) achieves ease-of-use by limiting users to spars-and-frames approximations of volumes. Sketch Chair (http://sketchchair.cc) is easy to use, but limited to making chairs.

The objective behind the present invention is to innovate in terms of ease-of-use past traditional general-purpose 3D editors, without falling into the trap of over-specialization.

### 3 SUMMARY

The present disclosure presents a family of interactive 3D Editors, i.e., software programs that allow users to create/edit 3D models, i.e., unlike for example games, the outcome of the interaction is a designed object. We consider general 3D editors, as well as programs that allow customizing products, also referred to as configurators or customizers and we refer to the whole as 3D editors. The key challenge in designing 3D editors is to make them powerful, yet also usable. Achieving one of the two objectives is easy. At one end of the resulting spectrum, general-purpose 3D editors, such as Autodesk Maya (http://www.autodesk.com/products/maya) allow creating wide ranges of geometry, but take months to learn. At the other end of the spectrum, specialized editors, such as Teddy are easy to learn, yet are also limited in terms of what they allow designing. The inventive concept innovates on 3D editing by substantially increasing ease-of-use without sacrificing expressive power. (1) The inventive concept introduces the concept of 3D editors designed as “physics sandboxes”, i.e., environments that simulate a place governed by physics, such as gravity or inertia, etc. The benefit of this approach is that it leverages users' knowledge of the physical world. (2) The inventive concept replaces aspects that would distract from the notion of a place governed by physics, such as traditional alignment techniques, manual grouping, etc. It instead proposes concepts that align well with the notion of a physical world or that eliminate the necessity for the aspects that clash with a physical world, such as automatic alignment, automatic view management. (3) The inventive concept optionally targets one or more specific target fabrication machines. This allows it to focus the interaction to the creation of contents the target fabrication machines are capable of fabricating. This allows the inventive concept to reduce user interface complexity without losing expressive power. (4) The inventive concept offers smart content elements for selected groups of the targeted fabrication machines that can embody useful domain knowledge, such as stability and material efficiency, allowing inexperienced users to solve common problems with ease.

### 4 BRIEF DESCRIPTION OF THE DRAWINGS

FIG. 1: block diagram illustrating a 3D editor system according to some embodiments

FIG. 2: Flowchart explaining the main loop that computes the visual output of a 3D editor implementing a physics sandbox

FIG. 3: Simplified version of scene graph with top layer formed by assemblies

FIG. 4: The result of joining part 2.1 and part 1.1

FIG. 5: (a) The assembly highlighted in the center may embody one coordinate system, (b) the block in the back may embody a different one. (c) Assembly in front dragged into proximity of block in the back, gaining access to that block's coordinate system.

FIG. 6: Flowchart describing the rotation and translation of assemblies dragged into the proximity of another assembly.

FIG. 7: Manual update of assembly properties, here lengths.

FIG. 8: Example of a model rendered with fabrication-specific artifacts.

FIG. 9: Flowchart describing how the proposed 3D editors compute and render fabrication-specific artifacts

FIG. 10: Work environments of different levels of realism

FIG. 11: Working area with a dedicated save area. Assemblies in this area are considered inactive until moved back to the “active” area of the working surface.

FIG. 12: Example of a tool using suggestive interfaces: a split tool (here labeled “cut tool”)

FIG. 13: Flowchart determining which interpretations of the application of the current tool to display in the main view and optional secondary views.

FIG. 14: Gravity and Elasticity

FIG. 15: Mechanism that can be pulled out

FIG. 16: Hinges for different fabrication technologies

FIG. 17: Assemblies containing compliant strips of living hinges.

FIG. 18: Sheet of material that can be deformed in two dimensions

FIG. 19: Selected tools that allow users to make assemblies compliant.

FIG. 20: Selected tools that allow users to make assemblies compliant.

FIG. 21: Some embodiments may offer (a) tool that allows applying force, (b) torque and/or (c) tools and assemblies that result in forces or torque, such as a (virtual) clamp.

FIG. 22: (a) Some embodiments embody a wind simulation and/or (b) water/buoyancy simulation.

FIG. 23: Picking up an assembly in a way tilting/rolling the assembly. This, for example, allows users to view or access the under side of an object.

FIG. 24: Flowchart describing how to tilt and roll an object by picking it up

FIG. 25: Rotating an assembly in terms of yaw for dragging it. This, for example, allows users to view or access the backside of an object.

FIG. 26: Flowchart describing algorithm that determines an assembly's yaw orientation when dragged

FIG. 27: Example workflow that results in user or system zooming the view

FIG. 28: Flowchart describing automatic zooming of stage.

FIG. 29: (a) Scene with objects located completely inside, (b) partially off-screen

FIG. 30: The example illustrates the use of afterglow effects in the editor in order to achieve fast transitions.

FIG. 31: Flowchart of rendering a 3D editor that embodies the realistic effects described above

FIG. 32: Examples of situations that require alignment in 3D

FIG. 33: The proposed non-modal alignment technique space curvature

FIG. 34: Flow chart explaining the algorithm behind space curvature on a single dimension of input, such as translation.

FIG. 35: Space curvature for 1 DoF rotation

FIG. 36: Space curvature for 2D translation

FIG. 37: Visualizing non-alignment assures that users will not think of objects being aligned:

FIG. 38: Non-alignment in a confined contraption

FIG. 39: Non-alignment with a hinge. (a) As the user adds a joint to two non-aligned blocks, (b) all axes but one rotary (tilt) axis are now constrained. The top block responds by wiggling around this axis, until (c) it comes to rest at a rotary offset.

FIG. 40: (a) Offsets should be small, so as not to produce large geometric effects, which could confuse users. However, (b) when objects are scaled down (or when shown in a smaller view, such as in a suggestive interface), their offsets may become larger, so as to remain visible. One way of determining the size of offsets is thus as a function of scale.

FIG. 41: One way to implement non-alignment is using algorithms similar to alignment, but with repulsive, instead of attractive forces.

FIG. 42: Flowchart for algorithm for non-alignment and wiggling

FIG. 43: (a) push/pull tool that scales an assembly along one dimension, (b) a push/pull tool applied to an individual part, and (c) a scale tool that scales on assembly along two or three dimensions.

FIG. 44: (a-g) Bottom-up compounds allow handling this assembly as if it (already) was a box; (d,e,g) disambiguation using suggestive interfaces

FIG. 45: Bottom-up compounds flow chart

FIG. 46: To calibrate, fabricate test strip, then enter which hole fit the pin into the dialog. This information allows to compensate for kerf, so that subsequently fabricated models will fit perfectly.

FIG. 47: Import, Edit, Export, Assembly, Review-Cycle.

FIG. 48: Hierarchy of representations for 3D models for cutting machines

FIG. 49: Convert machine-specific cutting path to 2D Line Drawing

FIG. 50: Spatial relationships between segments

FIG. 51: Flowchart classification of part vs. scrap

FIG. 52: Table design optimized using shared contours

FIG. 53; guestimation algorithm for material thickness

FIG. 54: flowchart identifying half joints

FIG. 55; flowchart matching half-joints

FIG. 56: joint graph data structure after joint matching

FIG. 57: Flowchart for collapsing redundancy

FIG. 58; flowchart assembling joints

FIG. 59: Displaying the imported cutting path and classification to the user

FIG. 60: A partially assembled model with a stack of identical parts and one pair of parts already assembled

FIG. 61: Showing half-joints to connect to.

FIG. 62: tools that allow users to tweak the assembly

FIG. 63: Offering refinement functionality by (a) verb-noun order in the form of a flip brush, (b) noun-verb order in the form of selection and flipping function, (c) context menu

FIG. 64: Export of 3D object to 2D fabrication

FIG. 65: Joint-based labeling of parts.

FIG. 66: Part-labeling style that conveys each part's rough overall location within the assembly

FIG. 67: Part-labeling styles that makes adjacency on the cutable sheet reflect connectedness in the 3D model

FIG. 68: Removing protective film from laser cut parts with the help of a tab

FIG. 69: Functions that add selected native 2D primitives for a given targeted fabrication machine—here a 3-axis laser cutter to the scene (a) plate, (b) a plate in vertical orientation, (c) a disk, and (d) a polygon.

FIG. 70: There are many ways of producing the specialized 2D primitive. This embodiment offers a tool that allows users to create native 2D primitives by sketching them, here illustrated at the example of a rectangle, a circle, and a rectilinear polygon.

FIG. 71: Functions that add predefined 3D compounds (here for a 3-axis laser cutter) to the scene (a) box, (b) cylinder, (c) a sphere, and (d) a cone. In the shown embodiment, the icons are designed to suggest that the system has two representations each available for cylinder and cone.

FIG. 72: There are many ways of producing the specialized 3D primitive. This embodiment offers a tool for 3D compounds that allows producing different compounds by sketching their 2D projection, i.e., sketching a circle produces a cylinder, etc. Other embodiments may let users sketch object as their 3D shape.

FIG. 73: Multiple ways to implement an (approximate) sphere using a 3-axis cutting device

FIG. 74: The use of smart components at the example of a robotic prototype design task

FIG. 75: One of the most common joints created using 3-axis laser cutters and similar devices: the notch joint

FIG. 76: One of the most common joints created using 3-axis laser cutters and similar device: finger joints (a) assembled and (b) six parts with finger joints that can be assembled into (c) a box

FIG. 77: Some embodiments of joints targeting milling machines

FIG. 78: Different embodiments for 2D input devices may support different approaches to moving an object around in 3D space. (a) Moving along a close-to-diagonal axis moves the object in depth. (b) The object moves in vertical+left-right plane, but will snap to be above objects in the scene. (c) The pointer moves in the horizontal x/y place of the scene, but the object automatically moves above objects in the scene.

FIG. 79: (a) Moving an object in the plane, causes it to move in the x/y plane of the scene. Inertia causes it to rotate. (b) When getting close to another assembly the tool or system may automatically form a joint.

FIG. 80: Flowchart: Connecting assemblies at a distance

FIG. 81: Connect tool producing 90-degree angles with finger joints

FIG. 82: Connect tool producing stacks

FIG. 83: This chewing gum tool allows connecting two assemblies across a distance and at an angle.

FIG. 84: Connect tool producing free positioning in space. (a,b) Users drag an assembly (c) into another assembly, but before letting go the user pull out again. This causes the system to create a chewing gum-like connection between the two assemblies. This functionality and the functionality of the previous two figures can be offered in a single tool.

FIG. 85: A graphical user interface (GUI) used to offer three separate connect functions

FIG. 86: This approach to connecting two assemblies uses the metaphor of a glue stick.

FIG. 87: Flowchart for glue stick tool

FIG. 88: As in FIG. 87 (a) the user draws a first mark and (b) a second mark, except that the second mark is drawn onto the inside/bottom of an assembly. Some embodiments may render objects transparent before the second mark is drawn, as shown here. This approach allows stacking objects in a way so that (c) the second object can slide onto first (or the first under the second) without having to flip. This step may be animated or, as shown here, complemented by a afterglow effect that explains what happened to the user. Here the outcome is a stack. (d) The system now reinforces the new configuration. In the shown example it cuts one of more holes across the assembly and (e) fixes the assembly by inserting (tapered) sticks into the holes. (f) The sticks may be inserted until flush. Other insertion depths and other joints are possible too.

FIG. 89: Approach similar to the glue stick tool. This version, however, creates simple posts first.

FIG. 90: Selected methods for adding a connector to top and edge of an assembly. (a) Marking a spot (using some gesture that marks a spot, here a small circle gesture; could also be a tap, etc.) (b) creates a connector, (c) Marking a line, creates (d) a corresponding connector. (e) A similar gesture drawn across an edge and (f) the resulting connector.

FIG. 91: Selected methods for adding a connector if the connector is supposed to be located over a corner. (a) Marking a spot (using some gesture that marks a spot, here a small circle gesture; could also be a tap, etc.) (b) creates a connector capable of connecting this spot to a side of the assembly, such as the top surface (c) one of the sides (here the left side, but could be ay other), or (d) to any combination thereof (here all three connected sides; alternatively this could be any subset).

FIG. 92: Another selected methods for adding a connector to a corner of an assembly. (a) Again marking a corner, results in (b) a two-sided base and (c) a connection between this base and the third side.

FIG. 93: Once a connector has been added, the system may allow users to modify it.

FIG. 94: Connection between two plates made from a single sheet of material vs. same connection reinforced.

FIG. 95: (a) connection consisting of two connectors. The shown ones can be connected using a notch joint (here with a snap-fit closure). (b) Bending one or both connectors allows positioning one of the connected assemblies with respect to the other. (c) There are multiple ways to implement this connectors. Here a reinforced one. Others are possible.

FIG. 96: If the user “connects” an object resting on the ground, the system may still generate a (special type of) “connector”.

FIG. 97: Examples of a few simple mechanisms and similar design elements (a) living hinge, (b) mechanical hinge, and (c) a crease (as, for example, used when working with acrylic and a heat gut or laser cutter

FIG. 98: Selected tools for (a) splitting up one part into two, (b) subdividing a part into two joint parts, (c) taking a compound apart. As suggested by the respective figures, this can be done by performing a stroke gesture across. (d) One use of the subdivide tool is that parts of the resulting subdivided object can be manipulated separately, e.g., using a tilt tool.

FIG. 99: Selected user interactions designed to insert a living hinge into an assembly. Here the user tells the system where to place the hinge by (a, b) clicking/tapping, (c. d) drawing a stroke onto the assembly, (e, f) drawing a stroke across one or more assemblies. Many other interactions are possible, including selection and menu selection, etc. The same interactions can be used to invoke functionality for the previous examples, such as joining, splitting, sub-dividing, taking apart, adding mechanisms, etc.

FIG. 100: chess pawn and castle made from boxels

FIG. 101: Grids and boxels of different types

FIG. 102: Two cubic boxels and how they can be joined.

FIG. 103: Exporting a single boxel and an assembly consisting of two boxels

FIG. 104: Adding boxels to a scene and existing assemblies

FIG. 105: Add boxel tool flowchart

FIG. 106: scaling a boxel using a version of a push/pull tool.

FIG. 107: Deleting one of more boxels

FIG. 108: GUI dialog allowing users to configure the scope of subsequent boxel operations

FIG. 109: Using a boxel brush

FIG. 110: boxel brushes

FIG. 111: Defining a boxel brush

FIG. 112: Adding multiple boxels by entering a path

FIG. 113: Mechanical boxels components

FIG. 114: Creating a turtle-like robot that makes use of mechanical components.

FIG. 115: electronic boxels

FIG. 116: electronic boxels

FIG. 117: mirror boxels

FIG. 118: Expressing symmetry using connectors instead of boxels allows creating additional types of symmetry.

FIG. 119: An example of a kit designed to help users create walking robotic creatures

FIG. 120: Mounting boxel components into distorted boxel assemblies.

FIG. 121: Embedding a boxel

FIG. 122: Embedding a boxel into non-boxel geometry

FIG. 123: Flowchart of how to embed a boxel

FIG. 124: Extended flowchart of how to embed a boxel

FIG. 125: Making an asset

FIG. 126: Non-raster/multi-raster boxels

FIG. 127: one possible GUI widget for adjusting boxels sizes

FIG. 128: Deforming a boxel assembly using a push/pull edge tool

FIG. 129: scene graph

FIG. 130: Deforming a boxel assembly using a push/pull tool

FIG. 131: Creating a terrain using boxel tools

FIG. 132: Using rounding tools and the erode tool

FIG. 133: The bend tool allows turning rectilinear geometry into

FIG. 134: Home screen/landing page consisting of detail view (here shown on top) and overview (here shown at the bottom)

FIG. 135: Embodiment of landing page

FIG. 136: Flowchart for the integrated attract/showcase/tutorial/editor view

FIG. 137: special purpose computing machine configured with a process according to the above disclosure

### 5 DETAILED DESCRIPTION

The present invention implements a new class of 3D editors. In one aspect, the inventive concept pertains to software programs designed with ease-of-use in mind so as to address a broad range of users, including those with no prior knowledge of 3D editing. It attempts to achieve this as follows.

First, some of its embodiments attempt to improve ease-of-use by leveraging users' knowledge of the physical world. By implementing a radical “what-you-see-is-what-you-get” approach, these embodiments display, animate, and simulate objects in a realistic way during editing, including realistic rendering and realistic physics. In some embodiments, these simulations are active during editing, i.e., without a specific rendering or preview mode. The objective for physical realism is twofold. First, the present invention is designed for use by a broad audience, including inexperienced users. The only knowledge truly inexperienced users can be expected to have is knowledge about the physical worlds. Second, for some of the more specialized embodiments that target a physical fabrication machines (see below), making the editor experience resemble the experience of physically fabricating and assembling the object, intends to create excitement during editing similar to the excitement users may experience when physically fabricating and assembling the object.

Second, some of its embodiments improve ease-of-use by eliminating some of the traditional hurdles involved in 3D editing, such as alignment, grouping, and view navigation (see below).

Third, some embodiments of the present invention increase ease-of-use by limiting their functionality to specific classes of personal fabrication machines, such as devices capable of cutting sheets of physical material. Three-axis laser cutters, for example do not allow fabricating arbitrary 3D models, but only a reduced set, such as 3D models assembled from flat plates (The term 3-axis used herein refers to laser cutters the cutting head of which can be height adjusted, then moved in a 2D plane during cutting). Milling machines, as another example, may be subject to additional constraints, such as a minimum cutting curvature. Cutting devices with additional degrees of freedom will typically offer additional possibilities. 3D printers, may generally be more capable in terms of producing three-dimensional objects, yet be subject to more specific limitations, e.g., in terms of their ability to produce overhanging structures, and so on. Some embodiments exploit these limitations imposed by the respective fabrication machine with embodiments that offer appropriately reduced functionality, aimed at matching what the fabrication device is capable of creating. Note that this does not fall into the same trap as the specialized 3D editors mentioned earlier in that the limitations in terms of expressiveness are already imposed by the fabrication device; implementing the same limitations into the 3D editor does not further limit the design space, so that ease-of-use is gained without further reducing the design space.

Fourth, certain embodiments further improve ease-of-use by implementing domain knowledge about the targeted fabrication machine(s) and the physics the resulting creations are subject to, such as the know-how, how to create a box or a certain type of hinge on a particular fabrication machine, or how to implement spheres of different sizes, etc.

Limiting functionality to a fabrication machine and implementing domain knowledge are both motivated by the fact that fabrication machines have recently become available to a much broader audience of users (caused by the expiration of several of the initial patents). As a result, the potential user base of such machines now includes not only traditional users, i.e., engineers in industry and the more recent tech-enthusiastic “makers”, but also increasingly “consumers” (aka “casual makers”), i.e., users who are interested in the physical objects these personal fabrication machines allow them to make, but lack the training or enthusiasm to dive into the functioning of the machines and the software. A technique that allows users to create and/or edit 3D models for specific fabrication machines is thus desired and the present invention is aimed at addressing this need.

Fifth, certain embodiments integrate with a repository. Some embodiments further implement an attract mode, a tutorial mode, a demo mode, or any combination thereof, making them suitable for deployment as part of the home screen/landing page.

### 5.1. Terminology

The term 3D editor or editor used herein generally refers to software programs that allow users to create or edit 3D objects. However, large parts of the invention also apply to editing 2D objects, such as objects cut out of plates, 1D objects, such as sticks, beams, or bars cut to length, as well as defining the behavior of any such objects over time (sometimes referred to as “4D editing”), etc.

The term computer used herein refers to a wide range of devices with computational abilities, including, but not limited to, servers, data centers, workstations, mini and micro computers, personal computers, laptops, tablets, mobile phones, smart phones, PDA, mobile devices, computational appliances, eBook readers, wearable devices, embedded devices, micro controllers, custom electronic device, a networked system, any combination thereof, etc. Typically, a computer includes a processor, memory, and allow for input/output devices.

The term system or software or software system used herein typically means a software program or system of software programs with optional hardware elements that among other functions, allows users to create or edit models. The software may be running on a computer located with the user, a computer located elsewhere (such as a web server or a machine connected to one), etc. The software may run locally, over a network, in a web browser or similar environment, etc. (In some cases, the terms ‘system’ refers to the entire system, including the fabrication machine)

Objects that users create, edit, or otherwise manipulate using the computer use the following nomenclature: Object:=the physical object the user is trying to create. Model:=virtual representation of the object. The term object is sometimes used as a synonym of model if unambiguous. Scene:=all contents visible/editable in the current session, i.e., an in-between version of the model. Part:=smallest entity that can be edited (even though it may be possible to turn it into multiple parts, e.g., by subdividing it). Compound:=multiple parts that are connected (e.g., rigidly by joints or in a way allowing sub-assemblies to love with respect to each other, e.g., forming a mechanism) so that editing functions can potentially be applied to multiple or all of them at once. Assembly:=a part or a compound. Stage:=the view in which the scene is displayed defined by position and parameters of a virtual camera, as well as backdrop.

Those of the disclosed embodiments that refer specifically to a fabrication machine employ a process based on the notion of three “worlds”. (1). The physical world is where the object will eventually be created. Given that the object will be fabricated from one or more materials and using one or more targeted fabrication machines, these determine the nature of the resulting objects. (2). A virtual world in terms of the targeted fabrication device(s) and materials is how the software may choose to show users what they may later fabricate in a “what-you-see-is-what-you-will-get” fashion. When designing from plywood to be processed using a 3-axis laser cutter, for example, users typically see some sort of a rendition of that. (3) A virtual world in terms of abstract graphics. Some interactions allow users to interact in terms of geometries that are independent from materials and what the targeted fabrication machines is capable of producing. One example is that users may add a sphere to the scene while working with an embodiment that embodies the constraints of a machine not capable of creating spheres. The editors part of the present invention may respond in various ways, such as by rendering this assembly in the virtual world (e.g., here, a sphere), by rending a (somewhat) corresponding part in terms of the targeted fabrication device(s), or some combination thereof.

The terms personal fabrication machines or simply fabrication machines may include computer-controlled 3D printers, milling machines, laser cutters, etc. (for a more inclusive list see below). The combination of computer and fabrication machine allows users to use computers to create and edit electronically readable descriptions of what to fabricate and then send these descriptions to one or more fabrication machine, which causes the fabrication machines to physically fabricate what is specified in the descriptions. One type of such as representation is a 3D model or simply model, e.g., a description that defines the shape of one of multiple parts and in many cases also how these parts spatially relate to each other in 3D (this includes 1D and 2D objects as special cases).

The term fabrication, used herein refers to the process of creating physical objects using a fabrication machine. The term fabrication machines used herein refers to computer-controlled machines that are designed to produce physical output. Fabrication machines can be of any type, including machines that cut up or remove material from a given block or sheet of material (subtractive fabrication), machines that build up an object by adding material (additive fabrication), machines that deform a given block, sheet, or string of material (formative fabrication), e.g., vacuum forming, punch presses, certain types of industrial robots and robot arms, and hybrid machines that offer combinations of abilities of the above, such as machines that cut and fold materials (e.g., LaserOrigami [Stefanie Mueller, Bastian Kruck, and Patrick Baudisch. 2013. LaserOrigami: laser-cutting 3D objects. In Proceedings of the SIGCHI Conference on Human Factors in Computing Systems (CHI '13). ACM, New York, N.Y., USA, 2585-2592. DOI=http://dx.doi.org/10.1145/2470654.2481358]), machines that cut and weld materials (e.g., LaserStacker [Udayan Umapathi, Hsiang-Ting Chen, Stefanie Mueller, Ludwig Wall, Anna Seufert, and Patrick Baudisch. 2015. LaserStacker: Fabricating 3D Objects by Laser Cutting and Welding. In Proceedings of the 28th Annual ACM Symposium on User Interface Software & Technology (UIST '15). ACM, New York, N.Y., USA, 575-582. DOI=http://dx.doi.org/10.1145/2807442.2807512]), or any combination.

Subtractive machines include those that are primarily designed to etch, cut into, or cut through sheets of material, such as certain types of laser cutters, knife-based cutters, water jet cutters, plasma cutters, scissors, CNC milling machines etc., i.e., machines that move a cutting device primarily in a plane (2 axes, 2 degrees of freedom), optionally with the ability to lift the cutting device (3 axes, 3 degrees of freedom). The same applies to machines that instead move the workpiece or some combination thereof during the cutting process.

Subtractive machines based on the same concepts may also offer additional functionalities and degrees of freedom, such as cutting devices that cannot only be moved, but also rotated around one or multiple axes (roll, pitch, and yaw, etc.), or that rotate the workpiece around one or more axes, or any combination thereof. Devices with high degrees of freedom are included, as well as those based on robotic arms in the wider sense. Also included are hybrid machines that include any of the above functionalities. Also included are combinations of machines, such as a laser cutter or milling machine and a 3D printer (or any other combination) that may produce an object together.

Machines that produce physical output under computer control used herein may also include processes that produce a physical output without direct control of a computer. For example, the “machine” may be one or multiple humans holding one or multiple cutting devices, such as scissors, knifes, lasers, etc. and that manufacture physical objects while following instructions. The “machine” also includes combinations of such human-based devices with fabrication machines.

As used herein, “a targeted fabrication machine” includes machines that implement multiple fabrication processes, such as additive plus subtractive, etc. or combinations of machines that together provide such hybrid functionality.

While the inventive concept is generally targeted at fabricating objects, many of the disclosed system and interaction techniques also apply to scenarios where users will not end up fabricating. These concepts, e.g., non-modal alignment, non-alignment, automatic view-management, automatic grouping, apply also to 3D editors not primarily designed for fabrication, as well as other types of interactive software programs, such as simulation and games, productivity software, office software, drawing and painting programs, etc.

Some aspects of the invention at hand also apply to additive machines. These include various types of 3D printers (fused deposition modeling, laser sintering, stereolithography and resin printers, inkjet-based printers, etc.), injection molding machines, etc.

Some of the techniques disclosed in this disclosure refer to objects made from individual parts to be assembled later (e.g., hybrid compounds, etc.). These more specialized techniques apply to various application scenarios. (1) For fabrication machines that bear very few constraints on the shapes they can produce (e.g., additive manufacturing using laser sintering), these techniques can be used for cases where users choose to break down an object into parts, e.g., to parallelize fabrication, to reduce the need for support material, or so create objects larger than the print volume of the 3D fabrication machine. (2) For those types of fabrication machines are limited to producing certain types of geometries, the techniques reveal these limitations to the user, help them deal with the limitation, and get a clear sense of what to expect when they fabricate in the end. Three-axis laser cutters, for example, tend to be used to cut flat plates from sheets of material (technically such cutters tend to be able to edge and engrave as well; however, users may choose not to use that functionality for a variety of reasons, such as speed and accuracy). By showing these techniques during interactive experience, the respective technique clarifies expectations and make the interactive experience more similar to the experience with the physical parts fabricated later.

Screens or displays referred to herein explicitly or implicitly may also include any type of computer display used with any of the computing devices described above, including LCD, any type of OLED, CRTs, projection, etc., as well as any type of 3D display, such as individual screens capably of displaying alternating stereo images, or any virtual reality or augmented reality display, including headsets, projection systems, retinal displays, or any type of volumetric or holographic display technology, etc.

### 5.2. Scene and Assemblies

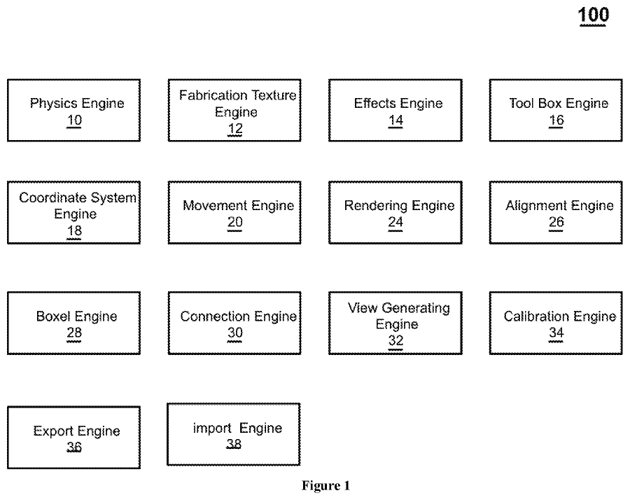

FIG. 1 is a block diagram illustrating a 3D editor system 100 according to some embodiments. 3D editor system 100 is also referred to interchangeably as “3D editor 100” or “system 100” or “editor 100.” The functions and operations of the engines of the 3D editor 100 are described for each engine. However, these functions and operations may be performed in part or in full by engines other than the engine described. A physics engine 10 performs applies physics properties, such as gravity, inertia, torque, and other forces, to one or more assemblies in the scene. The physics properties may be, for example, static, dynamic or both. A fabrication texture engine 12 performs operations to the one or more assemblies in the scene using fabrication-specific textures. An effects engine 14 generates effects, such as realistic graphics and sounds. A tool box engine 16 performs operations of various tools, such as a split tool, on the one or more assemblies in the scene. The tool box engine 16 performs operations such as compliant parts or applying forces to parts. The tool box engine 16 includes a glue stick tool, a gravity-based tilt tool, and a chewing gum tool, a gravity enabled yaw tool, a gravity/friction enabled yaw tool, an inertia/friction-based yaw tool, and a push/pull tool. Tool box engine 16 includes an add-assembly tool and a disassemble tool. The add-assembly tool may include an add cylinder tool, a round edge tool, an add hinge tool, and an add façade tool. A coordinate system engine 18 performs operations on assemblies in a global coordinate system or a coordinate system of a given assembly.

A movement engine 20 performs movement operations on assemblies, such as tilt, rotation, and drag. In some embodiments, the movement engine 20 uses the physics engine 10 to apply physics properties to the movement. A rendering engine 24 performs the processing of scenes and formatting of data for rendering and displaying the scenes. An alignment engine 26 performs operations on assemblies to align assemblies or to non-align assemblies. A boxel engine 28 performs operation on boxels. The operations include, for example, embedding a boxel into a scene. A connection engine 30 performs operations to connect assemblies together or disconnect assemblies. The connection engine 30 performs operations to snap or unsnap assemblies. In some embodiments, the connection engine 30 snaps or unsnaps assemblies in response to alignment or non-alignment operations of the alignment engine 26. A view generating engine 32 performs operations for generating detail views, zooming in, zooming out, and the like. The view generating engine 32 performs semantic zooming. The rendering engine 24 may use data generating by the view generating engine 32. A calibration engine 34 performs operations for calibrating machines, such as fabrication machines, that use data exported from the 3D editor 100. Export engine 36 exports data, for example, to a fabrication machine. An import engine 38 receives data, such as from a fabrication device.

The concepts disclosed in this section apply to generic 3D editors as well as to those 3D editors that target one or more specific fabrication machines.

First, to leverage users' knowledge about the physical world, the embodiments disclosed build on the notion of “what-you-see-is-what-you-get”, i.e., 3D editor 100 displays and animates objects in a realistic way including (various levels of) realistic rendering and (various levels of) realistic physics. The present invention may achieve physical realism by applying any or all of the following concepts.

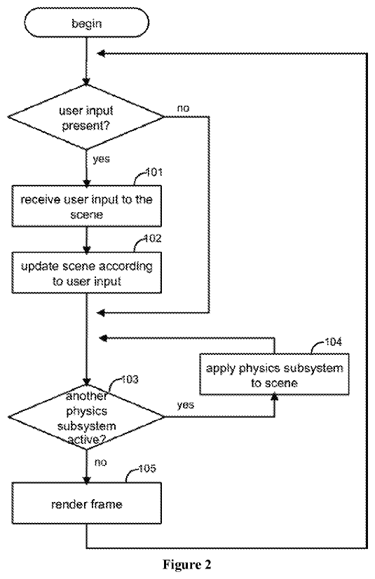

FIG. 2 is a process flow diagram of the 3D editor 100 according to some embodiments. In some embodiments, the physics engine 10 and the rendering engine 24 performs some of the process flow of FIG. 2. At 101, 3D editor 100 receives a user input to the scene. At 102, 3D editor 100 updates the scene according to the user input. At 103, 3D editor 100 determines whether another physics subsystem is active. If 3D editor 100 determines, at 103, that another physics subsystem is active, 3D editor 100 applies, at 104, the physics subsystem to the scene, and then makes another determination at 103. On the other hand, if 3D editor 100 determines, at 103, that another physics subsystem is not active, 3D editor 100 renders a frame at 105. Someone skilled in the art will appreciate that scenes are commonly represented in the form of scene graphs.

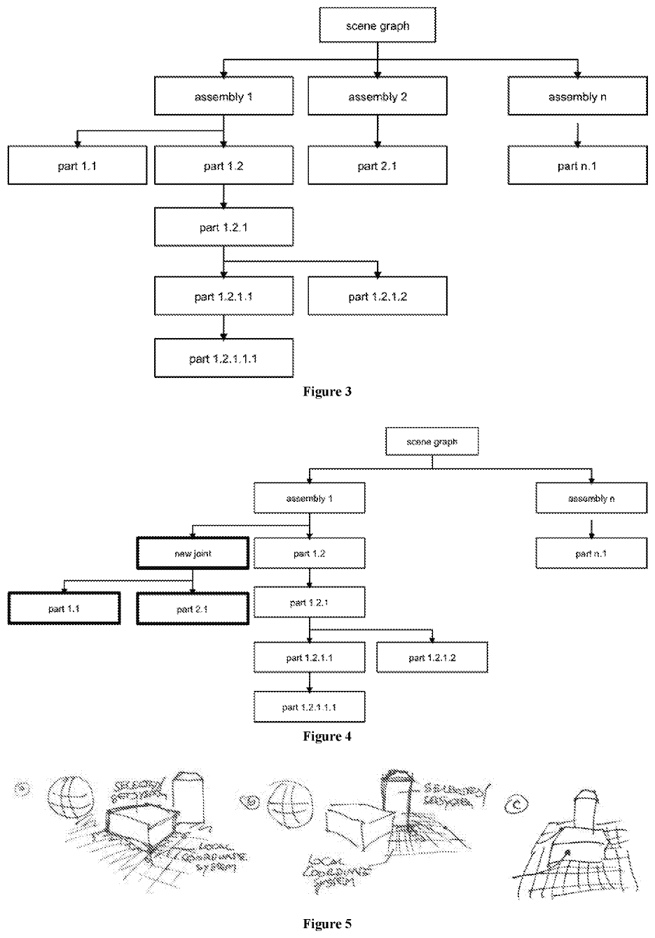

As illustrated by FIG. 3, which is a diagram illustrating a scene graph according to some embodiments. The scene graphs of the instant invention feature a distinct top layers: the assemblies. Scenes thus comprise one or more assemblies and each assembly in turn consist of one or more parts (unlabeled boxes). (In some embodiments assemblies may fill multiple top layers of the scene graph, e.g., because of grouping). (Note how the depiction of the scene graph is simplified: someone skilled in the art would appreciate that scene graphs typically hold additional types of nodes, such as cameras, lighting, and in particular transform nodes that scale and position, etc. assemblies and parts with respect to the stage and each other).

Assemblies are distinct from parts in a number of ways. During user interactions with the scene, assemblies behave as distinct physical entities. In most cases, all parts within an assembly are physically connected with one another, while assemblies are generally not physically connected to other assemblies. Since the scene-assembly-part model defines what is connected explicitly, it allows placing two assemblies in immediate physical contact (zero gap; or even press them against each other) without causing them to become physically connected. Connecting two assemblies into one generally features placing a joint (or mechanism, see below). Joining part 2.1 and part 1.1 from FIG. 3, for example, may result in the new scene graph shown in FIG. 4, where assembly 2 has ceased to exist and instead both parts are now in the same assembly held together by the newly placed joint.

Connections within an assembly may be rigid or compliant. For embodiments that use this scene-assembly-part model to represent objects to be fabricated, rigid connections tend to correspond to physical counter parts on the respective fabrication machine, such as joints. For a 2-3 axis laser cutter or similar device, for example, such rigid connections may represent finger joints, cross joints, butterfly joints, captured nut connectors, etc.; some of these connections may be glued or welded, etc. or just jammed together and held by friction. Compliant elements may for example, include living hinges, as disclosed below. Some embodiments represent assemblies consisting of elements that can move with respect to each other in a constrained way (mechanism: such as axles and bearings) as a single assembly; other embodiments represent them as multiple assemblies.

Most embodiments include one or more tools that allow users to move assemblies, i.e., whichever part of the assembly users touch or click, they always interact with the entire assembly. Examples of such tools include the gravity-based tilt tool and the inertia/friction-based yaw tool, all types of stacking tools, etc. as disclosed later in this document.

When assemblies are moved into each other, the assemblies do not penetrate each other (as is commonly the case with 3D editors in the prior art) but collide and push each other away. Someone of skill in the art will appreciate that this can be accomplished with the help of an off-the-shelf physics engine.

As a result, embodiments of the scene-assembly-part model tend to offer two very different types of interactions and tools. In order to allow users to manipulate assemblies in a scene, tools will generally refer to tools based on gravity, inertia, and friction, such as the gravity-based tilt tool and the inertia/friction-based yaw tool. In order to allow users to manipulate parts (or combinations of multiple parts which we may call sub-assemblies) in an assembly, tools may also include non-physical tools, such as push-pull, etc.

If exported to a fabrication machine, all parts of an assembly tend to physically hold together either right away, or when assembled. Two different assemblies in contrast do not hold together.

Based on this scene-assembly-part model, assemblies also tend to have their own coordinate system, as described in the following.

### 5.3. Coordinate System

Global coordinate systems/local coordinate systems. Some embodiments may use a single global grid, as is common with 3D editors in general. This grid can be rendered onto the working surface, effectively forming the scene's backdrop at all times, as common for the vast majority of 3D editors in use today. Based on this, the grid may be used for alignment in that objects can be snapped into it.

The global grid, however, makes only so much sense in the context of the principles laid out earlier in this disclosure, such as physics in the editor. If two assemblies collide, for example, and one gets bumped away causing it to translate and rotate in a way governed by physics; as a result it will typically not land in a meaningful location on some grid (unless the respective embodiments intentionally snap it), but at an arbitrary location and in some arbitrary rotation. This suggests that things can get out of alignment easily.

Some embodiments therefore drop the concept of a global coordinate system and grid. Instead, such embodiments define a coordinate system and grid only within an assembly, i.e., only where parts are physically connected thereby “physically” maintaining their alignment (FIG. 5). Across assemblies, coordinate systems only come into play when one assembly is moved into the space of another assembly. In this case, the dragged object may align itself with the target object and its coordinate system, e.g., its rotation. Based on this, an embodiment may choose to not even show the respective grid, at least most of the time

FIG. 5 is an isometric view illustrating dragging an assembly in two coordinate systems according to some embodiments. While the system 100 may use a global coordinate system, as common with 3D editors, the shown embodiment uses multiple local coordinate systems, i.e., each assembly has its own coordinate system and shares the scene with other assemblies in only a loose arrangement. (a) The block highlighted in the center of, for example, may embody the coordinate illustrated here as a grid (whether that grid be actually visible or not). (b) The block highlighted in the back of the other may have a different coordinate system, such as the one shown as a grid here (whether that grid be actually visible or not). (c) When an operation on an assembly refers to a coordinate system of a different assembly, here by means of dragging one assembly against a second assembly, the operation may refer to either coordinate system; here, for example, it aligns the rotation of the dragged assembly with the assembly encountered along the way; this may repeat itself with other assemblies along the way. Other interactions may manipulate the assemblies encountered (e.g., aligning those assemblies to a dragged object).

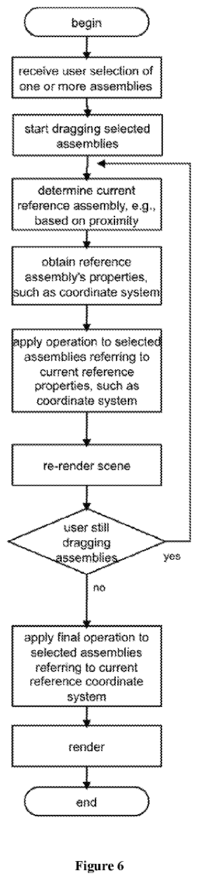

FIG. 6 is a process flow diagram illustrating the operation of the rotation and translation of assemblies dragged into proximity of another assembly according to some embodiments. In some embodiments, the coordinate system engine 18 and the rendering engine 24 performs some or all of the process flow. The process describes this algorithm at the example of the user dragging one or more assemblies. The local operation could be an alignment operation, such as match orientation or line of edges, or any other operation that makes reference to the current reference assembly, such as make sizes match, make colors match, create a series of new objects interpolating some physical dimension, such as height, etc. The operation that triggers the operation can be the user dragging assemblies, but could also be any other action that changes the position and/or orientation of assemblies, such as an automatic or semiautomatic user or system action that moves assemblies around. Finally, instead of using proximity, other functions can be used to determine the reference assembly, such as the user may manually selecting a reference object, for example, in order to align some properties of some assemblies with some reference assembly.

At 1901, 3D editor 100 receives a user selection of one or more assemblies. At 1902, 3D editor 100 starts dragging the selected assemblies in the scene. At 1903, 3D editor 100 determines the current reference assembly, for example, based on proximity. At 1904, 3D editor 100 retrieves properties of the reference assembly, such as a coordinate system. At 1905, 3D editor 100 applies an operation to the selected assemblies using current properties of the reference assembly, such as the coordinate system. At 1906, 3D editor 100 re-renders the scene. At 1907, 3D editor 100 determines whether the user is still dragging the assemblies. If the determination at 1907 is the user is still dragging the assemblies, 3D editor 100 returns to the determination at 1903. Otherwise, if the determination at 1907 is the user is no longer dragging the assemblies, 3D editor 100 applies at 1908 the final operation to the selected assemblies referring to the current reference coordinate system. At 1909, 3D editor 100 renders the scene.

Showing sizes and achieving precision by entering numbers. Especially for embodiments that display no global grid that would communicate a coordinate system to the user, different embodiments may choose different strategies for communicating dimensions of parts and assemblies to the user, as illustrated by FIG. 7, which is an isometric view of a change in dimension of an assembly according to some embodiments. (a) Some embodiments may choose to display the dimensions of an assembly or part or feature, here the depth of the box. Different embodiments may choose different strategies for picking what to annotate when. For example, all relevant features in an assembly may be annotated at all times, on user request, etc. One embodiment may choose to show annotations only when the user is currently using a tool that refers to or manipulates lengths or scales, when the user is selecting an assembly or part or feature of it or when hovering over an assembly or part or feature using an input device that offers a hover state, and/or when trying to align objects.

The embodiment shown in (FIG. 7a) uses a sketch-like/handwritten style, looking as if an industrial designer had manually annotated a sketch; many other styles are possible. This particular embodiment (continuously) adapts the orientation of the annotation in 3D so as to face the user, keeping it readable. Some embodiments may choose elaborate view management strategies to assure the visibility of labels (e.g., [Blaine Bell, Steven Feiner, and Tobias Höllerer. 2001. View management for virtual and augmented reality. In Proceedings of the 14th annual ACM symposium on User interface software and technology (UIST '01). ACM, New York, N.Y., USA, 101-110. DOI=http://dx.doi.org/10.1145/502348.502363]).

As shown in FIG. 7b, some embodiments allow users to modify assemblies by entering a new value for a dimension. In the shown embodiment, users select the dimension (e.g., by clicking or tapping it; the system 100 may also auto select a dimension, e.g., the closest one), then overwrite the current value by entering a new value on a physical or soft keyboard. Other embodiments allow users to instead/also change dimensions by clicking, tapping, or dragging appropriate relative controls, such as sliders, etc. (c) This results in the assembly changing; here the assembly got shorter. There may be multiple ways to achieve the specified change in geometry; embodiments may resolve ambiguities using suggestive interfaces, as described elsewhere in this disclosure. Some embodiments provide other ways of revealing dimensions, e.g. using a ruler tool or a tool that explicitly turns dimension annotations on and off. The same general approach can be used for other properties, such as rotations, colors, etc.

FIG. 7 illustrates the following. (a) During some operation one (or more) scales are being revealed. Here the scale says that that the block is 5 cm long. In this example, the user now selects the scale or the number. On a touch system this could, for example, take place by the user tapping on it. (b) The size of that dimension can be edited now. User who have access to a keyboard by enter a number. Here we show an onscreen keyboard appearing, e.g., as a pop-up associated with the dimension or separately. It could be a specialized keyboard, e.g., with digits and/or a decimal point and/or units and/or an “enter”/“return” key or a more general-purpose keyboard. (3) The object responds by updating the so-adjusted dimension.

Animated transitions. To keep users oriented, embodiments may use animated transitions. Such transitions may, for example, take place in the context of tools that result in movement without the user dragging the object to its final destination, such as tools that “snap” to a destination. Examples include certain types of alignment tools, assembly tools (“attach this assembly to that assembly”), scaling and rotation tools, and disassembly tools, etc. and includes versions that operate on a plurality of assemblies at once. Some embodiments emphasize the transition using appropriate sounds.

### 5.4. 3D Editors as a Physical Environment

Realistic textures including transparent and translucent materials. The system 100 may choose materials and/or allow users to choose materials, allowing the system 100 to render each part in its actual surface texture, translucency, reflectance, bump maps, etc. or any combination thereof. Someone skilled in the art will appreciate that this is commonly accomplished with the help of shaders. Image pyramids and mip-mapping allow achieving performance as the scene is zoomed in and out. Embodiments targeted to a specific fabrication machines may choose to limit the selection to materials that are available for use with the targeted device, such as sheets of plywood, acrylic, Delryn, etc. for a 3-axis laser cutter, ABS and PLA for an entry-level FDM 3D printer, steel and glass for a high-end sintering 3D printer, and so on.

Some embodiments offer textures that change between multiple representations when zoomed (“semantic zooming”). A map may, for example, stop showing any streets but highways when zoomed out past a certain point. One approach is to set a fix threshold for size of structures, number of features, amount of detail, etc. A system 100 performing the zooming may then assess every feature and stop rendering the feature if the feature falls below the threshold.

Realistic physical properties. In some embodiments, the physics engine 10 may consider the specific mass of the materials used in assemblies; iron would, for example, generally be heavier than acrylic and wood. This would manifest itself during collisions (heavy objects are likely to bump light ones away), when computing friction, deformations (see discussion of bending living hinges), etc. In some embodiments, the physics engine 10 may consider the considered friction indices. Assemblies made from Delryn then tend to slide further and tumble less than objects made from wood or even rubber. In some embodiments, the physics engine 10 may consider compliance (e.g., when computing bending and stretching of assemblies, such as living hinges etc.) elasticity/damping (e.g., when determining the wiggling after a collision or when the user relaxes a force applied), sheer strength, Young modulus, etc.

Fabrication-specific artifacts: If the model is intended for fabrication on a fabrication machine, some embodiments consider this process by picking textures so as to represent expected fabrication artifacts or by simulating fabrication artifacts. The result they may render onto the model's (regular and/or bump map) textures (and in the case exceptionally large artifacts) into the object geometry. When processing plywood using a laser cutter, for example, realistic textures may include traces resulting from fumes and burning, may consider the direction of air suction, etc. When processing acrylic using a laser cutter, for example, realistic textures may include buckling and molten edges. For plasma cutters edges may contain burrs. Some embodiments may allow users to specify additional options for pre-/post processing artifacts, such as the result of a plasma cutter after applying use of a deburring tool, the use of a laser cutter after the adding, cutting, and removing masking tape, sanding, sand blasting, chemical processing (e.g., using acetone fumes for certain plastics) etc.

FIG. 8 is an isometric view illustrating an example of a model rendered by the 3D editor according to some embodiments. The model is a 2″ wooden box. The box comprises six wooden plates that are joint using finger joints. The 3D editor 100 has rendered the box using realistic texture 210 and has added fabrication-specific texture artifact 211, which simulates the burning of edges by the laser and fabrication-specific texture artifact 212 simulating the staining of the wood by the fumes moving in the specific direction of air suction in the simulated 3-axis laser cutter. This can, for example, be computed using a simple, asymmetric motion blur. The system 100 may render the texture artifact, for example, by applying this blur as a graphics shader to the assembly's textures. If the scene is zoomed in further, 3D editor 100 may display additional fabrication-specific geometry features, such as slanted edges resulting from the shape of the laser beam (aka “kerf”).

FIG. 9 is a process flow diagram illustrating an algorithm used to compute fabrication specific-textures according to some embodiments. In some embodiments, the fabrication texture engine 12 and the rendering engine 24 performs some or all of the process flow. At 201, 3D editor 100 retrieves parameters of part and characteristics of a fabrication machine. At 202, 3D editor 100 simulates the effect of the fabrication machine onto the part geometry during fabrications. At 203, 3D editor 100 applies the changes in geometry to the part geometry. At 204, 3D editor 100 determines whether more fabrication machine-specific geometry effects are to be simulated. If the determination at 204 is that more fabrication machine-specific geometry effects are to be simulated, 3D editor 100 simulates effects at 202 as described. Otherwise, if the determination at 204 is that more fabrication machine-specific geometry effects are not to be simulated, 3D editor 100 simulates the effect of the fabrication machine onto the part texture during fabrications. At 206, 3D editor 100 applies the changes in texture to the part. At 207, 3D editor 100 determines whether more fabrication machine-specific texture effects are to be simulated. If the determination at 207 is that more fabrication machine-specific texture effects are to be simulated, 3D editor 100 simulates effects at 205 as described. Otherwise, if the determination at 207 is that more fabrication machine-specific texture effects are not to be simulated, 3D editor 100 ends the process.

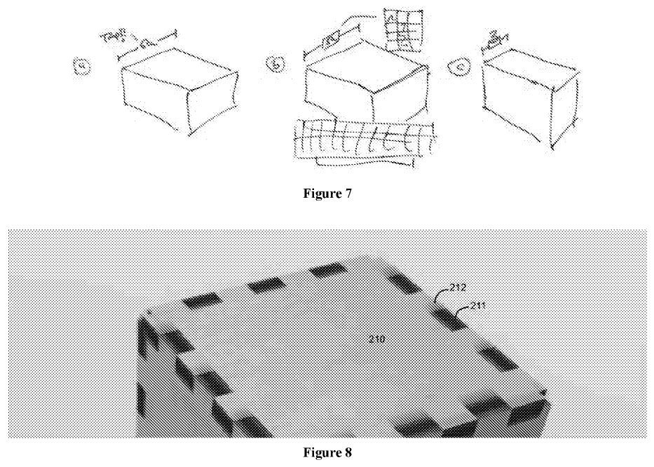

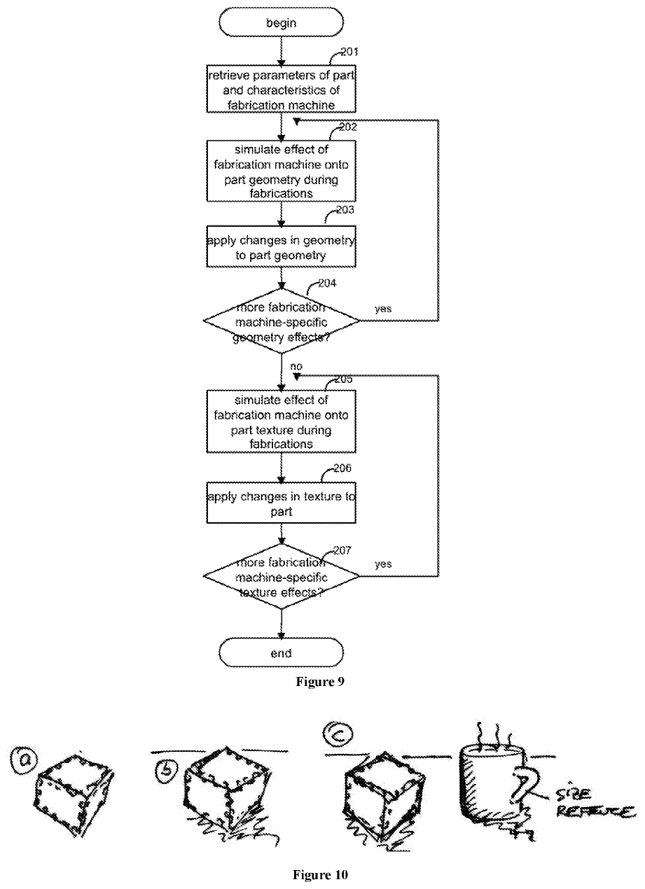

Realistic work environment where the modeling takes place (aka realistic stage). This could be a desk or a workshop or similar. FIG. 10 is an isometric diagram illustrating selected versions of a desktop-like environment of an assembly according to some embodiments. When modeling larger objects, 3D editor 100 may use a larger space as environment, e.g., one that goes down to the floor, as in a workshop or similar. In some embodiments, the 3D editor 100 allows users to customize the environment, e.g., by applying the same tools that allow users to modify assemblies to the environment, such as the working surface (change color, transparency, reflectance, physical properties, such as springiness).

As shown in FIG. 10a, the work environment may be empty except from any assemblies the user is currently working on. Alternatively, additional elements may be added to make the work environment more realistic. As shown in FIG. 10b, the work environment may also contain a working surface that itself has material properties, such as a wooden table, a glass or a reflective surface etc. Here the shown assembly is casting a shadow on the working surface. The working surface may also contain parts of a presumed world surrounding the user, such as a table or workshop. In the shown embodiment, there is a table the end of which is shown as a horizontal edge, but which can also be executed in any level of realism. The room could then continue using a wall or window in the back, etc. (c) The environment may contain one or more additional object for size reference, here a mug. This serves the purpose of providing the user with a sense of scale even when no explicit scale or measurements are being shown. In some embodiments, the system 100 may choose to subject the size reference object and/or the other decorative objects in the work environment to the same tools and physics normally intended to be applied to assemblies. The system 100 may also allow the user to change the working surface and other size reference and decorative objects. For example, the system 100 typically includes tools allowing users to manipulate assemblies; the system 100 may allow users to apply some subset of these tools to the working surface and other size reference and decorative objects, etc (e.g., change material, change texture, scale, etc.).

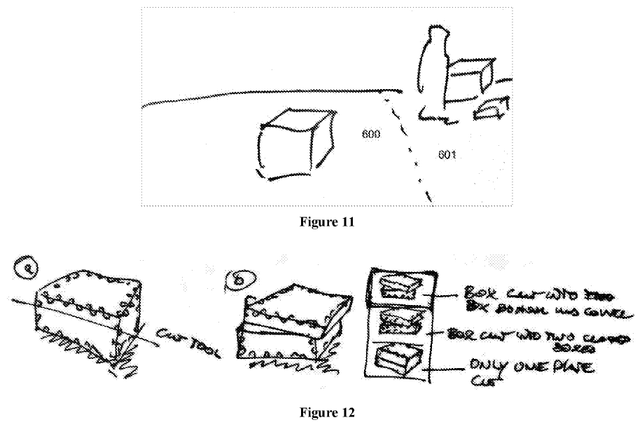

The system 100 may allow users to load and save their models, e.g., by storing them in a personal file system or on a server. Alternatively, the system 100 may allow users to keep some, multiple, or all of their models in their work environment. FIG. 11 is an isometric view illustrating a scene that places a stored object in a specific area 601 so as to distinguish stored objects from currently active objects in area 600 according to some embodiments. This approach allows users to “load & save” models easily by simply moving them into and out of the save area. The distinction between the areas can be used, for example, to determine to only export models in the active area when the user chooses to fabricate. The system 100 may load all assemblies back in when the user logs back in (Laser cut models, for example, are highly compressible, making this reasonably fast). Objects stored in the 3D editor 100 could be prevented from using up (too much) rendering or physics simulation time by converting them to textured rectangles while being outside of active use. When users start to engage with the textured rectangles, moving, rotating, and manipulating the textured rectangles, the system 100 may convert the textured rectangles back to 3D models. Someone skilled in the art would know how to implement this based on how large-scale battle simulation games do it (e.g., Rome Total War).

Realistic graphics including light and shadows. Objects may be rendered in a realistic perspective, field of view, and zoom. In some embodiments, the system 100 renders shadows, such as soft shadows. In some embodiments, the system 100 renders shadows in real-time, e.g., by means of real-time shadow-mapping. In various embodiments, the system 100 employs even more sophisticated approaches to computing lighting in order to obtain additional realism with clear or reflective objects and assemblies in the scene. In such a system 100, a piece of straight of curved acrylic may produce reflections, caustic effects, spectral effects, etc.

Realistic sounds: when objects collide or scrape across a surface, etc. in some embodiments, the system 100 renders matching sounds. In some embodiments, collision events trigger stored sounds (e.g., looking up in an array, hash, trivial hash, or a look-up table, etc.); other embodiments may generate the sounds by simulating the events taking place in the editor. Sound generation may consider the materials and/or size and/or weight of the involved objects. For even higher realism, in some embodiments, the system 100 renders sounds taking the objects contained in the scene and their placement with respect to each other and the environment into considering (sound rendering). In some embodiments, the system 100 adds made-up sounds to interactions that would otherwise produce no or no perceivable sound (such as picking up an object).

Natural input. Some embodiments of the system 100 are designed to work on a computing system with various input/output capabilities. While different embodiments may use different input/output mappings, the system 100 is designed so that inputs take place in the most natural way and with the most intuitive mapping from input to display space. In particular: (a) direct touch: here users interact with assemblies by tapping or dragging them directly on a touch-sensitive screen; this can be done using a finger, a stylus, a digitizer, etc.; it can be emulated if desired using an indirect input device, such as a mouse, and a pointer. (b) Absolute six degree-of-freedom input (as used in virtual reality): here users interact with assemblies by acquiring them in three-dimensional space where they tap or drag them directly. This embodiment goes together with a corresponding 3D display, such as a head-mounted display (e.g., Oculus Rift, Vive, etc. with 3 DoF, such as roll, pith, and yaw, or 6 DoF tracking/realwalking, such as x, y, z, roll, pitch, yaw) so that users acquire objects in three-space where they see them in three-space.

Some embodiments are designed to run across these different input/output systems, e.g., including 2D direct touch and 3D with 6DOF input. To allow for this, all interactions may be designed for (single) direct touch input in the first place, as this tends to be available on a large number of computing devices available today or can be emulated using an indirect input device controlling an on-screen pointer. If the platform offers additional input capabilities, the system 100 includes for additional functionality or speed-ups, such as the ability to also rotate objects using multi-touch or to select objects behind other objects in 6 degrees of freedom (DOF).

Resolving ambiguity in the interaction. The present invention allows users to manipulate assemblies by means of tools, such as scaling tools or texture tools. In various embodiments, the system 100 includes tools that contain all information to perform the operation, such as a scaling tool that gathers the new scale at part of the interaction. Such tools can show the outcome during the interaction, making it easy for users to see what they are about to get. In various embodiments, the system 100 may also include tools that use more parameters than what the respective tools allow users to enter as part of the interaction. Some tools may allow users to provide the additional parameters before the tool is applied, which allows the tool to still provide feedback as the user interacts. Yet other tools allow entering the additional parameters after the tool interaction. In order to provide feedback along the way, the tools may assign default values for the missing parameters or may try to guess the values of the parameters. In this case, the tools may allow users to fix or tweak the results in case the default or guessed values were incorrect. Where the tool chose to connect two parts using finger joints, for example, the user may afterwards replace the finger joints with a skeleton+façade structure. Tools may also ask for the missing parameters. Tools may also explore multiple possible values for the parameters and allow users to choose afterwards, e.g., by rendering the respective outcomes and offering users to choose from them (building on suggestive interfaces [Takeo Igarashi and John Hughes. Chateau: A Suggestive Interface for 3D Drawing. In Proc. UIST 2001. Pages 173-181]).

Some embodiments include all of these strategies, while other embodiments may include a subset of these strategies. FIG. 12 is an isometric view of a system using a tool according to some embodiments. (a) In the shown example, the user is performing an action with multiple possible interpretations, here performing a gesture using a split tool to the side of a box. (b) In this embodiment, the system 100 responds by performing what the system 100 considers the action the user most likely meant—here the system 100 assumes that the user meant to cut the box in half. This top-ranked version only goes into the main view. At the same time, the system 100 shows other possible interpretations to the user, in this example using a picture-in-picture visualization. In this case, the system 100 suggests (top) cutting the box into top and bottom, (middle) turning the box into two separate closed boxes, and (bottom) leaving the box intact apart from a cut across one of the plates. The system 100 allows users to override the system's suggestion by picking another interpretation from the picture-in-picture views, in which case the selected interpretation is moved or copied into the main view. Alternatively, users may simply continue working in the main view, automatically picking this default; in this case the picture-in-picture views may or example disappear automatically.

To generate the picture-in-picture views, the system 100 for example clones the scene graph and processes each one individually. The picture-in-picture views may be scaled down geometrically or “semantically”, i.e., so that the key features that make them different are highlighted.

In this embodiment, the system 100 computes the interpretations and estimates a probability for each one, for example, based on default settings, statistics of past use, etc. In the shown example, the system 100 may have come up with more than the three shown interpretations, but the system 100 may have chosen not to render them. The option of a straight cut through the front plate and a diagonal cut through the side plate, for example, appears unlikely and when the system 100 determines that is probability is below an internally defined “tell me” threshold, the system 100 may simply suppress this option, as was the case on the shown example.

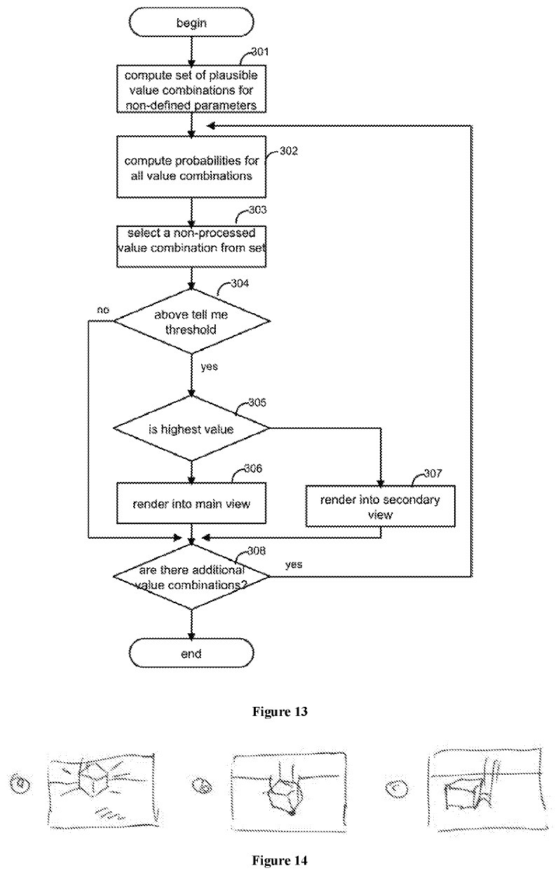

FIG. 13 is a process flow diagram illustrating a display determination operation according to some embodiments. In some embodiments, the tool box engine 16 and the rendering engine 24 performs some or all of the process flow. The process determines the alternatives and the choice which ones to render. If only a single interpretation should be above the “tell me” threshold, the system 100 may simply execute it and be done.

At 301, 3D editor 100 computes a set of plausible value combinations for non-defined parameters. At 302, 3D editor 100 computes probabilities for all value combinations. At 303, 3D editor 100 selects a non-processed value combination from the set. At 304, 3D editor 100 determines whether the non-processed value combination is above a “tell me” threshold. If the determination at 304 is that the non-processed value combination is above a “tell me” threshold, 3D editor 100 determines, at 305, whether the non-processed value combination is the highest value. If the determination at 305 is that the non-processed value combination is the highest value, the 3D editor 100 renders at 306 the tool application into the main view. If the determination at 305 is that the non-processed value combination is not the highest value, the 3D editor 100 renders at 307 the tool application into the secondary view. After the rendering at 306 or 307, 3D editor 100 determines at 308 whether there are additional value combinations. If the determination at 308 is that there are additional value combinations, 3D editor 100 proceeds to compute at 302 as described above. Otherwise, if the determination at 308 is that there are no additional value combinations, 3D editor 100 ends this process. If the determination at 304 is that the non-processed value combination is not above a “tell me” threshold, 3D editor 100 proceeds to the determination at 308 described above.

Configuring proactive behavior. In order to allow the system to deal with uncertainly, the system 100 may perform some or all of its computation in terms of estimated probabilities, utilities, and penalties [Donald Knuth. The TeX Book. Chapter on line break algorithm]. Based on these, the system 100 makes decisions on the user's behalf. Different users have different preferences with respect to proactive system behaviors. To accommodate for this, the system 100 may maintain one or more configurable “tell me threshold”; when one or more of these threshold is exceeded, the system 100 may make the respective suggestion (e.g., suggesting to add structural support). Similarly, the system 100 may maintain one or more configurable “do it threshold”; when one or more of these threshold are exceeded the system 100 takes immediate action.

In some cases, alternative solutions can be arranged into a multi-step workflow. In the case of FIG. 12 this may be (step 1) cut the plate in front, (step 2) cut all the way around, and (step 3) close up the two resulting boxes. In one embodiment, the system 100 executes the most comprehensive solution, but allows users to access the less comprehensive versions by invoking the undo function. In the case shown in FIG. 12, the system 100 may, for example, choose to render the result as two closed boxes. If this is not the option the user wanted, the user may trigger an undo function, which undoes the last step, resulting in two open boxes. If this is not the option the user wanted either, the user may trigger undo again, resulting in the single box with a cut plate. Users may navigate back and forth by invoking undo and redo. Alternatively, the system 100 may start by rendering a different stage of the workflow, e.g., if that step seems more likely than the most comprehensive one.

Add-assembly tool based on gravity. collisions: Some embodiments of the present invention may simulate additional aspects of physics, such as collision, in order to achieve a stronger sense of immersion and realism. FIG. 14 is an isometric view illustrating illustrates this at the example of an add-assembly tool according to some embodiments. An add-assembly tool allows adding assemblies to the scene by dropping or throwing them into the workspace. In some embodiments, the system 100 enables similar physics effects whenever multiple assemblies collide. In this case, assemblies bumped into may be bumped away, knocked over, or even break apart as a result of the collision. In various embodiments, the system 100 uses this effect to implement a disassemble tool that allows users to disassemble compounds by hitting them with a tool, e.g., shaped like a hammer. One way of implementing collisions (as well at gravity and inertia) is to include a physics engine (Havok, PhysX, Bullet, Cannon, etc.).

This particular interaction may also take place as a way of starting a new modeling session (the user may, for example, have selected to create “new” scene), i.e., to pre-populate the stage with a simple object that illustrates the laws of the editor's world (a) a simple cube appears (b) drops following gravity, and (c) bounces of the ground until it comes to rest (FIG. 14).

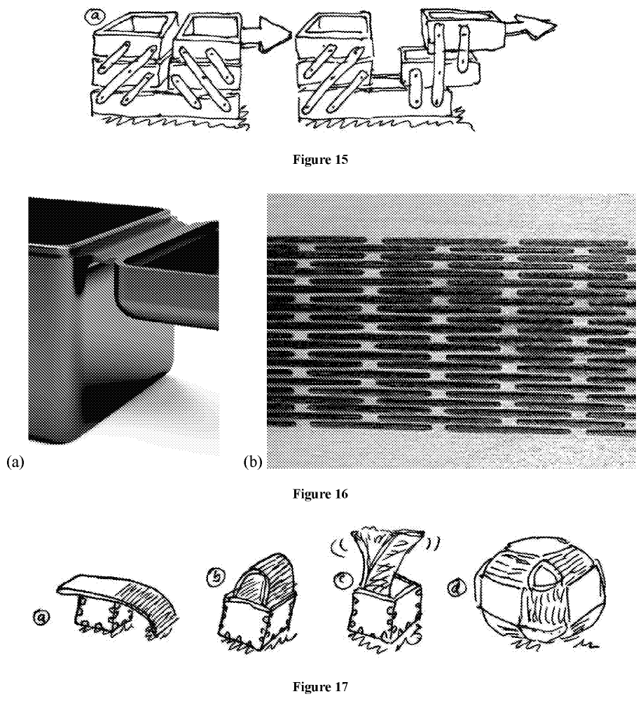

Simulation of moving parts and physical constraints. Some embodiments may allow users to edit and/or operate assemblies with moving parts, such as levers, wheels and axles, pulleys, incline planes, wedges, screw, gears, or other mechanisms resulting from these or combinations of these. Some embodiments may offer specialized tools for editing or operating mechanisms. Other embodiments may instead or in addition offer versions of those tools that are generally used for moving things around, so that these can also operate or modify mechanisms. FIG. 15 is an isometric view illustrating an example of moving parts according to some embodiments. The object shown, for example, contains several rotary joints that allow the assembly to be “opened up”. Grabbing the top right bowl, for example, and pulling it upwards and towards the right would then results in the shown behavior. Similarly, turning the device upside-down should cause the bowls to fold out. The shown behavior may be implemented using a the physics engine 10 that is aware of the mechanisms offered by the system 100, or it may be implemented using a regular physics engine that simply moves the bowl within the constraints of its neighborhood of parts and optionally considering the weights and/or friction involved between the parts of the assembly.

Simulation of deformation and springiness: Some embodiments may allow for compliant materials resulting in non-rigid parts and assemblies. While no material and thus assembly is ever fully rigid, many assemblies are rigid enough to result in only very small deformations. An embodiment may thus choose to render all deformations or just those large enough to be noticeable.

Structure and arrangement of parts into an assembly has major influence on the amount of resulting deformation. For example, as shown in FIG. 16a, making a cross section of a part very thin causes it to become locally compliant. Here the effect is achieved using a 3D printer or injection molding machine; similar effects can be achieved using milling machines, laser cutters, etc. FIG. 16 is a plan view illustrating surface effect on a surface of an assembly according to some embodiments. As illustrated, a similar effect can be achieved by covering a region of material with slits in the shown arrangement. Both of these designs have sometimes been referred to as “living hinges.”

If forces apply, compliant parts and assemblies tend to deform. In some embodiments, the system 100 computes these forces and render the resulting deformation. FIG. 17a is an isometric view illustrating an overhanging part bending down under the forces of gravity according to some embodiments. FIG. 17b is an isometric view illustrating an assembly that users can bend and hold assemblies and compute and render the resulting deformation. As illustrated by FIG. 17c, which is an isometric view illustrating releasing a bent assembly according to some embodiments, the user may release a bent assembly to cause the bent assembly to return to its natural shape. Here, this was triggered by pulling the strip out of the box. Some embodiments render the damped wiggling of the strip during the resulting relaxation phase with the help of a physics sub system, such as the physics engine 10. FIG. 17d is an isometric view illustrating an assembly that includes complaint parts according to some embodiments. In the shown situation, the spatial relationship between parts is flexible and thus determined by the physics subsystem. The resulting assembly is compliant and springy, i.e., applying a force to the entire assembly causes it to deform and spring back.

Some embodiments support objects deformable in two or more dimensions. FIG. 18 is a diagram illustrating one example of a sheet of material that can be deformed in two dimensions, allowing it to buckle according to some embodiments. This can be done with elastic materials, such as wood, or, as shown with inelastic materials, here copper that deform permanently.

One way of computing the deformation of compliant parts and assemblies is by means of specialized components that implement their own deformation as a function of the forces applied. A more general way of implementing deformation is by means of general-purpose solvers for deformation, such as those based on finite elements analysis. The page https://en.wikipedia.org/wiki/List_of_finite_element_software_packages lists software libraries lists solutions that perform such analyses, such as Agros2D, CalculiX, Code_Saturne, DIANA_FEA, deal.II, DUNE, Elmer, etc.; someone skilled in the art would appreciate that the better-suited engines are those that allow for large deformations. Suitable subsystems can also be adopted from engines commonly used as part of computer games. Some embodiments push physics and simulation further, e.g., including dynamic aspects, such as oscillation.

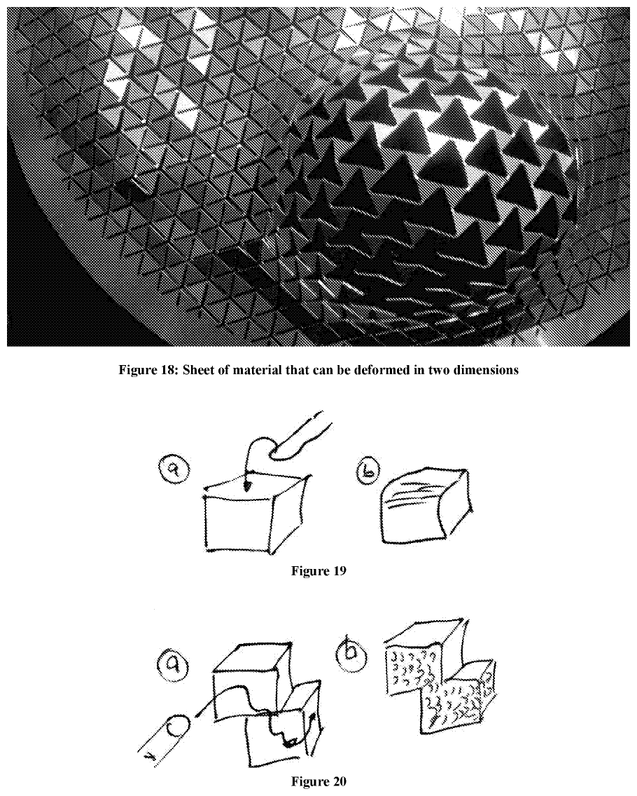

While all materials and parts may have some level of compliance, embodiments may include various tools to allow users to explicitly create, insert, and modify compliant parts or regions or parts. FIG. 19 is an isometric view illustrating selected examples of tools for compliant parts according to some embodiments. (Selected add tools add assemblies containing compliant elements to the scene, such as (a) add cylinder to create cylinders and (b) add cone to create cones. Here the compliant parts allow creating rounded surfaces. (c) Round edge tools allow users to introduce compliant regions into otherwise angular assemblies. (d) Add hinge tools allow users to insert compliant regions into sheets of material. Some embodiments conclude the orientation of the hinge from the direction of the input stroke performed by the user; in other embodiments, the system 100 obtains the parameters of hinges before or after the hinge is places as discussed earlier in our section on parameter entry. (e) Add façade tools allow users to attach a 1D or 2D compliant surface to a number of control points. The compliant surface then stretches over the control points in analogy to a 2D curve in computer graphics, such as non-uniform rational basis spline (NURBS). These examples are illustrated using the specifics of a somewhat compliant material, such as wood created from a sheet using a subtractive fabrication machine, such as a laser cutter, milling machine, water jet cutter, etc. Someone skilled in the art will appreciate that similar effects can be achieved with other materials and also other machines capable of producing similar slit patterns, or machines capable of fabricating living hinges, such as a wide range of 3D printers.

To allow users to interact with compliant parts and assemblies, some embodiments include tools that make certain regions compliant or rigid or change their rigidity, such as the ones shown in FIG. 20, which is an isometric view illustrating other selected examples of tools for compliant parts according to some embodiments.

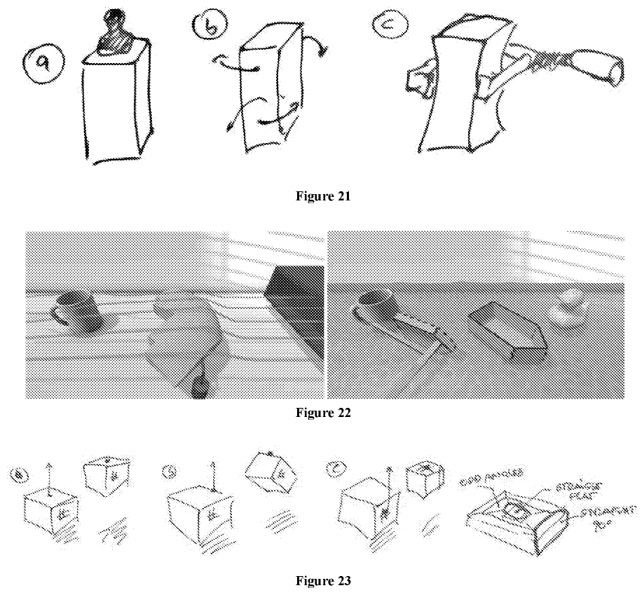

Although compliant behavior is described in the context of gravity, forces may also be applied by the user, e.g., using tools. FIG. 21 is an isometric view illustrating selected examples of tools for applying forces to parts according to some embodiments. In some embodiments, the system 100 includes (a) tool that allows applying force, (b) weights, (c) torque and/or (d) tools and assemblies that result in forces or torque, such as a (virtual) clamp.

FIG. 22 is an isometric view of a simulation soft an assembly according to some embodiments In addition to gravity and user input, in some embodiments, the system 100 adds additional types of physics or physics-like simulations that apply forces to assemblies based on simulated wind, as shown in FIG. 22a, which is an isometric view of a wind simulation of an assembly according to some embodiments, [Nobuyuki Umetani, Yuki Koyama, Ryan Schmidt, and Takeo Igarashi. 2014. Pteromys: interactive design and optimization of free-formed freeflight model airplanes. ACM Trans. Graph. 33, 4, Article 65 (July 2014)] e.g., by allowing users to add wind sources to the editor, stability vs. breakage (e.g., [Takeo Igarashi, Hidehiko Tanaka. Method for constructing a 3d polygonal surface from a 2d silhouette by using computer, apparatus thereof and storage medium. U.S. Pat. No. 6,549,201 B1, Apr. 15, 2003]). Some embodiments allow computing whether the object will stand or tip over, (e.g., [Romain Prevost, Emily Whiting, Sylvain Lefebvre, Olga Sorkine-Hornung. Make It Stand: Balancing Shapes for 3D Fabrication. In Proc. ACM SIGGRAPH 2013] whether it can spin like a top (e.g., [Moritz Bächer, Emily Whiting, Bernd Bickel, Olga Sorkine-Hornung. Spin-It: Optimizing Moment of Inertia for Spinnable Objects. In Proc. ACM SIGGRAPH 2014], some embodiments allow spinning assemblies in the editor), how it will float; some embodiments allow adding simulated water to the editor, as shown in FIG. 22b, which is an isometric view of a water buoyancy simulation of an assembly according to some embodiments), or how the object responds to temperature (some embodiments allow adding heat and cold sources).

### 5.5. Making the Non-Physical Aspects of 3D Editing Physical

The concept of physical interaction as disclosed above results in a consistent user experience. Yet, 3D editors traditionally contain several aspects that do not align well with the notion of a world based on physics—in particular view management and alignment. In the following, novel approaches to view management and alignment are described that are consistent with a world based on physics.

### 5.5.1. View Management

Realistic view navigation. Many traditional 3D editors allow for 6-degree-of-freedom-view navigation (as in three degrees of rotation and three degrees of translation), some with additional zoom or dolly zoom (which changes the perspective between parallel projection and strong foreshortening). Because of the large number of degrees of freedom, some navigation tools can involve complex user actions (such as press-and-hold the middle mouse button, then drag) and thus can be hard to learn and error-prone to use—users may end up with an undesired perspective or even looking away from the object or zooming in so far that the screen is filled with a single color or zooming out until nothing can be seen [Susanne Jul and George W. Furnas. 1998. Critical zones in desert fog: aids to multiscale navigation. In Proceedings of the 11th annual ACM symposium on User interface software and technology (UIST '98). ACM, New York, N.Y., USA, 97-106. DOI=http://dx.doi.org/10.1145/288392.288578]). Some embodiments of the system 100 may support some version or subset of this traditional style of navigation.

Other embodiments of the system 100, however, may offer assembly-based view management. The main idea here is that embodiments offer one or more tools that allow users to inspect assemblies by manipulating the assembly, rather than by manipulating the camera (with the camera, of course, traditionally representing the user's eyes). In accordance with what users may need to inspect, different embodiments offer different sets of inspection tools. If users may need to inspect detail, for example, an embodiment may include a close-up tool that allows picking up an assembly and moving it closer to the camera; the same functionality would traditionally be achieved by zooming the camera. Alternatively, e.g., an embodiment handling scenes of low-complexity and/or on large displays may refrain from offering such a tool. If users may need to inspect an assembly from different sides, an embodiment may allow rotating assemblies in terms of yaw; this might be used as substitute for (some aspects of) the traditional camera orbiter mode. If users may need to inspect an assembly from above and below, an embodiment may allow tilting assemblies; this might be used as substitute for (some other aspects of) the traditional camera orbiting. If users may need to inspect the internal structure of assemblies, an embodiment may allow viewing it in a semi transparent representation, as a wireframe graphic, or as some sort of explosion diagram, etc.; this might be used as substitute for a global rendering settings.

Some embodiments include a single assembly-based view navigation tool, others include multiple specialized tools, yet others include one or more tools that allow users to manipulate multiple degrees of freedom at once. For example, a mouse-based or single-touch-based system may offer a tilt/yaw tool that allows rotating an assembly around its tilt and yaw axes in one operation (e.g., adjust yaw by dragging sideways and adjust tilt by dragging up/down, in the case of a 2D input device). A multi-touch based embodiment may also allow, for example, close-up viewing using a pinch-to-zoom gesture or similar. As another example, an embodiment may use a 6DoF VR controller or comparable device to allow users to manipulate a large number of degrees at once, such as tilt, yaw, roll, horizontal pan, vertical pan, and close-up or any subset of these. Other embodiments may invoke assembly-based view navigation tools by tapping, clicking, or simply pushing a button, e.g., to bring a selected assembly into close-up viewing.

Such operations can be complemented with additional automated aspects, such as up-close viewing while also tilting and/or yawing the assembly so as to be perpendicular to the camera and/or scaling it to filling a particular percentage of the screen. Such operations may also establish a mode within which a particular set of functions of tools is made available, such as that a pointing device controls tilt and yaw of assemblies as long as they are in up-close viewing mode, i.e., until the mode ends.

In some embodiments, the system 100 includes assembly-based view navigation exclusively. However, hybrid and redundant embodiments are possible too. Such embodiments may, for example, combine an assembly-based close-up tool with traditional orbiting, etc.

Different embodiments of the system 100 implement assembly-based view navigation in different ways. An assembly-based view navigation operation may be inherently temporary, so that manipulated assemblies move or animate back automatically, e.g., once the tool is released. Alternatively, assemblies may permanently come to rest in the intended position. Especially the latter allows assembly-based view navigation to be unified with other tools, in the sense that any tool that moves assemblies around can implicitly serve as an assembly-based view navigation tool. Gravity-enabled tilt-tools and gravity-enabled yaw-tools, for example, may be considered tools for manipulating assemblies (e.g., as part of a workflow that positions assemblies before fusing them with other assemblies)—but these tools can also be considered assembly-based view navigation tools.

Analogously, the temporary versions can also be integrated with other tools. A tool that adds texture to assemblies, for example, may temporarily position those assemblies for up-close viewing while users position the texture; the assembly may then, for example, automatically snap back to its previous position and orientation.

The primary benefit of assembly-based view navigation is that it largely eliminates the need to manipulate or even think about the view. In traditional view navigation, users need to switch back and forth between manipulating the scene and manipulating the view. Even worse, they need to learn each aspect separately, which may include the difficulty of controlling six or more degrees of freedom using a 2D input device, such as a mouse or touch. Assembly-based view navigation, in contrast, allows users to only think and learn about manipulating objects, which then does double duty for manipulating scene and view. Furthermore, the integration makes it easy to complement tools that manipulate assemblies with just the right amount of view manipulation, such as only to automatically tilt and yaw an assembly into position so as to allow manipulating the front, etc. As a result, some embodiments may choose not to offer an equivalent for the traditional 6 DoF view navigation, thereby eliminating one of the hurdles that traditionally made it difficult for new users to get into 3D editing.

Finally, assembly-based view navigation integrates particularly well with the concept of a “realistic” 3D editor as already described throughout this disclosure. Traditional camera-based view navigation contains a lot of interactions that clash with the notion of a physical world, e.g., when users fly around an object or duck through a virtual table surface in order to view an object from below. In contrast, the notion of picking up an object and turning it in one's hand in order to view it from different sides tends to be consistent with the notion of a physical world.

Note that the concept of assembly-based view navigation emerges from the notion of a world containing a realistic work environment and multiple assemblies. The traditional concept of 3D editing, in contrast, is generally based on a single assembly and a stage of no discernable work environment. In such a world that effectively consists only of a single chunk of contents and the camera, manipulating the single assembly can be indistinguishable from manipulating the camera.

Different embodiments may include different types of assembly-based view navigation tools. In the following, a few specialized tools, including gravity-enabled tilt-tools and gravity-enabled yaw-tools, are described.

Gravity-enabled tilt-tools. As illustrated by FIG. 23, some embodiments may offer tools that allow users to pick up assemblies. Some embodiments offer tools that use picking up to rotate an assembly—either as the sole purpose of the tool or as a side effect of the manipulation performed by the tool. FIG. 23 is a diagram illustrating a tool to allow users to pick up assemblies according to some embodiment. The tool does so in a physically realistic or at least pseudo realistic way. (a) Picking up an assembly above the object's (real or stylized) center of mass allows lifting the assembly up without rotating it. (b) Grabbing an assembly anywhere else causes the object to tilt (or roll). In the shown case, the object may for example tilt to a 45-degree angle, which may be desirable when attempting to drop the assembly into a matching contraption. (c) Grabbing an assembly by the side causes it to tilt by a larger extent, such as around 90 degrees. In order to make the effects feel physically realistic, the assembly may be given inertia causing it to swing back and forth. In order to keep the interaction easier to control, the swinging object may be strongly damped. (d) To make it easier to achieve common tilt angles, the contact regions that correspond to such common tilt angles may be virtually extended. The contact area above the center of mass may, for example, be given additional area. Such extended regions may be defined in terms of assembly geometry, or they may be defined by determining tilt/roll based on regular physics first and then rounding it to supported values. Tilt tools that also support gravity-enabled yaw (as described below), may instead support slight tilt or roll, so as to enable yaw. Extended regions may be visibly marked or not.

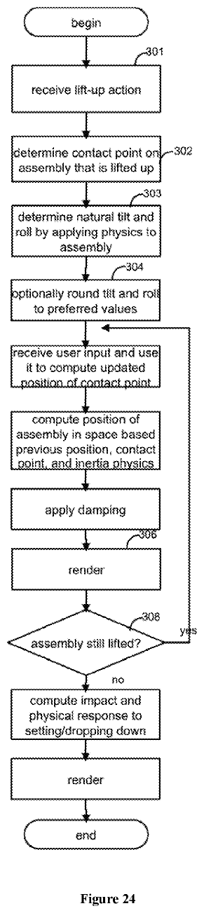

FIG. 24 is a process flow diagram illustrating a tilt and roll operation according to some embodiments. In some embodiments, the physics engine 10, the movement engine 20, the view generating engine 32 and the rendering engine 24 perform some or all of the process flow. At 2201 3D editor 100 receives a lift-up action from a user. At 2202, 3D editor 100 determines the contact point on the assembly that is lifted up. At 2203, 3D editor 100 determines the natural tilt and roll of the assembly by, for example, applying physics to the assembly. At 2204, 3D editor 100 option may round the tilt and roll to preferred values. At 2205, 3D editor 100 receives user input and computes updated position of contact point using the user input. At 2206, 3D editor 100 computes the position of the assembly in space passed on the previous position, contact point, and inertia physics. At 2207, 3D editor 100 applying damping to the motion of the assembly. At 2208, 3D editor 100 renders the scene in response to the position and damping. At 2209, 3D editor 100 determines whether the assembly is still lifted. If the determination at 2209 is that the assembly is still lifted, 3D editor 100 proceeds to receiving user input at 2205. Otherwise, if the determination at 2209 is that the assembly is not still lifted, 3D editor 100 computes at 2210 the impact and physical response to setting or dropping down the assembly. At 2210, 3D editor 100 renders the scene with the assembly set or dropped down.

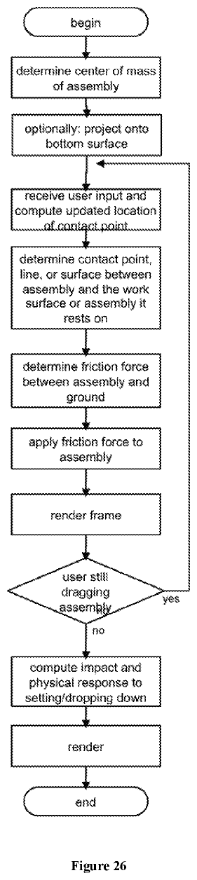

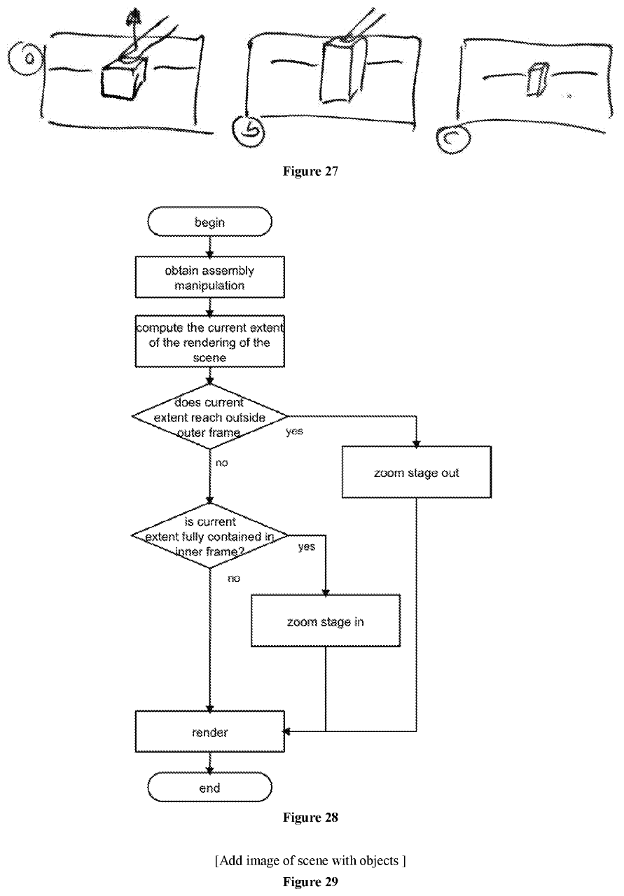

Gravity/friction-enabled yaw tool. Embodiments that support multi-touch may allow users to rotate assemblies in terms of yaw, for example by acquiring the assembly with two fingers such as thumb and index finger and performing a rotation with the respective pair of fingers. Embodiments that include input with sufficient degrees of freedom, such as a VR controller may also rotate assemblies by acquiring the object, rotating the controller, and dropping the assembly. Alternatively, embodiments that support spatial input of at least two degrees of freedom (such as x, y on single or multi touch systems, mouse/trackball/d-pad/joystick etc. input, game controller, VR controller, etc.) may rotate assemblies in terms of yaw using the algorithm described in FIG. 26, which is a process flow diagram illustrating a yaw determination for a drawing assembly according to some embodiments, and that allows manipulating assembly raw as part of a (physically realistic) movement. The algorithm involves dragging an assembly in a way that it makes (or is simulated to make) some contact with the working surface or another assembly below, resulting in (realistic or fake) friction. The system 100 rotates an object during dragging as a function of the dragging direction. The system 100 allows users to re-orient an assembly by choosing an appropriate dragging path that ends tangential to the desired orientation.

Note how two different dragging paths generally result in different resulting orientations of the dragged assembly, even if the user's input covers the same net vector. The dragged object may be subject to inertia, potentially causing it to swing, oscillate, or overshoot. Some embodiments may apply appropriate damping to prevent this.

To allow the same tool to be used to merely move objects, some embodiments may help users to move an assembly without rotating it by eliminating small friction forces (e.g., by thresholding them) or by virtually expanding the touch contact region over the center of mass.

Friction forces may apply not only to yaw, but also tilt and roll. Some embodiments may consider these components of the friction force, thereby allowing the dragged assembly to tilt, roll, tumble, or even flip over during dragging. Other embodiments may eliminate this by eliminating the respective components of the friction force vector, or by projecting down the contact point of the user's input into the same plane as the center of mass. Some embodiments may apply the friction force also to the assemblies the dragged assembly, allowing this class of tools to be used to affect the rest of the scene, e.g., to align assemblies.

Another embodiment of yaw tool considers inertia instead of or in addition to friction. This allows these versions to work without the dragged assembly being in physical contact with the work surface or another assembly. Strong damping helps prevent the object from spinning perpetually. Gravity/friction-based yaw tools can be combined with gravity-based tilt/roll tools. The inertia-based version is particularly useful here.

FIG. 26 is a process flow diagram illustrating a yaw determination for a drawing assembly according to some embodiments. In some embodiments, the physics engine 10, the tool box engine 16 and the rendering engine 24 performs some or all of the process flow. At 2401, 3D editor 100 determines the center of mass of an assembly. At 2402, 3D editor 100 projects the center of mass on the bottom surface of the assembly. The projection at 2403 is not performed in some embodiments. In one embodiment, the projection of the assembly may be user selectable. At 2403, 3D editor 100 receives user input and computes an updated location of the contact point of the assembly on a work surface or other assembly that the assembly rests. At 2404, 3D editor 100 determines a contact point, line, or surface between the assembly and the work surface or assembly on which the assembly rests. At 2405, 3D editor 100 determines the friction force between the assembly and the ground. At 2406, 3D editor 100 applies the friction force to the assembly. At 2407, 3D editor 100 renders the frame of the scene. At 2408, 3D editor 100 determines whether the user is still dragging the assembly. If the determination at 2408 is the user is still dragging the assembly, 3D editor 100 returns to the receiving user input at 2403. Otherwise, if the determination at 2408 is the user is no longer dragging the assemblies, 3D editor 100 computes at 2409 the impact and physical response to the setting down or dropping the assembly. At 2410, 3D editor 100 renders the scene with the assembly set down or dropped.

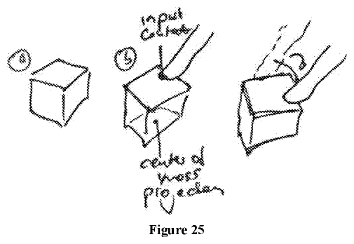

FIG. 25 is an isometric view illustrating the operation of rotating an assembly in yaw for a dragging movement according to some embodiments.

As discussed above, these and other tools can be combined with automatic snapback, with additional up-close viewing, with each other, etc.

Many of today's mobile devices, such as phones and tablets contain accelerometers capable of detecting when the device is being shaken. Some embodiments use this to allow users to interact with the scene assemblies. One approach is consider the stage as being statically coupled to the phone's casing, so that any movement to the phone results in a corresponding movement of the stage.

Automatic stage scaling: As a means to reduce the necessity to trigger up-close viewing repeatedly, some embodiments may allow manipulating the user's view onto the stage, such as zoom, pan, and tilt. In many situations, the objective is to make “good use” of the stage, i.e., (1) to fit all assemblies into the stage or (2) make sure that each assembly is at least partially visible on stage (so it can be pulled in if necessary), but other view management strategies are possible. Within those constraints, the stage could, for example, be zoomed in as far as possible so as to minimize the necessity to zoom.

The optimality of the view onto the stage may change as users manipulate assemblies. As shown in FIG. 27, which is an isometric view illustrating a zooming operation according to some embodiments, a stage may be appropriately zoomed, when a user (a) makes an assembly on stage larger, so as to now reach the edge of the view or get close to it (b). The user may now (c) zoom out the stage so as to fit the assembly into the stage completely again. In its simplest form, this could be accomplished with makeStageLarger or makeStageSmaller buttons or similar functionality. Similarly, users may tilt the view in order to accommodate higher or less high objects. (Panning is possible too, although some embodiments may choose to instead move assemblies as in assembly-based view navigation).

In some embodiments, the system 100 chooses to scale the stage automatically. Using FIG. 27 again, many embodiments perform the last step, shown in (c) automatically, i.e., if an object is getting close to extending past the edge of the view, the view will shrink automatically (e.g., using a smooth animation). While it is conceptually possibly to do this continuously during the interaction (e.g., using rate controlled manipulation), many embodiments instead perform the zoom adjustment after the user completes the current interaction. This means that very large-scale adjustments may take multiple steps. To keep the number of steps manageable, in some embodiments, the system 100 scales so as to leave a certain amount of blank space in which further scaling can then be performed. Such multi-step scaling allows scaling objects by a constant factor per step, thus can achieve any scale in a logarithmic number of steps. Similarly, if assemblies are ever scaled down past a minimum size, embodiments may scale the stage up again. To prevent overly frequent stage “yoyo” zooming, most embodiments would employ “hysteresis”, i.e., the scale of the scene has to drop down further past the scale that triggered its expansion before it gets scaled down.

All of the above can be done for tilt and yaw as well.

In some embodiments, the 3D editor 100 may complement zooming the stage with additional actions, such as the (e.g., automatic) addition or removal of size reference objects, e.g., replacing or complementing the cup shown earlier with a size reference object appropriate for the new scale, such as a chair. In some embodiments, the 3D editor 100 may also modify the stage, e.g., transition from assemblies being placed on a desktop work environment to a workshop environment, where (large) objects are placed on the floor. These transitions may be animated, including effects where the desk may appear out of or disappear into the workshop's ground.

FIG. 28 is a process flow diagram illustrating an automatic zooming operation according to some embodiments. In some embodiments, the view generating engine 32 and the rendering engine 24 performs some or all of the process flow. This process uses an invisible boundary called outer frame that, when crossed by a grown assembly, causes the stage to zoom out automatically. It also uses an invisible boundary called inner frame that, when a shrinking assembly ends up fitting into this frame, causes the stage to zoom in automatically. Note that the current extent may fully enclose the object; it may also be defined to include only part of the assembly, such as include some visible fraction of each assembly to as to keep them in reach, while part or most of the respective assembly may be located off-screen this way. In various embodiments, the system 100 may use different criteria for triggering automatic zooming, such as lines crossed, percentages of an assembly inside or outside or areas, certain surfaces on assemblies being located inside or outside certain areas etc. While many embodiments will trigger automatically after the completion of a manipulation, in other embodiments, the system 100 may (also) trigger automatic zooming at other times, such as when a tool is being selected (so as to accommodate the use of that respective tool).

FIG. 28 is a process flow diagram illustrating an automatic zooming operation according to some embodiments. At 2602, 3D editor 100 obtains assembly manipulation information. At 2604, 3D editor 100 computes the current extent of the rendering of the scene. At 2606, 3D editor 100 determines whether current extent reaches outside the outer framing of the scene. If the determination at 2606 is that the current extent reaches outside the outer framing of the scene, 3D editor 100 calculates at 2607 the rendering data for zooming out the scene. At 2608, 3D editor 100 renders the scene. Otherwise, if the determination at 2606 is that the current extent does not reaches outside the outer framing of the scene, 3D editor 100 determines at 2609 whether the current extent is fully contained in the inner frame. If the determination at 2609 is that the current extent is fully contained in the inner frame, 3D editor 100 calculates at 2610 the rendering data for zooming in the scene, and renders at 2608 the scene. Otherwise, if the determination at 2609 is that the current extent is not fully contained in the inner frame, 3D editor 100 renders at 2608 the scene.

Some devices may offer additional view management features. For example, some mobile devices, such as phones and tablets, etc. may allow users to rotate the view by rotating the screen between a portrait and a landscape orientation. Some embodiments may implement this in a “transparent” way, i.e., so that the arrangement and visibility of contents of the stage is affected as little as possible. Other embodiments may use this to allow users to intentionally view contents up-close, e.g., by zooming in, e.g., also to switch between a view that contains editor and additional contents, such as a repository, to an isolated view of the editor.

Some embodiments may offer ways of rearranging assemblies on stage. This may be triggered manually by the user, e.g., by pushing a button, performing a gesture, etc. or automatically by the system. In some embodiments, for example, the 3D editor 100 may move assemblies closer together in order to allow the system to zoom in the stage. In other embodiments, the 3D editor 100 may rearrange objects to keep them visible, e.g., by moving them out from being fully or partially occluded by another assembly or from being fully or partially off screen. Such embodiments typically determine patches of empty space in 2D screen space, map them back to 3D world space, and the move assemblies to an appropriate empty patch, e.g., by considering which patch is closest.

### 5.5.2. (Non)-Animation

Exaggerated realism. So far strategies for creating systems that behave realistically have been described. In contrast, some embodiments may choose to exaggerate realism for additional visual clarity or to attract an audience with an affinity for this type of effect, such as video gamers, kids, cartoon readers, or simply people who like the style. Embodiments may, for example, implement cartoon-like physics effects [Bay-Wei Chang, David Ungar. Animation: From Cartoons to the User Interface. In Proc. UIST 1993] to emphasize animation with anticipation, follow-through, objects stretching when being accelerated or falling lower-parts-first, parts subjected to forces deforming or disassemble temporarily, etc. The option to render using exaggerated realism applies to all interactions and effects described in this disclosure.

Fast, cartoon-like transitions. Along the same lines, some embodiments may employ a cartoon-like style for rendering movement in the 3D editor 100, i.e., those transitions that could also be animated. These embodiments move objects quickly (often immediately or in real-time, i.e. within a fraction of a second) using the technique described in [Patrick Baudisch, Desney Tan, Maxime Collomb, Dan Robbins, Ken Hinckley, Maneesh Agrawala, Shengdong Zhao, and Gonzalo Ramos. 2006. Phosphor: explaining transitions in the user interface using afterglow effects. In Proceedings of the 19th annual ACM symposium on User interface software and technology (UIST '06). ACM, New York, N.Y., USA, 169-178. DOI=http://dx.doi.org/10.1145/1166253.1166280], i.e., they show some sort of fading trail to inform users about the transition that just took place.

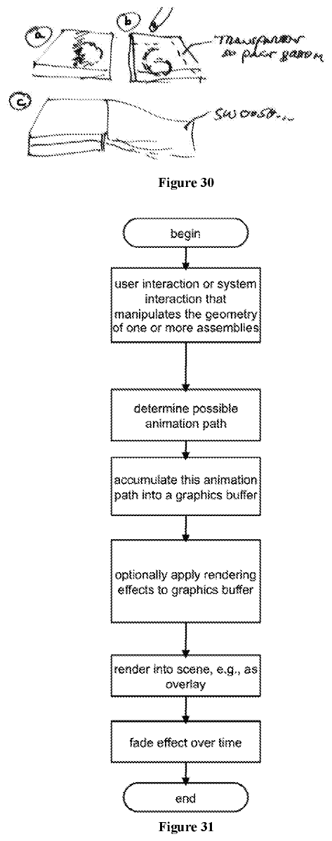

FIG. 30 is an isometric view illustrating an example that illustrates the use of afterglow effects in the editor in order to achieve fast transitions according to some embodiments. The user is assembling two parts using a gluestick-based stacking tool. (a) The user paints virtual glue onto one assembly using a “glue stick” tool, and then (b) applies matching virtual glue onto another assembly. (c) The moment the user completes the second “glue stick” interaction, the second assembly transitions towards its position on top of the first assembly (some embodiments may implement it the other way around, i.e., the first assembly transitions towards the second assembly). Some embodiments may animate the assembly, a process that inherently consumes a certain amount of time. The shown embodiment, in contrast, instead translates the second part immediately and or quasi immediately and instead of the animation shows an translucent trail illustrating the path the second assembly might have taken, had it been animated. This trail disappears after a while, e.g., by fading.

The benefit of this type of style of rendering movement is that is avoids slowing users down, as traditional animation techniques do. Some embodiments will complement the transition with appropriate sounds. This style of visualization can be applied to all interactions or system actions that could otherwise be rendered using animation. In contrast, this approach is less useful for interactions that inherently “animate” such as dragging.

FIG. 31 is a process flow diagram illustrating the operation of rendering with realistic effects according to some embodiments. In some embodiments, the effects generating engine 12, the view generating engine 32 and the rendering engine 24 performs some or all of the process flow. At 3001, 3D editor 100 detects a user interaction or system interaction that manipulates the geometry of one or more assemblies. At 3002, 3D editor 100 determines a possible animation path. At 3003, 3D editor 100 accumulates the animation path into a graphics buffer. At 3004, 3D editor 100 applies rendering effects to the graphics buffer. The rendering at 3004 not performed in some embodiments. In one embodiment, the rendering may be user selectable. At 3005, 3D editor 100 renders the effects into a scene, for example, as an overlay. At 3006, 3D editor 100 fades the effect over time.

### 5.5.3. Alignment: Space Curvature

The concepts disclosed in this section apply to generic 3D editors as well as to those 3D editors that target one or more specific fabrication machines.

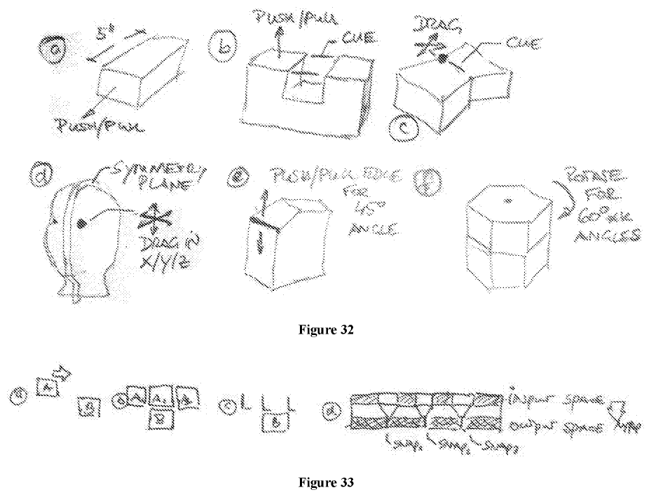

Non-modal Alignment. Alignment plays a key role in 3D editing (and in particular in those systems aiming at fabrication). For example, users may want to create a move two plates so as to add a joint, the two plates need to attach directly edge-to-edge. FIG. 32 is an isometric view illustrating a few examples of situations that require alignment in 3D, such as translation, rotation, and scaling. Space curvature can be applied to any n-dimensional manipulation that requires precision at certain discrete values, including translations, scaling, rotations, skewing, deformation, control point manipulation, handle-based manipulation, etc. There are similar examples in 2D, 1D, and also in higher dimensions. These situations emerge with any type of input devices, including 1D, 2D, 3D and higher DoF, such as 6 DoF controllers.

In 3D editors, alignment has traditionally been achieved with the help of (magnetic) snapping [Eric Bier. Snap-dragging in three dimensions. In I3D '90 Proceedings of the 1990 symposium on Interactive 3D graphics, pp. 193-204] and some embodiments of the present invention may implement this approach. Magnetic snapping translates or rotates an assembly as soon as the user has moved it closer to that snap position than a certain epsilon, such as closer than 10 pixels (or 5 mm) or closer than 5 degrees of rotation.

Traditional snapping, however, is limited in that that it makes it impossible to close-to-align two assemblies, as they would snap together as soon as they get close enough. Thus traditional snapping tends to be accompanied by a mechanism for deactivating snapping; in Microsoft Office applications, for example, snapping can often be deactivated by holding down the <Alt>-Key. Alternative approaches (e.g., on computers that do not offer a keyboard) include the use a gesture or GUI button instead. Any and all of these, however, require users to learn the respective interaction and thus tend to result in a learnability/discoverability hurdle—sometimes to the extent that many users never (bother to) find out about this option.

Some embodiments may therefore instead use an alignment method not based on magnetic snapping, but on temporarily stopping a dragged assembly (snap-and-go [Patrick Baudisch, Adam Eversole, Paul Hellya. System and method for aligning objects using non-linear pointer movement. U.S. Pat. No. 7,293,246 B2. Nov. 6, 2007]). This technique designed for use with mice and other indirect input devices temporally slows down a dragged object to a speed of zero while in alignment, making it easy to align because the technique effectively enlarges the position corresponding to the aligned position in the space of the input device. Unfortunately, snap-and-go only works for indirect input devices, such as mice.

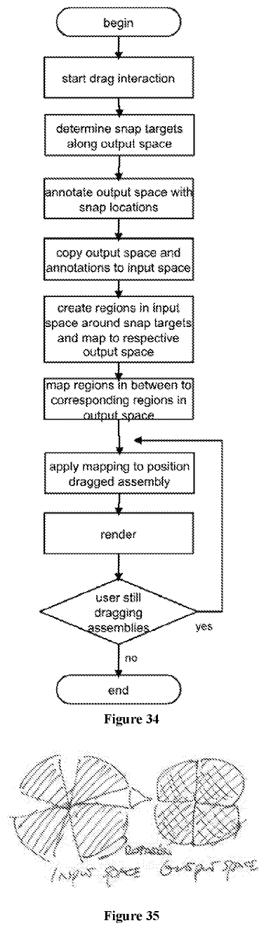

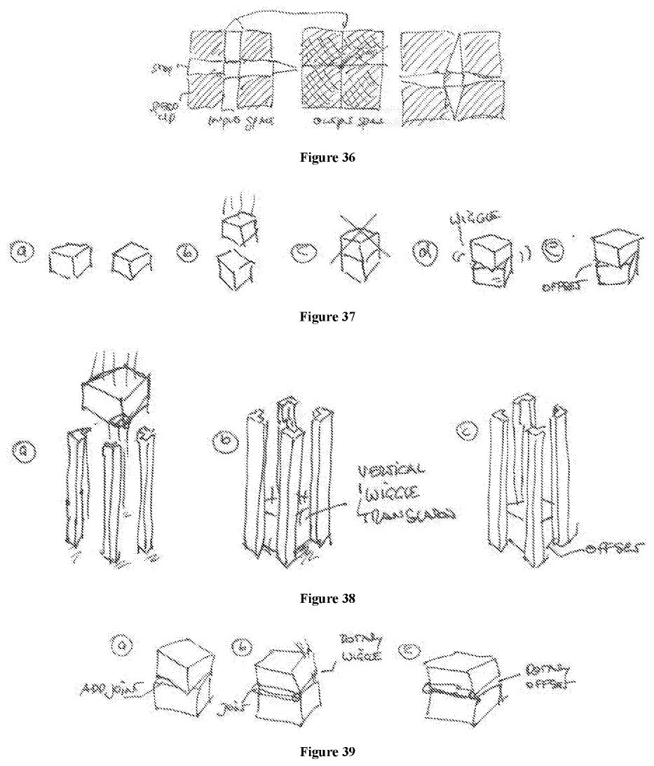

The inventive concept, which is referred to as a space curvature, includes a novel alignment method that works not only with indirect input devices, but also with direct input devices, i.e., devices that establish a 1:1 mapping between input space and display space, such as touchscreens/direct touch, pen/stylus input, virtual reality controllers, etc. As used herein, screen space is also referred to as output space. As illustrated by FIG. 33, FIG. 35, FIG. 36, and FIG. 34, space curvature slows the dragged assembly down to speed zero while in alignment with the snap target, and then speeds up the dragged assembly on its way to the next snap location.

One way of implementing space curvature is by determining the space of intended output positions and map them to the space of possible input positions. FIG. 33 illustrates this for alignment along one dimension of translation, here along the horizontal axis. (a) The user drags assembly A horizontally towards/past an assembly B. (b) In this particular embodiment, the system wants to make it easy to place A in the three positions shown, i.e., align A's right edge with B's left edge, align both assemblies fully, and align A's left edge with B's right edge (here A and B are of equal size; if they were not, the embodiment may generate additional snap targets for left- and right edge alignment). (c) This results in three snap targets for (here illustrated with reference to A's left edge. (d) Space curvature resolves this by mapping the space of the input device to the output space of the dragged assemblies as shown. In particular, the system maps areas of a certain width (here shown in white) to the respective snap locations, making these easier to acquire. To make up for the “lost” space, the system maps the remaining input range to the output space between snap targets. In FIG. 33 white rectangle denotes pointer stops/snap locations, hatched areas denote regions in which dragged assemblies are sped up, and cross hatched areas demote regions in output space. FIG. 34 explains the algorithm.

What users thus see is that a dragged assembly stops at a snap target, then lags behind as the input device, such as the user's finger already continues on, then starts to move slightly faster than the input device until it catches up and gets ahead of the user's input device. The assembly thus reaches the next snap position before the input device and stops again.

Each individual snap targets can be given a different “intensity”, i.e., a different size in input space. The bigger that intensity/size the easier the snap target will be to acquire. Some embodiments may thus choose to assign intensity/sizes according to how likely a target is to be acquired or according to how important it is to avoid the respective type of user error. In one application scenario, the system 100 may complement a tool that scales assemblies with space curvature making is very easy to scale the assembly to integer sizes in terms of centimeters and to a lesser extent to integer sizes in terms of millimeters.

Ideally, space curvature receives “raw” input from the input device (as opposed to input already rounded to the closest pixel), i.e., with input precision in the sub-pixel range, as this makes sure that all positions remain accessible.

FIG. 34 is a process flow diagram illustrating the operation of space curvature on a single dimension input according to some embodiments. In some embodiments, the tool box engine 16 and the rendering engine 24 perform some or all of the operations of the process flow. At 3201, 3D editor 100 starts a drag interaction in response to a user input. At 3202, 3D editor 100 determines the snap targets along the output space. At 3203, 3D editor 100 annotates the output space with the snap locations. At 3204, 3D editor 100 copies the output space and annotations to an input space. At 3205, 3D editor 100 creates regions in the input space around the snap targets and map the regions to respective regions in the output space. At 3206, 3D editor 100 maps regions in between two corresponding regions in the output space. At 3207, 3D editor 100 applies the mapping to the position of the dragged assembly. At 3208, 3D editor 100 renders the position dragged assembly into a scene. At 3209, 3D editor 100 determines whether the user is still dragging the assembly. If the determination at 3209 is the user is still dragging the assembly, 3D editor 100 returns to the applying the mapping at 3207. Otherwise, if the determination at 3209 is the user is no longer dragging the assemblies, 3D editor 100 ends the drag process.

FIG. 34 is a plan view illustrating a non-modal alignment technique using space curvature according to some embodiments.

Unlike magnetic snapping, space curvature never causes dragged assemblies to perform any jerky movements. Some embodiments may still add emphasis to certain moments in the interaction, such as the moment an assembly aligns itself. Some embodiments may add a shake effect resembling magnetic snapping; other embodiments may use other channels, such as sound or visual stimuli, haptic, etc.

FIG. 35 is a plan view illustrating space curvature at the example of 1 DoF rotation, in particular the input-to-output mapping, according to some embodiments. In this particular example, there are four snap targets at 0, 90, 180, and 270 degrees. (a) Input space mapped to (b) Output space. This means, when the rotation angle lies within the white sectors, the assembly stays aligned with the respective (rotary) snap location; in between, the manipulated assembly catches up, then spins ahead, until it reaches the next snap target.

FIG. 36 is a plan view illustrating space curvature, more specifically its input-to-output mapping, for translations with two degrees of freedom, according to some embodiments. (a) Snap target that fills an entire row of a certain height and an entire column of a certain width, maps to (b) output space (using trivial rectangle-to-rectangle mapping, which can be accomplished by translation and scaling of input. (c) A “local” 2D snap target formed by the white regions tapering off away from the snap target. Mapping the hatched regions to the rectangles in (b) can be accomplished using several different mapping. One approach is to split up both spaces into triangles (and be done radially or orthogonal to that) and then map triangle to triangle, which can be accomplished with a unique mapping. Another approach is a perspective transform/homography. When multiple snap locations are present, their effects add up.

Space curvature for higher dimensionalities works in direct analogy to the algorithms described in 2D. The same way 2D space curvature maps rectangles or quadrilaterals to rectangles, 3D space curvature maps cubes or cubes with an indented corner to cubes, and so on, such as, hyper cubes to hyper cubes or hyper cubes to hyper cubes with an indented corner in 4D.

The mapping behind space curvature can also be implemented as a sequence of separate steps—one for each dimension. In 2D, for example, such a “dimension-by-dimension” implementation might first align x and then align y. In FIG. 36, two cases are described, i.e., first alignment with a row and column and second alignment with a point. Starting with the row and column version, a dimension-by-dimension algorithm first aligns a first dimension, such as translation in x (using the algorithm described in FIG. 34). This maps an input (x/y) coordinate to an x-aligned x/y coordinate. Now the algorithm feeds this x-aligned x/y coordinate into a second space curvature mapping that handles the y-alignment (again using the algorithm described in FIG. 34), returning an x/y aligned coordinate.

In a similar fashion, alignment in rotation and translation can be combined by concatenating the two mappings, i.e., the output of the first becomes input to the second.

For the point alignment version, perform the two alignment steps are performed separately, but the non-aligned x/y coordinates are also kept, so the final stage now has four x/y pairs as input. The algorithm now determines the how offset the alignment method has produced in each dimension and use one to limit the other.

The space curvature algorithm, as described above, leads to a slight jerkiness when manipulating an assembly, as the algorithm causes a repeated stop-and-go. For applications where a smooth appearance is preferable, certain embodiments may therefore instead implement patent space curvature with a “delayed” update mechanism. As users manipulate the assembly (here at the example of scaling), the size of assembly on screen adjusts continuously and only the attached (numeric or symbolic) scale display updates in the expected stop-and-go fashion. Users adjust the size of the assembly with an eye on the scale display and when the desired value is reached they stop. The scale display now shows the intended value; however, the scale of the actual assembly on screen will in most cases be inaccurate. The system 100 therefore adjusts the geometry to match the value suggested by the scale after the interaction ends. The system 100 may do so right as the interaction ends or at a later, less conspicuous moment, e.g. faded slowly over time, at the beginning of the next manipulation of that assembly, the manipulation of some other assembly, etc.

This approach may be used to help users acquire small targets, e.g., when the user touches the screen, drags one or more fingers across the screen or uses any other type of pointing input. Acquiring a small target is equivalent to aligning the pointer or finger etc. with the target and this can be achieved by applying the algorithm disclosed above to the pointer or finger etc. position.

### 5.5.4. Non-Alignment

Visualizing (non) alignment. It is often important for users to know whether or not two sub-assemblies in an assembly are indeed aligned. Some embodiments may follow a traditional approach and visually explain alignment. If the left edges of two parts happen to be aligned, for example, some embodiments may, for example, connect these two edges with an additional line. However, such lines and similar displays tend to clutter the display—especially when there is a lot of alignment (as tends to be the case with certain fabrication machines, such as laser cutters, etc.). This clutter may make it harder to understand a scene.

An alternative approach that inverts the design problem: rather than illustrating alignment is proposed that illustrates non-alignment (which may be refer to as Heisenberg misalignment). The respective embodiments do so as follows. If two assemblies were aligned explicitly (using an explicit alignment tool or a tool manipulates assemblies that aligns them as a side effect of the interaction), then these embodiments renders them as aligned. Otherwise, however, these embodiments visually exaggerate the (potentially tiny) offsets to visually clarify the non-alignment. One way of achieving this is to make the rendered version not correspond to the data model. In such an embodiment, the on-screen rendition of a non-aligned assembly will look different (i.e., more extreme) than, for example, the export of the same assembly to a fabrication device.

Alternatively, and maybe more commonly, the same approach is used to show whether two collocated sub-assemblies form a single (connected) assembly or whether they are two separate assemblies that just happen to be collocated. In the example shown in FIG. 37 is an isometric view illustrating the visualization of non-alignment according to some embodiments. A user tries to stack (a, b) two assemblies. (c) Since the assemblies are not connected, the assembly on top will resist aligning itself with the assembly below. (e) Instead, it will always come to rest in a position with their edges misaligned. Different embodiments may choose different types of misalignment, such as yaw, tilt/roll, horizontal offset, vertical offset, or some combination thereof. (d) Right after letting the top assembly go, the assembly on top may “wiggle” to emphasize the non-alignment, i.e., go back and forth along its misaligned dimension(s). The assembly on top may achieve the space necessary for wiggling along certain degrees of freedom, for example, by hovering a little bit above the assembly below. As the wiggling decreases, the assembly on top may then slowly sink down further and (e) either come to rest with a tiny bit of a vertical offset or flush against the object below if another degrees of freedom can be used to communicate non-alignment—here the rotary offset (yaw).

All of these effects can be thought of and visualized as repulsive forces between the two assemblies and with a certain amount of damping. The wiggling may be actual animation or may be implemented fully or in part using afterglow effects as described above in this disclosure. While this approach makes assemblies appear misaligned, in their internal data model the assemblies scene graph may (while unlikely) actually happen to be aligned; one way of achieving this effect is to introduce the misalignment when rendering the scene graph.

FIG. 38 is an isometric view illustrating a non-alignment in a confined contraption according to some embodiments. The figure shows a box dropped into a square “tube” (this contraption is made of four guides), which confines all of the assembly's degrees of freedom except vertical translation An embodiment might communicate that the assembly is not physically connected to the ground by making it wiggle up and down (as it cannot wiggle along any of the other dimensions) and, when the assembly comes to rest, it may continue to float above the ground by a tiny bit. That said, the ground is generally not part of any assembly, so showing non-connectedness will typically not be necessary and most embodiments will choose to simply drop the assembly. However, if additional assemblies are dropped into the tube they may demonstrate the wiggling and floating behavior. If yet additional assemblies are dropped into the tube, this may restart the wiggling of assemblies below. Some embodiments may also (partially) compress vertical offsets below with their weight. Wiggling and coming to rest may play again when an assembly is moved or when something bumps into it.

As illustrated by FIG. 39, which is an isometric view illustrating non-alignment with a hinge according to some embodiments, the 3D editor 100 constrains offsets and wiggling when objects are connected/mounted onto one another. (a) This example starts with two separate assemblies, here boxes. (b) When the user connects the box on top with the box below using a hinge, the rotary yaw offset between the two boxes goes away, i.e., both boxes are now visibly aligned in yaw; if there should have been an offset in translation before, also that now disappears. The only degree of freedom that is not logically aligned right now is rotation around the hinge, i.e., tilt and so the resulting assembly responds by this degree of freedom wiggling in order to illustrate its non-alignment. The top box therefore wiggles in terms of flapping open/close, as if a spring was preventing it from fully closing. (c) The box could come to rest closed, but since there is no other way to show its non-alignment, some embodiments will let it come to rest still slightly open.

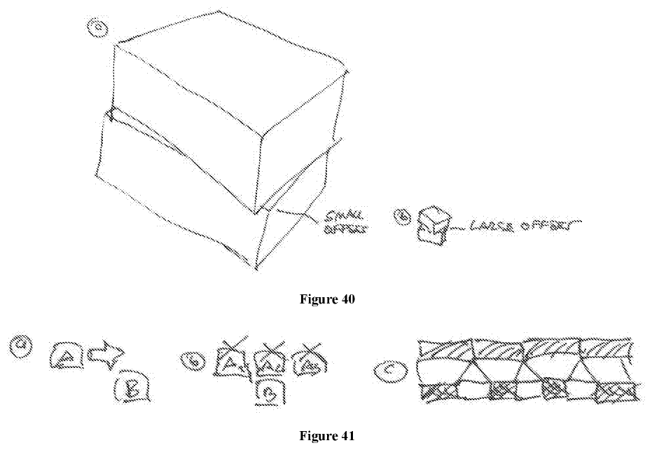

There are many different possible strategies for determining the size of offsets. FIG. 40 is an isometric view illustrating offsets for non-alignment according to some embodiments. The figure illustrates one strategy that chooses the size of the offsets so as to make the offset as small as possible, i.e., to produce as little misalignment as possible, while still making the misalignment clearly visible. This results in (a) small offsets for large assemblies or assemblies shown up-close, and (b) larger offsets for assemblies that are shown at a small scale (e.g., as part of a suggestive interface, see below). For some embodiments, the offset may thus change during scaling (this may be hidden by wiggling the object again, which is plausible, giving the presumed motion). Similar during zooming.

There are multiple ways for implementing non-alignment. One approach is to simply determine the degrees of freedom and animate along those. Another approach is to insert appropriately chosen springs into the model and let a physics engine or something similar perform the animation. In assemblies that contain sequences of multiple non-aligned objects, e.g., a stack multiple boxes high, some embodiments prevent offsets from accumulating by choosing offsets in alternating directions. In this and all subsequent examples, wiggling may be implemented using traditional animation or by rendering a trail, as discussed earlier, or any combination thereof.

FIG. 41 is a plan view illustrating non-alignment with repulsive forces according to some embodiments. In one embodiment, the system 100 that implements non-alignment using a variation of the non-modal space curvature alignment algorithm presented above, i.e., using a similar algorithms, but with repulsive, instead of attractive forces. (a) The user is moving block A horizontally and the system (b) wants to prevent it from aligning with block B. (c) The user achieves this by mapping the “input space”, i.e., the position of the pointing device (shown on top) to the “output space”, i.e., the horizontal position where object will be placed. Note the inserted blank, thus unreachable regions of output space. The same approach applies to rotation and multiple degrees of freedom else discussed elsewhere in this disclosure. Similar effects can be achieved by “inverting” other snapping methods, such as traditional magnetic snapping, such as variants of traditional magnetic snapping, but with repulsion instead of attraction.

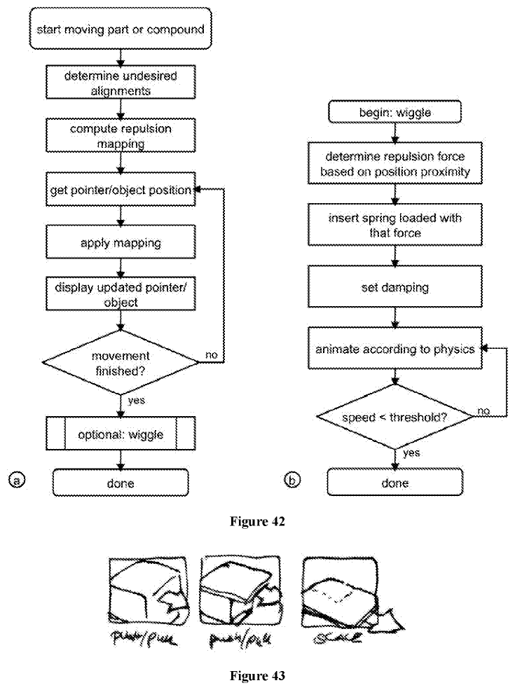

FIG. 42 is a process flow diagram for non-alignment and wiggling according to some embodiments. In some embodiments, the tool box engine 16, the movement engine 20, and the rendering engine 24 perform some or all of the operations of the process flow. For non-alignment, at 4301, 3D editor 100 detects moving of parts or components. At 4302, 3D editor 100 determines undesired alignments. At 4303, 3D editor 100 computes repulsion between parts or components. At 4304, 3D editor 100 gets a pointer or object position. At 4305, 3D editor 100 maps input space to output space. At 4306, 3D editor 100 applies the map. At 4307, 3D editor 100 displays the updated pointer or object. At 4308, 3D editor 100 determines whether the movement is completed. If the determination at 4308 is that the movement is not completed, 3D editor 100 continues to get the pointer and object position at 4304. Otherwise, if the determination at 4308 is that the movement is completed, 3D editor 100 may optionally perform a wiggling operation at 4309.

If, at 4309, a wiggling operation is to be performed, 3D editor 100 determines at 4320 the repulsion force based on position proximity. At 4321, 3D editor 100 inserts a spring that has the determined repulsion force. At 4322, 3D editor 100 sets damping. At 4323, 3D editor 100 animates the scene according to physics. At 4324, 3D editor 100 determines if the speed is less than a threshold. If the determination at 4234 is that the speed is not less than the threshold, 3D editor 100 continues to animate at 4323. Otherwise, if the determination at 4234 is that the speed is less than the threshold, 3D editor 100 ends the wiggling operation.

5.5.5. Non-Grouping with Compounds

Functionality for compounds. Compounds of the present invention are assemblies that offer additional functionality on the assembly as a whole. Examples include joints and mechanisms. A box consisting of six rectilinear plates connected with finger joints along all sides, may be considered a compound as well if we add additional functionality, such as allowing the entire assembly to scale along one or more of its principal axes, causing four of its plates to all scale at the same time and four of the finger joints to be recomputed so as to fit the new dimensions, etc. Other compounds may offer this type of scaling functionality as well.

FIG. 43 is a diagram illustrating scaling using a push/pull tool according to some embodiments. Scaling an object along one or more dimensions can be accomplished using many other approaches, such as by means of one or more handles attached to the assembly/compound.

This type of “box-specific” functionality can be made available explicitly by defining that this compound is a box (either by importing the compound pre-grouped as a box or by selecting the six plates and “grouping” them (or pick some sort of “define object” function as done, for example, in Macromedia Flash Version 2), allowing the system to apply its box-specific functions.

Another approach is to perform the grouping automatically. Any two parts physically connected by a joint or mechanism, for example, suggest that the two parts have a relationship to each other, thus may be manipulated together. This explicit approach can lead to difficulties (1) with inexperienced users who may struggle with the concept of grouping/models organized in the form of hierarchies. In particular, users may construct compounds from individual parts (e.g., a box by assembling six sides) and the compound functionality never becomes available. (2) When compounds have to be ungrouped in order to customize them, causing the special compound functionality to disappear.

Implicit “bottom-up” compounds functionality Some embodiments therefore implement the additional compound functionality in an implicit way. Objects are only “loosely” assembled from parts. When users try to manipulate an assembly/compound, a set of specialized filters (one for each type of additional functionality) analyze the object (either at this moment or earlier and cache results). Each filter determines whether its pre-requirements are met and if so offers its functionality. Example: A five-sided box, i.e., a box with no top. When scaling the box by pulling one of the sides outwards, a filter determines that there are other connected parts and scale these connected parts accordingly [Eric Saund, David Fleet, Daniel Lamer, and James Mahoney. 2003. Perceptually-supported image editing of text and graphics. In Proceedings of the 16th annual ACM symposium on User interface software and technology (UIST '03). ACM, New York, N.Y., USA, 183-192. DOI=http://dx.doi.org/10.1145/964696]. (Additional example: assembling six plates so that they form a box, scaling this box down may convert the box to a stack of plates).

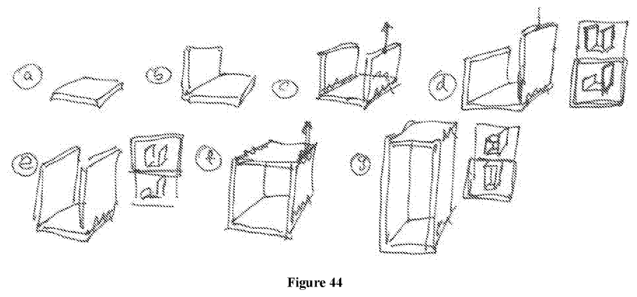

FIG. 44 is a process flow diagram illustrating a bottom-up compound operation according to some embodiments. In some embodiments, the movement engine 20 and the rendering engine 24 performs some or all of the process flow. At 4401, 3D editor 100 detects the user is starting to manipulate part of an assembly. At 4402, 3D editor 100 runs filters on the assembly and the entire scene to assess how similar respective parts and subassemblies are to the assembly that is being manipulated. At 4403, 3D editor 100 selects a part or subassemblies with similarities above a threshold. At 4404, 3D editor 100 determines whether the part or subassembly can undergo the current type of manipulation. If the determination at 4404 is that the part or subassembly can undergo the current type of manipulation, 3D editor 100 adds at 4405 the part or subassembly to the selection. At 4406, after 4405 or if the determination at 4404 is that the part or subassembly cannot undergo the current type of manipulation, 3D editor 100 determines whether there are more parts or subassemblies to be selected. If the determination at 4406 is that there are more parts or subassemblies to be selected, 3D editor 100 continues selecting at 4403. If the determination at 4406 is that there are not more parts or subassemblies to be selected, 3D editor 100 continues at 4407 manipulating the extended set.

### 5.6. Targeting Specific Fabrication Machines

As discussed earlier, some embodiments of the inventive concept increase ease-of-use by limiting their functionality to specific classes of personal fabrication machines, such as laser cutters. Many such devices do not allow fabricating arbitrary 3D models, but only a reduced set, such as 3D models assembled from flat plates, in the case of 3-axis laser cutters. The present invention exploits the limitations imposed by the fabrication machine by offering appropriately reduced functionality, aimed at matching what the fabrication device is capable of creating. In some sense, the present invention builds on editors for construction kits (e.g., MecaBricks); unlike construction kits, however, the “parts” are user-defined within the constraints of the targeted fabrication machines. While most functions of the present invention are illustrated at the example of a 3-axis laser cutter or compatible device (plasma cutter, water jet cutter, in some cases milling machines etc.), the inventive contributions in this section apply to other fabrication machines as well.

### 5.6.1. Calibration

Calibration. Some machines are subject to calibration. Laser cutters for example may burn a certain amount of material during cutting (aka “kerf”). To make sure that objects fabricated by the system, embodiments may allow calibration tools. FIG. 46 is a diagram illustrating a test strip calibration tool according to some embodiments. Users fabricate the test strip, try out which hole the pin fits into best, and enter the ID of that hole back into the system, e.g. using a GUI dialog. The system 100 then re-computes the object so as to obtain the best fit for this particular calibration, i.e., so that joints etc. in subsequent fabrication cycles have the right tightness.

Similarly, embodiments may offer a test strip for determining cutting intensity. The strip contains holes to be cut with different intensities (power settings and/or speed). Users fabricate the strip, find out which holes actually cut through, and enter the ID of the weakest one that still cut all the way through (or the strongest that failed etc.) into a GUI dialog. This allows the system to calibrate the power settings of subsequent cuts by simply using the weakest setting that still cut (plus an optional fudge factor).

Changing material thickness. When designing an assembly and then changing the material thickness, some dimensions of the assembly may change. In the case of a box, for example, the space inside of the box may change, the outer size of the box may change, or any combination thereof. In various embodiments, the 3D editor 100 may ask or guess whether the user prefers the additional material to grow away from the inner surface (so as to preserve the inner diameter of boxes etc., relevant, e.g., when storing certain-sized objects inside) or outer surface (so as to maintain fit into an external enclosure), or around the middle of the material etc. (e.g., for centered parts), or any other combination. The 3D editor 100 may try to guess based on scene geometry. The 3D editor 100 may also disambiguate by asking the user. Different embodiments may offer such functionality also in the form of various change thickness tools that either changes insides or outsides, etc.

### 5.6.2. Importing 2D Representations of 3D Models

As discussed earlier, one way of creating 3D objects is by fabricating parts from material that is largely two-dimensional and then assembling these parts into the 3D object. Such 2D parts will typically be fabricated using two or three-axis subtractive devices, such as certain types of laser cutters, knife-based cutters, water jet cutters, plasma cutters, scissors, CNC milling machines, etc. However, this approach may also be used with other fabrication methods, such as additive methods including 3D printing, if these are used to make largely flat parts (e.g., to reduce the use of support material, to fabricate faster, to make larger objects, etc.).

As discussed earlier, the most convenient way of manipulating the models describing 3D objects to be fabricated using a 2-3 axis laser cutter etc. is by means of manipulating a 3D representation of the model, e.g., in a 3D editor.

Unfortunately, such a 3D model may not always be available. Instead, especially in shared repositories, models for laser cutters etc. are most commonly (designed and) shared in 2D formats (e.g., G-Code or .svg). Such formats describe models in the form of a cutting path across a 2D plane, as this is what the fabrication machines are able to execute. This may, for example, be described at the lowest possible level, i.e. G-Code, which actually tells the machine where to move its tool head, etc. G-Code tends to be hard to view and manipulate for humans, though. To make such 2D models slightly easier for humans to view and manipulate, they tend to be edited and shared in line drawing or vector graphics formats (e.g., encoded using the .svg file format, or the file formats of Adobe Illustrator, InkScape, OpenDraw, PowerPoint, etc.). As someone skilled in the art would appreciate, such 2D line formats can be converted back and forth to a G-Code (e.g., by the fabrication machine's printer driver), which allows using 2D drawing formats almost interchangeably with G-Code. Still, editing in any 2D format is difficult, as it requires users to mentally decompose the 3D object to be created into two dimensional parts.

To address the issue of models for 2-3 axis fabrication machines often being shared in 2D formats, while they would be easier to edit in 3D, we propose a method for converting 2D representations of 3D models for laser cutting etc. to 3D representations. Our algorithm implements a multi-stage pipeline that includes, among others, a conversion of 2D drawings to parts, auto assembly of those parts as far as possible, optional artificial intelligence steps that try to guess how to best resolve ambiguity, and a final resolution of ambiguity by user interaction.

Ultimately, this 2D import combines with 3D editing and 3D export into the workflow shown in FIG. 47. The typical workflow in the diagram is to maintain the 3D model and make all changes based on it. However, as shown using the dashed arrow, the system also allows re-importing exported models.

The physical assembly creates non-planar (aka “three-dimensional”) physical objects. This is accomplished by folding, bending, extruding, etc. flat parts or by assembling multiple flat parts, e.g., stacking, gluing, screwing, welding them, or by joining parts using appropriate types of joints, such as snap fits, press fits, etc.

The 3D editing step will typically take place interactively in a 3D editor, such as the one described throughout this disclosure. Alternatively, users might manipulate 3D models using other means, such as script.

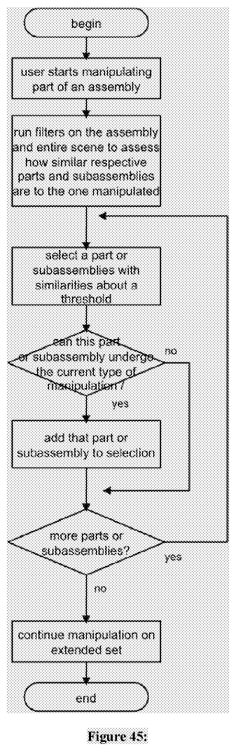

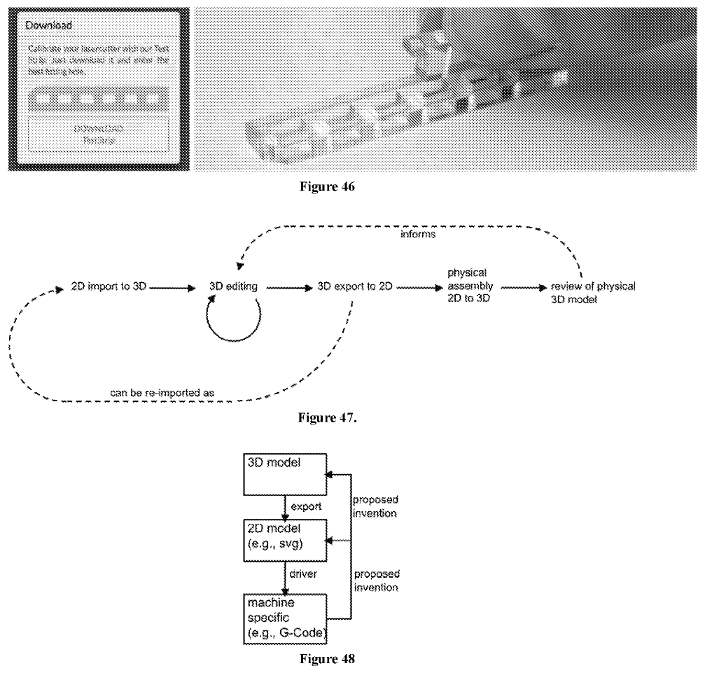

During 3D export to 2D, such 3D models can then be (automatically) converted to a cutting path, as represented e.g., in G-Code. This may be accomplished through an intermediate 2D representation (as illustrated by FIG. 48) or directly in a single step. This “downwards” conversion tends to be straightforward. The 3D-to-2D conversion has, for example, been implemented by FlatFab [Online Version as of Jul. 7, 2017]. The 2D-to-machine-specific conversion may, for example, be part of the driver software of the respective device (Universal Laser Systems https://www.ulsinc.com).

In the following, we disclose a method for converting 2D representations of 3D models to 3D representations (FIG. 48).

The disclosed conversion process may be performed in full or just parts of it. For example, the import format may be a 2D drawing, in which case we skip the first step of converting the cutting path. Or we may leave out steps at the end and export an in-between data format. We may even skip the automatic part in part or entirely, starting with manual assembly. The algorithm may also perform some steps in alternative orders. The algorithm may, for example, determine material thickness earlier in the process.

### Step 1: (Optional) Cutting Path to 2D Line Drawing

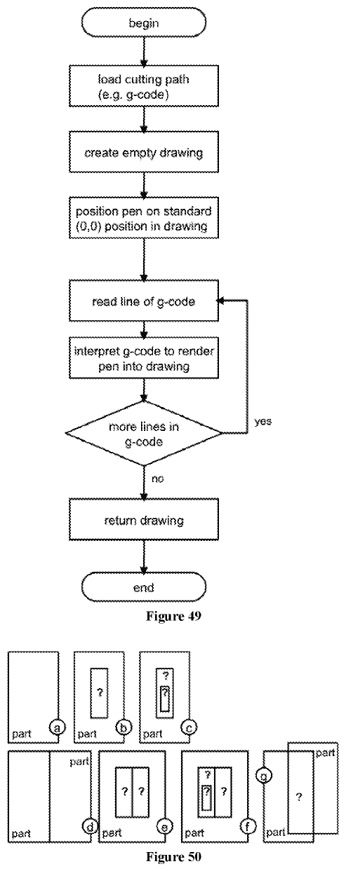

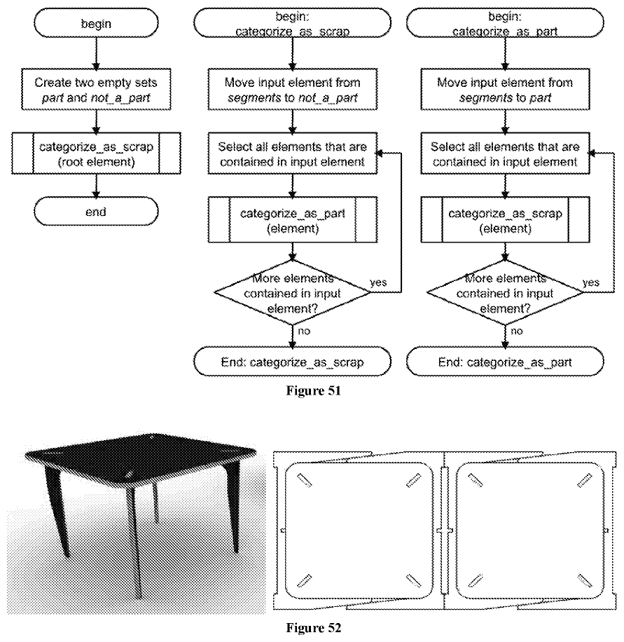

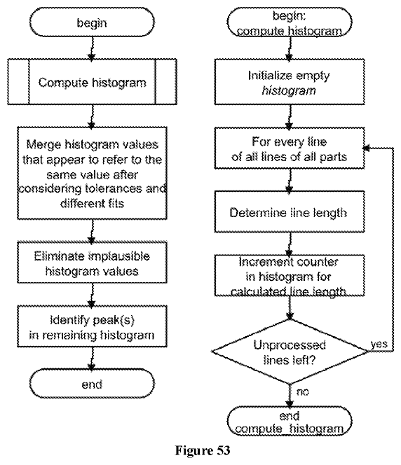

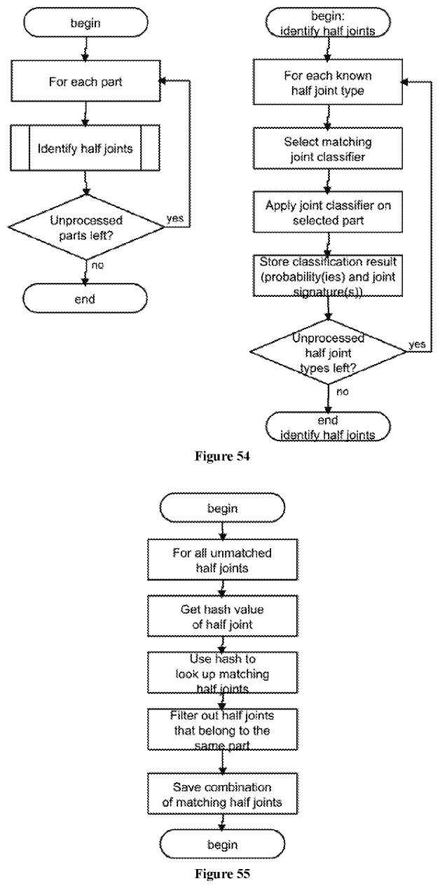

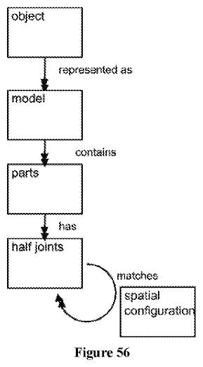

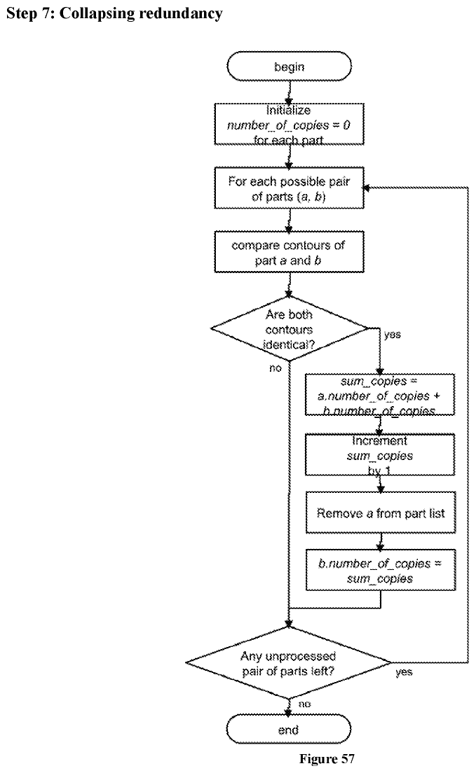

If the model should be in a machine-specific cutting path representation, the proposed invention renders it out into a 2D line drawing. In the case of G-Code, for example, we place a matching brush at some starting point and then move the brush according to the g-code instructions, one at a time, as illustrated by FIG. 49. We implement this by calling the respective functions from one of many publicly accessible g-code libraries, such as https://agataguzik.wordpress.com/2009/09/09/pgcode3d-library-for-processing or renderers, such as http://gcode.ws

### Step 2: Segmentation

The algorithm now converts the line drawing into a set of segments; this set will contain all parts of the 3D model, as well as scrap pieces surrounding the parts. Someone skilled in the art will appreciate that image segmentation is a standard problem and can be solved for line drawings e.g. by tracing connected lines and grouping found closed circles/surfaces as individual segments. The algorithm proceeds as follows: For each segment, store a set of neighbor segments, i.e., the set of all segments it shares at least one line segment with. Sort segments according to their hierarchy in a data structure, which could be a tree structure, where the outermost/biggest segments are located higher in hierarchy than the segments they contain. The algorithm now sorts all top-level segments directly below a root element.

Step 3: Classification of Segments as Parts Vs. Scrap

Next, the algorithm classifies which of these elements are likely to be part of the model and which are likely scrap. FIG. 50 shows possible spatial relationships of segments.

One simple possible algorithm is shown in FIG. 51: (0) Create two empty sets part and not_a_part. Select the root element as the current element (1) Move the current element from segments to not_a_part. (2) if the current element is in not_a_part, move all segments contained in it from in segments to part. (3) If the current element is in part: move all segments contained in it from segments to not_a_part. (5) Repeat steps 2 and 3 recursively for all segments that just have been removed from segments.

This algorithm handles all cases well where objects are laid out without touching (FIG. 50a). It assumes all contours inside of parts (FIG. 50b) to be cutouts/scarp material, not parts. It assumes contours inside of cutouts (FIG. 50c) to be parts again, and so on. All these assumptions hold as long as parts do not share contours. To make these assumptions is reasonable, as humans and typical nesting/layouting software tend to lay parts out this way. As a result, many models tend to segment only into cases FIG. 50a or FIGS. 50a and b.

Humans and software may create shared contours though for the purpose of optimization, i.e., to reduce cutting time and especially material consumption. FIG. 50d shows one possible case of shared contours, where two parts are placed adjacently. FIG. 52 shows another example. Shared contours can lead to misclassifications as they blur the boundaries between what is part and what is scrap.

In order to identify cases of shared contours, as for example in FIGS. 50d and e, the algorithm detects cases where an odd number of segments, such as three segments, are immediate neighbors with each other. When such “cycles” are found, some embodiments notify the user or ask the user to validate/correct the systems classification interactively.

If such a case of doubt, the algorithm may perform additional heuristic tests on each segment, i.e., tests indicating how likely a segment, considered in isolation, appears to be viable as a part. The algorithm may consider any subset of the following features: (a) Segments larger than their neighboring segments tend to be parts, as users and programs tend to minimize scrap. (b) Segments that are identical to segments that have already been classified as parts tend to be parts. (c) Segments bearing engravings tend to be parts. (d) Segments that are largely convex, (i.e., ratio between segment surface and the surface of its convex hull close to one) tend to be parts. (e) Segments with incisions the width of the material thickness (suggest the use of cross joints) and are thus parts.

### Step 4: Guesstimating Material Thickness

The shape of many joints reflects the thickness of the material sheet they are to be fabricated from. The width of the incision that makes a cross joints, for example, is the material thickness. The length of the fingers of a 90 degree finger joint, for example, commonly corresponds to the material thickness.

The following naïve algorithm (flowchart in FIG. 53) exploits the fact that many models contain joints or mechanisms some dimension of which is the material thickness. (1) Compute histogram of line segment length (=For all lines of all parts, determine line length and increment counter of that line length in a line length array or hash) (2) Merge values that appear to be referring to the same value after considering tolerances and different fits. (3) Eliminate implausible values from the histogram, such as thicknesses beyond what commonly available cutters can cut and material thickness not commonly sold. (4) Return the peak(s) in the remaining histogram as candidate(s) for the material thickness(es).

Some embodiments may filter first, i.e., start by creating an array or hash-map of plausible values and then count line segments that have plausible lengths. Thickness estimation can also be run earlier in the algorithm, as early as g-code, which does contain line segments lengths. More elaborate versions of the algorithm limit their analysis to line segments that appear to be part of a joint (see below), which eliminates a lot of noise.

### Step 5: Identifying Half Joints

Next, the algorithm locates joints. Joints are typically inspired by carpentry. Examples of joints include finger joints, cross joints, butterfly joints, in general but not limited to any joints the signature of which involves a combination of outside contour and cutouts, etc. The exact nature of the joints varies by cutting tool.

Our algorithm proceeds by locating contours that suggest a joint (or, rather, one half of it—we will refer to these as half joints). For each joint type, our algorithm implements one classifier, i.e., a piece of code (e.g., a class) that is passed a part and that searches this part for one or more half-joints. A notch joint classifier, for example, may look for straight incisions into an edge of the part. A finger joint classifier may look for notches along an edge.

For each identified potential half joint, joint classifiers return the joint's characteristic parameters, such as the depth and width of teeth and gaps for finger joints. We will refer to these are as a joint's signature, as it may be useful in identifying the matching half-joint.

Joint classifiers may also return an estimated probability that this region actually is a half joint. A long row of finger joints, for example, will return a high estimated probability, as this pattern is unlikely to occur outside of finger joints. A single incision, in contrast, may be part of a notch joint; it may also be part of many other things, so the estimated probability will be lower.

Our algorithm calls each of its joint classifiers on all parts and stores the results for each joint type.

Our algorithm implements joint classifiers by performing matching G-code-like descriptions of the half joint—such as “left, straight, left, straight, right, straight, right, straight, repeat” for finger joints or “right, straight, left, straight by material thickness, left, straight, right” for cross half joints—on the contours of all individual parts.

### Step 6: Matching Half-Joints

Next, the algorithm tries to match joints. Naïve embodiments try to match all possible pairs of two half joints, resulting in a time complexity of O(n²) (with n being the number of half joints found earlier). A more elegant embodiment stores half joints in an appropriate data structure, such as an array sorted by half joint signature for O(n*log(n)) or a hash table for O(n) complexity, by locating only those matches that fit. Contours, such as “right, 1 cm straight, left, 1 cm straight, left, 1 cm straight, right” are easily hashed, e.g., converted first to a string such as R10L10L10R and then hashed. FIG. 55 shows the flowchart.

The matching produces the data structure shown in FIG. 56, the primary contents of which is the set of all matching half joints for every half-joint.

### Step 7: Collapsing Redundancy

The algorithm now clusters identical parts, i.e., it locates parts defined by the same contour, eliminates all but one from the graph joint, and increments the counter of the remaining copy for every copy deleted. Matching contours can be done by matching contours stores as a string with all rotated versions of the other fingerprint (fast algorithms use sub-string searching).

### Step 8: Assembly

The algorithm now searches the joint graph for uniquely defined joints, i.e., pairs that have only a single match (with redundant parts counting as one), and combines these parts into sub-assemblies. Our algorithm proceeds as follows: (1) the algorithm starts with a list of assemblies:=the list of all parts. (2) Iterate over all pairs of assemblies and their half-joints: (3) if there is exactly one match, assemble the two parts, i.e., (4) remove them from assemblies, (5) join the two half joints and (6) add the newly created assembly to assemblies. See flowchart in FIG. 58.

### Step 9: Manual Verification and Assembly

Optionally, the system may start by giving users the opportunity to verify any of the automatic processing steps, such as segmentation and classification. As illustrated by FIG. 59a, the system may show the imported drawing or cutting path with parts highlighted to the user. (b) After the user has verified segmentation and classification, the system removes the scrap (here shown as animating away).

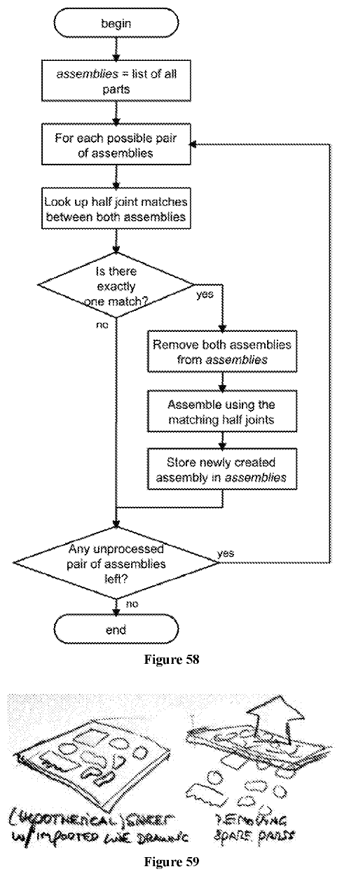

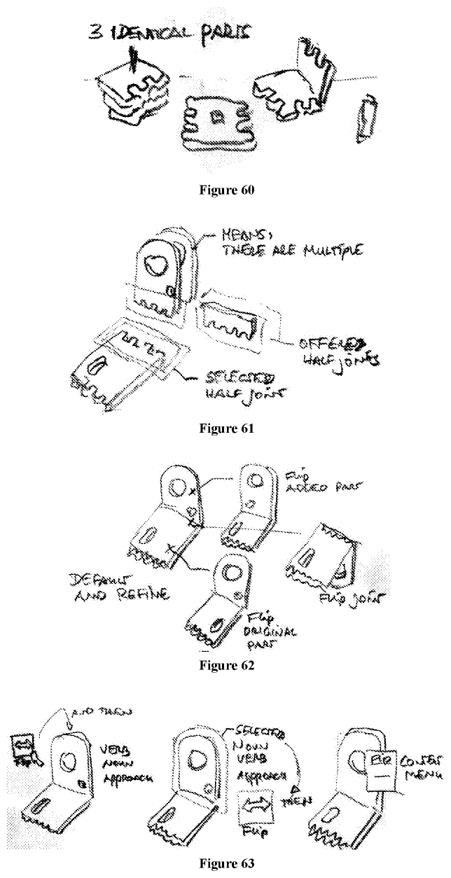

Some embodiments then group identical parts (e.g., by stacking them) and assemble what can be assembled with sufficient confidence, resulting in a scene like the use shown in FIG. 60. Some embodiments collocate parts with potential matches.

While some embodiments may try to continue to assemble for the user, e.g., by making suggestions, other embodiments prefer to simply support users as they “drive”. FIG. 61 shows one such approach. (if stacks of identical objects are involved on both sides, all operations may optionally be applied to multiple or all of them). The user has touched/clicked/selected a part, and the system responds by highlighting all potential matches.

One approach is to allow users to assemble with a simple click or tap on the object to connect to, causing the two objects to join. FIG. 62 shows additional tools for tweaking the resulting joint, e.g., if one or both objects need to be flipped.

As illustrated by FIG. 63, the system may offer such refinement functionality in a variety of ways.

Some embodiments offer additional tools to help simplify assembly. Selecting the swap tool and clicking or tapping on a part or assembly causes the system to highlight all plates or assemblies in the scene the currently selected assembly can me swapped with (i.e.) identical joint signatures. The flip tool flips a part or assembly that was attached using a symmetric joint. The inside-out tool changes the chirality of an assembly by flipping all angled joints.

### 5.6.3. Export

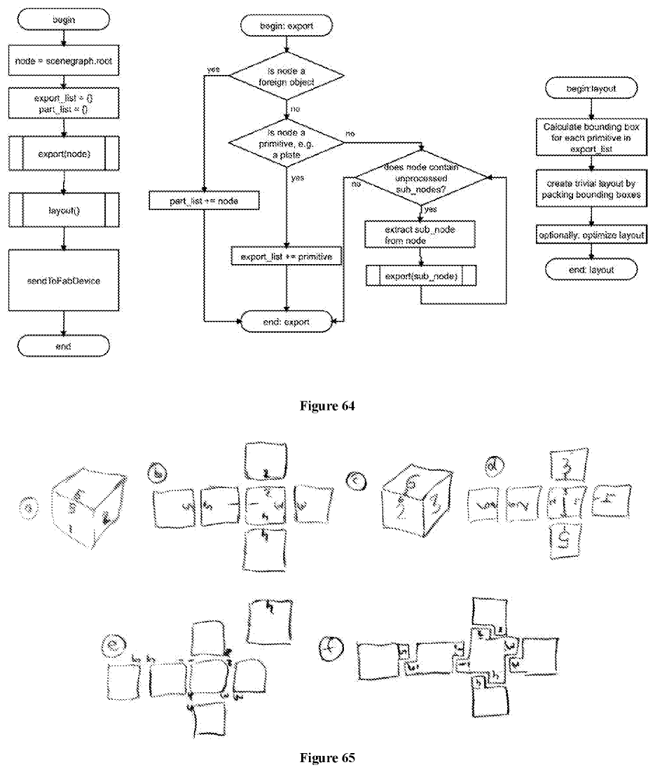

A 3D editor 100 targeted at fabrication may perform its main loop as (1) receive input from the user, (2) use it to process a scene containing models/assemblies, (3) repeat. In addition, the 3D editor 100 typically includes means for converting one or more parts, assemblies, or scenes into a file format/“code” that can be sent to a fabrication machine. For a laser cutter, for example, this may mean to decompose a 3D model into 2D plates as shown in FIG. 64, which is a process flow diagram illustrating an export operation according to some embodiments, decompose these 2D plates into a cutting plan which may be encoded in a vector format (e.g., .svg) or an even lower level format, such as G-Code. This is the code that the system will send to the fabrication machine, such as the laser cutter (or structurally similar machine, such as water jet cutter, etc.).

The export of 3D models to 2D machines serves an important purpose, because it allows users to edit their models in 3D, which is much easier than the today most common way of editing such models directly in 2D line format (e.g., Adobe Illustrator, InkScape, OpenDraw, PowerPoint, or any other program that allows editing 2D line drawings). While editing in 2D line formats requires users to mentally convert back and forth between the 3D object they want to create and the 2D format the fabrication device accepts, editing in 3D and exporting to 2D automatically dramatically simplifies this process for users, thus makes this type of fabrication accessible to a much wider audience.

The export engine 36 may perform some or all of the process flow. At 4801, 3D editor 100 creates the nodes of the object from the scene graph. At 4802, 3D editor 100 generates an export list and a parts list for the object. At 4803, 3D editor 100 prepares the export data for the node from the export list and the parts list. The 3D editor 100 beings the export at 4803. At 4811, the 3D editor 100 determines whether the node is a foreign object. If the determination at 4811 is that the nodes is a foreign object, the 3D editor 100 generates at 4812 the part list of the node, and ends the export. Otherwise, if the determination at 4811 is that the nodes is not a foreign object, the 3D editor 100 determines at 4813 whether the node is a primitive (e.g., a plate). If the determination at 4813 is that the node is a primitive, 3D editor 100 exports at 4814 the list for the primitive, and ends the export. Otherwise, if the determination at 4813 is that the node is not a primitive, 3D editor 100 determines at 4815 whether the node contains unprocessed sub-nodes. If the determination at 4815 is the node does not contain unprocessed sub-nodes, the 3D editor 100 ends the export. Otherwise, if the determination at 4815 is the node contains unprocessed sub-nodes, the 3D editor 100 extracts the sub-node from the node at 4816, exports the sub-node at 4817, and continues back to the determination at 4815. At 4804, 3D editor 100 generates the layout data of the object. The 3D editor 100 begins the layout at 4804. At 4821, 3D editor calculates the bounding box for each primate in the export list. At 4822, 3D editor 100 creates a trivial layout by packing bounding boxes. At 4824, 3D editor 100 optionally optimize the layout. The 3D editor 100 ends the layout. At 4805, 3D editor 100 send the data to the fabrication device.

Some embodiments perform the conversion of 3D to 2D on export, i.e., the scene graph itself still consists of generic 3D objects during editing. Other embodiments, however, implement the conversion to the target fabrication machine earlier and in particular the moment objects are being created and modified, so that the display of parts, assemblies, and scene is already in the form and visual appearance of the target fabrication machine. This very strong form of WYSIWYG offers a series of benefits, such as that it allows users to already see what they will get, catch unexpected effects early on, but also to allow users to use their judgment if the result can be expected to perform as intended.

Note how the algorithm described in FIG. 64 also creates a part list, i.e., the list of objects to be purchased in addition to whatever is being fabricated.

### 5.6.4. Assembly Instructions

As described above, some fabrication machines (such as ⅔-axis subtractive devices, such as ⅔-axis laser cutters, 3-axis milling machines, ⅔-axis water jet cutters, etc.) tend to produce objects in multiple parts, thus require assembly. Some embodiments will automate assembly, e.g., using robotic arms. For this purpose, the assembling machine(s) will require information on how to do so. Other embodiments will require human users (or whoever offers assembly as a service) to assemble objects by hand. To help these humans perform the job with ease, many embodiments incorporate assembly instructions into fabricated parts. Different embodiments will accomplish this in different ways.

FIG. 65 is a diagram illustrating several different strategies for labeling parts according to some embodiments. All of the strategies can be combined in various ways. (a, b) Joint-joint labeling. Some embodiments label each side of a joint with matching markers (e.g., glyphs, letters, numbers, drawings, icons, etc.), printed, cut, engraved, etc, into the respective parts. This can be pairs of identical markers, such as an engraved “312” on one side and an engraved “312” on the other side, or complementary markers, such as a zigzag pattern that extends across the joint. During assembly, this allows users to look for matching and assemble these. Some embodiments may place joint labels on the more visible side of each part (e.g., the outside of a box), so as to ease assembly (see figure); other embodiments will place joint labels on the less visible side of each part (e.g., the inside of a box), so as to make the labeling interfere less with the visual appearance of the final result. Placing the marker on only one side each helps users figure out how parts need to be oriented with respect to each other during assembly, namely in most cased so as to have both labels face up or both face down (while less intuitive, alternating marker orientation is possible as well). If markers are on the same side and always facing inwards (or outwards for that matter) this can help users figure out in which direction to tilt parts with respect to each other during assembly. While it is possible to label all connections, the shown version only labels the minimum number of connections. It computes this as a minimal spanning tree. This figure leaves out finger joints for visual clarity. (c,d) Joint-part labeling. Each part gets a marker and then each joint is labeled with the ID of the part it connects to.

(e) This version places markers on the “support” material next to parts, so as to not interfere with the look of the final object at all (even though at the expense of requiring users to match parts up while still located inside the cut sheet). (f) This version places markers outside the actual parts, but on little perforated tabs that initially stay with the respective part, but that users will break off once the part has been placed in its intended context, so that the marker information on the tab is no longer required (and now often in the way of further assembly). Since etched markers can be hard to read or take time to create, some embodiments cut markers into the tabs.

Since joint-joint and joint-part labels require quite a bit of effort in terms of locating the matching part (O(n²)), some embodiments instead opt for a labeling scheme that allows users to find the matching parts faster.

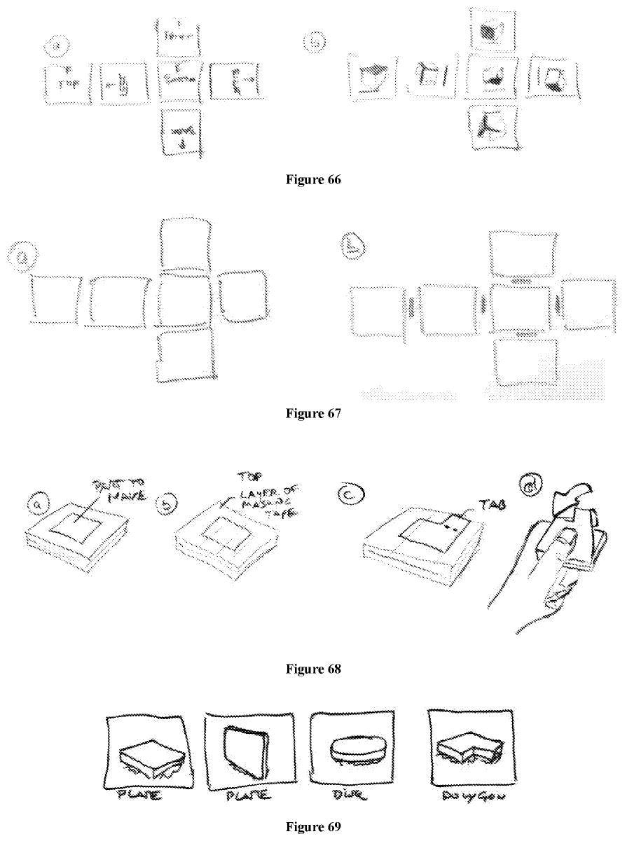

FIG. 66a is a diagram illustrating labeling styles according to some embodiments, and illustrates one approach, i.e., to label parts in a way where each label (also) denotes a position in a global coordinate system. (a) The shown version introduces position-specific terms to part IDs, such as words like front or middle or back, left or center or right. For more complex assemblies, the system adds story number for the vertical coordinate in the case of multi-story assemblies. For assemblies consisting of multiple subassemblies, we may use a divide-and-conquer approach by convey which sub-assembly a part belongs to. (b) Similarly, this version shown a simplified sketch of the overall object on each part, highlighting where the part is located in the overall object.

FIG. 67a shows another approach to part labeling that can be combined with any of the approaches listed above. Here parts are laid out so as to make adjacency in the 2D sheet to be cut correspond closely to connectedness in the 3D model. The algorithm accomplishes this by unfolding the 3D model until it becomes flat, and then mapping this to the sheet to be cut. Someone of skill in the art will appreciate that this can, for example, be accomplished using developable surface algorithms. (b) This version explicitly labels which adjacencies are meaningful by adding an appropriate marker (symbol, glyph, icon, etc.) between meaningfully adjacent parts.

Some embodiments complement the techniques listed above with an approach to preventing erroneous assembly by preventing non-matching parts from being assembled. The algorithm accomplishes this by making each pairs of joints distinct, so that each joint on a part has only one matching counterpart. For finger joints, for example, this can be accomplished by varying the sequence of finger widths. For butterfly joints, this can be accomplished by using differently shaped cutouts, e.g., copying the different joints from a jigsaw puzzle. This can be accomplished with an algorithm as simple as one that enumerates the joints in the scene, then maps each number to a joint pattern. There are many possible mappings, such as representing the joint ID as a binary number and then assign each finger joint a small width for a zero and a higher width for a one at the respective position in the finger joint. Another approach is to randomize joint parameters, which can be further improved by checking newly generated joints against the joints already in the current object (ideally in all possible orientations).

### 5.6.5. Clean Surfaces for Laser Cutting Assembly

As someone of skill in the art will appreciate, some technologies, such as laser cutting can leave residue on the parts, e.g., as a result of heat and smoke caused by the laser. This effect can be reduced by covering the sheets to be cut with a protective film, such as adhesive plastic foil or masking tape, etc. Unfortunately, this requires users to (generally manually) remove the film after cutting (and before or after assembly). Users generally accomplish this by inserting a fingernail or thin blade between film and part—as time consuming and tedious process.

FIG. 68 is an isometric view illustrating removal of residue from a laser cut part according to some embodiments. The view demonstrates how some embodiments reduce the time required to remove such protective film from (a) a part, here a laser cut rectangle. (b) The same part with masking being applied before cutting. (c) Adding one or more tabs to the geometry of the part via some sort of perforation. The shown version is intended to help remove the protective film from the topside of the part (i.e., the side facing the laser). (d) After cutting, users remove the part from its surrounding material—the tab is still attached. Bending the tab towards the protective film breaks it off, yet typically leaves the protective film intact. Lifting the tap off further keeps the protective film on the tab, yet peels it off the part. The same process can be used to remove protective foil from the bottom side of the part, i.e., the side facing away from the laser.

### 5.7. Tools that Manipulate Assemblies

Native primitives allow users to create parts that the targeted fabrication machine is able to fabricate as a single part. FIG. 69 is a diagram illustrating native primitives for a 3-axis subtractive fabrication device designed to cut all the way through sheets of material according to some embodiments.

There are many different ways how such native primitives can be added. FIG. 70 is a diagram illustrating a different embodiment for 2D primitives according to some embodiments. This embodiment includes fewer, but more powerful tools. This type of tool can easily be implemented using a simple shape or gesture recognizer, even as simple as the $1 gesture recognizer by Wobbbock et al.

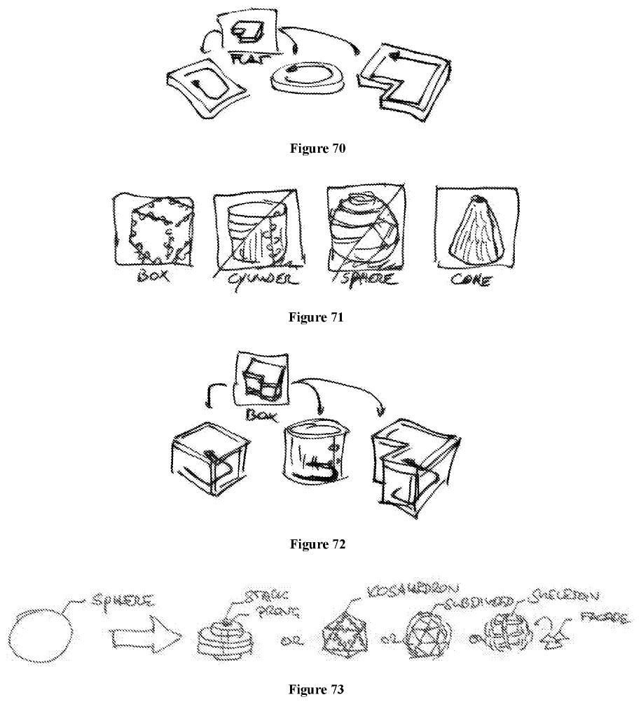

Predefined compounds are objects that the intended fabrication machine is not able to fabricate in one part, but that it can fabricate from multiple parts, e.g., to be assembled by the user. Some embodiments may offer predefined various compounds as shown in FIG. 71, which is a diagram illustrating predefined 3D compounds according to some embodiments.

There are many different ways in which the predefined compounds can be added. FIG. 70 shows one version of a different embodiment that offers fewer, but more powerful tools.

Predefined/imported assemblies. Some embodiments include libraries of commonly used assemblies and/or allow importing assemblies form one or more repositories (see also the section on integration with repositories further down).

Ambiguous assemblies. Some assemblies allow for multiple different types of implementations on the targeted fabrication machine. In this case we refer to them as ambiguous assemblies. FIG. 73, for example, is a diagram illustrating multiple ways to implement a sphere according to some embodiments. On a 3-axis laser, for example, (a) a sphere may be implemented as (b) a stack of plates (c) an icosahedron, (d) a subdivided icosahedron; (e) a supporting skeleton covered with a façade.

When such an assembly is created, the user may specify which representation to create (for example, by picking a specific tool that will always create stacks of plates or my picking a more genetic tool that allows the choice to be input) or the system may choose. The embodiment may consider various parameters in making its decision, such as the size of the sphere, forces it is expected to take, etc. (and of course the targeted fabrication machine). Embodiments may allow users to create specific implementations, to change the implementation of an ambiguous assembly later, and/or generic implementations that may change their own implementation what requirements change, e.g., when the assembly is scaled or loads change.

In FIG. 73, for example, the system 100 may choose as follows: (b) a sphere barely bigger than a few material sheets, for example, may be implemented as stack; (c) a larger sphere as an icosahedron, (d) an even large sphere as a subdivided icosahedron; (e) the system may give an even larger sphere a supporting skeleton.

Embodiments may offer ambiguous assemblies (and predefined assemblies in general) in various forms. They may offer a specific implementation, a generic implementation that the system picks when inserted, a generic implementation that keeps changing as requirements change, or a generic one that stays abstract and generic and is not implemented until fabrication time. At the same time, the object may be displayed in the editor as a specific implementation, as a generic abstract thing, or as an overlay of both. So far, good experiences were gained showing everything in the domain of the target fabrication machine to go with the “what you see is what you get” concept described earlier.

Approximate assemblies. In some cases, some or all of the implementations on the target fabrication machine only approximate the desired shape. As with other ambiguous assemblies, the system 100 may consider several parameters when making its decision; for approximate assemblies, in some embodiments the system 100 also considers how closely the respective implementation approximates the desired assembly when deciding which implementation to pick.

Foreign assemblies. Sometimes users' models involve “foreign” assemblies, i.e., parts of compounds that will not be fabricated by the targeted fabrication machines. There are several reasons why these assemblies cannot be fabricated. (1) The targeted fabrication machine may not be capable of fabricating the respective shape (3-axis laser cutters, for example, cannot form screws), (2) The targeted fabrication machine may not be capable of processing the respective materials (100 W laser cutters, for example, generally cannot process steel objects), (3) The targeted fabrication machine may not be capable of producing the required level of complexity (e.g., servomotors or LEDs), or (4) the foreign assembly may simply not be part of the object, but part of the environment the object is supposed to interact with (e.g., a water bottle and a bike frame, in case the object is a bottle mount for a bike).

Some embodiments represents foreign assemblies in the model, as this (1) tends to make the model more comprehensible by showing assemblies to be fabricated in their full context, (2) often allows connecting sub-assemblies that would otherwise be disconnected, (3) helps create contraptions that physically connect to foreign assemblies (e.g., the bike bottle mount, for example, can be created by subtracting the bottle and the bike frame from a generic holder (plus/minus offsets for play)).

To allow users to include foreign assemblies in their models, some embodiments may allow users to import foreign assemblies from a library of commonly used foreign assemblies. They may allow including additional objects by importing models from an online repository of 3D models of 3D printed models (e.g., http://thingyverse.com) or to upload 3D objects scanned (e.g., using a 3D scanner, a depth camera, or one or more regular cameras) or modeled elsewhere (e.g., in any of the 3D editors mentioned earlier).

To allow foreign assemblies to perform more realistically in various physics simulations, embodiments may allow annotating them with additional meta information, such as weight, stiffness, texture, specific weight/buoyancy, translucency, optical density, etc., import then together with such annotations, or look up such annotations elsewhere. To clarify what will be fabricated and what will not, the embodiments may render foreign assemblies differently, e.g., de-saturated or translucent, etc.

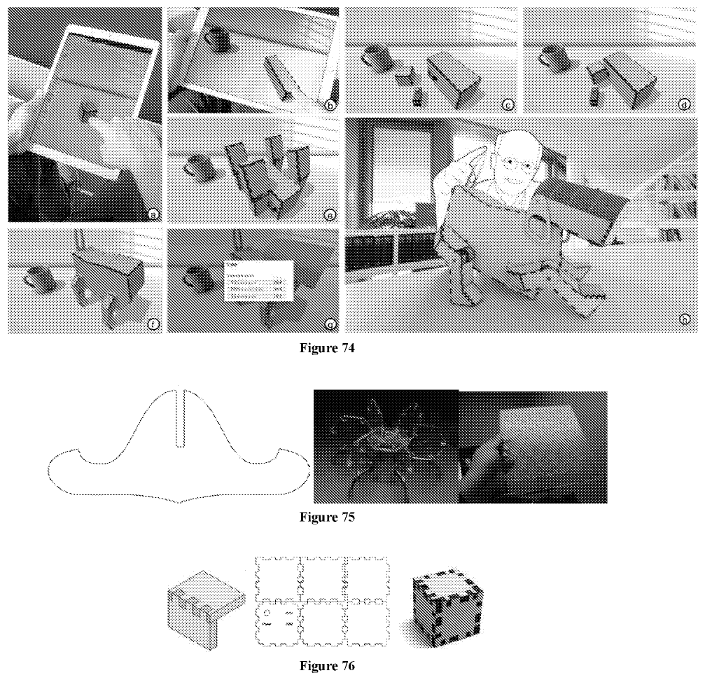

Smart components are assemblies with optional additional meta information that embodies engineering knowledge, thus allow users to create assemblies that would normally require an engineering background. FIG. 74 is a diagram illustrating how such smart components can make complicated design tasks easier according to some embodiments. (a) A cube drops into the scene and bounces off the ground. The box already contains finger joints. (b) The user picks the push/pull tool and quickly resizes the box's length, width, and height. All finger joints grow along with the box, keeping the model consistent at all times; this means that the user could actually fabricate the workpiece right now—or any other time for that matter. (c) Starting to design the first leg, the user drops a servomotor smart component and another box into the scene. The servomotor is a smart component; among other things, this particular component embodies the know-how required to mount it, i.e., that one side of it want to embed itself into a sheet of material by means of a rectangular cutout for the main body and four holes for screws, while the other side of the servo holds a disk that can be embedded into a second sheet of material parallel to the first, and so on. As the user picks up the servomotor component and drags it towards the box (d) the servo component snaps into the wall of the box. This causes the system 100 to cut the necessary cutouts and mounts, so that the servo is instantly embedded and on a mechanical level functional. The user drops additional boxes and another type of smart servomotor components into the scene, which produces the dog's knees. Then the user uses the mirror tool to produce the legs on the other side, resulting in a first version of (e) a four-legged robotic animal. The user refines the shape of legs and body, then picks up the dog and (f) flips it around, adds another box as head and uses the round tool, to give the dog a rounded snout and (g) sends it off to fabrication either locally or here through the web-based serviced described later in this disclosure. At a later time, e.g., few days later, a package with all the parts arrives and the user (h) assembles his or her first prototype.

Different embodiments use different approaches to embody the engineering knowledge. Some embodiments define components using a few numbers and symbols, such as a few constants set in .json and .xml file. Other embodiments consider a type of component as a class and each smart component is an object, as in object-oriented programming (and arguably, even the approach to just store a new named variables can be considered a special case of object construction).

Someone skilled in the art will appreciate that there are many ways to implement, store, and load such class descriptions and object descriptions. Some embodiments that may implement a subset of the functionality of a class by trying to represent all relevant data in the form of (member) variables, other embodiments may (also) contain executable code or script, such as an subset of (1) the visual representation in the editor (e.g., in the form of a 3D graphics file, e.g., in .stl format or a textured format, such as .obj or similar and/or code that expresses this), (2) the fabrication instructions required to create the mount for the smart component (e.g., an assembly in the editor's own format, an .stl format or G-CODE, or similar, or a piece of code that expresses this), (3) a behavior that the resulting assembly is able to perform (e.g., the rotation in the case of the servo motor; this can be encoded as the axis representing the rotation center, as code performing the animation etc. (4) a filter that determines what objects the smart component can be combined with, (5) an animation to be played back when mounting the smart component, (6) an animation to be played back when un-mounting the smart component, etc.

Note that a smart component may contain a foreign object and may even look like a foreign object (as is the case with the servomotor smart component discussed above), yet the additional behavior makes it more than a foreign object. The smart servomotor component embedded into the dog's knees in FIGS. 74f and h, for example, could potentially be based on the same servomotor. However, this smart component will be complemented by different behavior here resulting configuration that holds the servo from two sides, while the smart component discussed earlier holds servos from only one side.

The inherently object-oriented nature of smart components also allows expressing relationships between different smart components using a variety of ways including inheritance. Some embodiments will use this to group smart components by functionality. One type of resulting functionality is that the system 100 may include tools that replace smart components of functionally equivalent, yet slightly different smart components. A make stronger tool, for example, may replace a weak servomotor component with a stronger one often with little modification of the overall assembly's geometry; a make more precise tool may replace smart components with more precise ones; a make cheaper tool may replace smart components with cheaper ones, and so on. Some embodiments will extend this concept beyond smart components (or consider everything a smart component for that matter) allowing these tools to be applied more broadly to an assembly or scene, then attempting to replace all sub-assemblies that implement such a make_stronger( ) method with appropriate sub-assemblies.

The servomotor component is just an example of a rotating smart actuator component. Many embodiments will often multiple, if not dozens or hundreds or thousands of smart components smart components, such as additional actuator components, such as linear servomotor components or lift table components, additional rotating components, such as screws, axles with bearings (or ball bearings), nails, etc. ball bearings, universal joints, or one of hundreds of carpenter joints (captured nut, etc.) mechanisms, such as rack-and-pinion mechanisms or such from collections such as the book 507 mechanical movements. In that sense, finger joints, nudge joints, and gluing can also be considered smart components.

Predefined joints and mechanisms. While users often know what final shape they are trying to achieve (say, a bike with two wheels, frame, saddle, fork), the challenge often lies in the technical construction, i.e., how to get the individual parts to be arranged the desired way and especially to do so in a way that is structurally sound. This difficulty arises especially when designing for fabrication machines that are limited to simple, such as flat primitives, as they require users to decompose their desired design into such primitives and the add contraptions that hold these primitives together once fabricated. The inventive concept addresses this by offering tools and libraries that contain domain knowledge on the joints and mechanisms common for the intended platform. For 3-axis laser cutters, for example, one particular embodiment may offer, among others, finger joints and notch joints, living hinges, as well as pairs of gears and similar mechanisms. FIG. 75 is a diagram illustrating a notch joint according to some embodiments. FIG. 1 is a diagram illustrating a finger joint according to some embodiments.

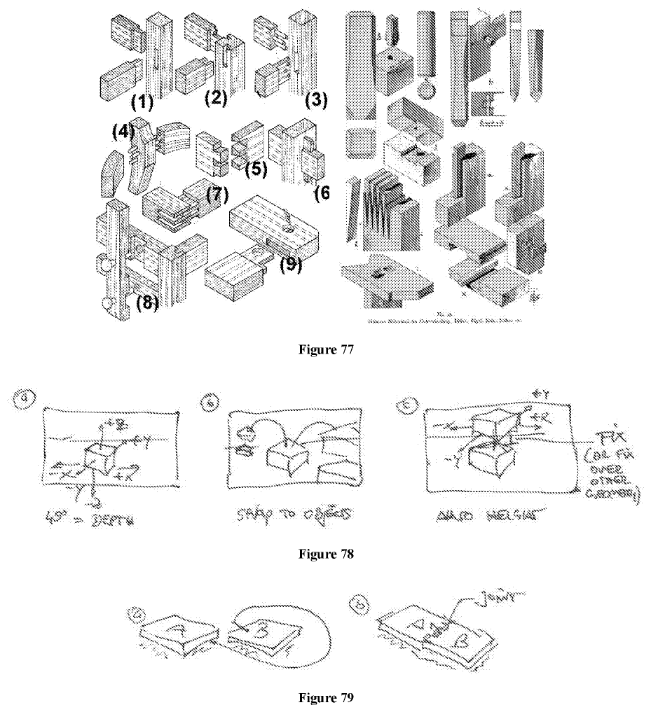

While most of this section focuses on 3-axis laser cutters and related machines, the same techniques apply to other machines. If the target machine is a milling machine, for example, embodiments generally consider the size of the mill bit; they may also offer additional carpenters joints (FIG. 77 is an isometric view illustrating joints according to some embodiments) that, say, laser cutters would not be capable of fabricating.

5.7.1. Joining Assemblies that do not Directly Touch Yet

Joints implemented using special techniques. Some embodiments may offer joints implemented using special techniques. For certain materials (e.g., acrylic) on certain machines (e.g., a 3-axis laser cutter or better), some embodiments may offer bending the material (as described in laserOrigami]). For certain materials (e.g., acrylic) on certain machines (e.g., a 3-axis laser cutter or better), some embodiments may offer welding parts together (as described in laserStacker]).

Automatic creation of joints and mechanisms. The inventive concept allows users to arrange assemblies with respect to each other in a way that causes the system to create a physical connection between the assemblies. Some embodiments may create a connection automatically if two assemblies are arranged in a certain way with respect to each other, e.g., stacked, interacting, at a 90 degree angle, etc. In this case, the system 100 automatically creates a joint at the intersection, connecting the two assemblies. The system 100 may consider various parameters when determining what connection to create, such as the materials of the assemblies, material thickness, distances and angles to be bridged, the types of joints currently in use in the model, especially those (if any) explicitly defined by the users, and the systems built-in knowledge about structural and mechanical engineering.

FIG. 78 is a diagram illustrating a selection of tools that can be used to move assemblies around according to some embodiments. Other tools include, 6 DoF input devices, e.g., controllers designed for virtual reality. These tools can, for example, trigger the automatic creation of joints and mechanisms (FIG. 79 is a diagram illustrating movement of an object according to some embodiments).

Connecting assemblies at a distance A specific challenge for users is to place two (or more) assemblies with respect to each other even though these assemblies would not normally touch each other. When designing a camera holder for phones, for example, a user may have created the camera mount and the phone mount separately, but now this user needs to connect the two mounts in a way resulting in the correct placement causing the camera held by the camera mount to face the phone held by the phone mount. Embodiments following the more traditional 3D editing approach may simply allow moving the two assemblies together, then connect them.

Embodiments employing gravity, in contrast, require a support structure that bridges the gap between the two. Such embodiments may offer a connect tools that allows placing one (or more) assemblies with respect to one another, causing the system to automatically create a support structure between the two (i.e., another assembly) that holds them in place with respect to each other, when necessary.

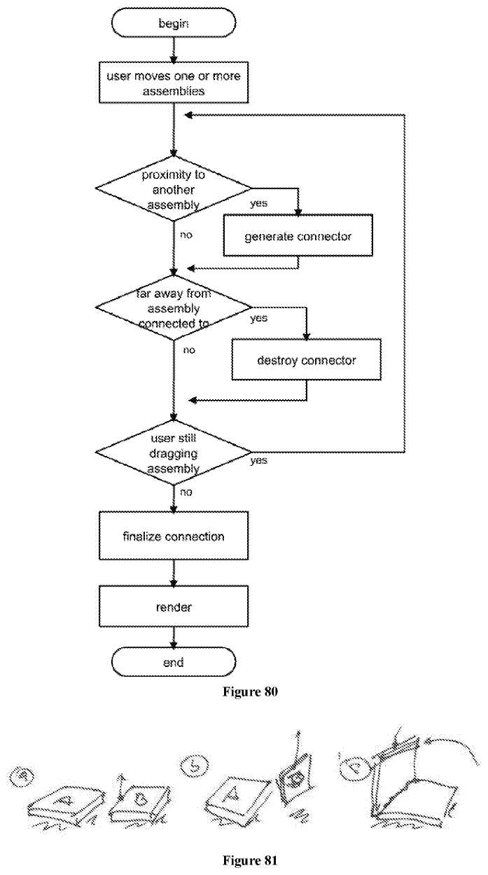

FIG. 80 describes one possible algorithm. This one allows moving an object close to another one, causing them to be connected automatically, i.e., the tool will automatically generate additional parts and joints in between or will extend and merge the existing assemblies.assmblies. When computing “proximity”, the system may consider the structure of the two objects, the distance, structural aspects such as weight and lever when creating connection. When computing “far away” similar factors may be considered. In addition, many embodiments will choose “proximity” and “far away” so as to implement hysteresis.

FIG. 80 is a process flow diagram illustrating the operation of connecting assemblies according to some embodiments. In some embodiments, the tool box engine 16 and the rendering engine 24 performs some or all of the process flow. At 5601, 3D editor 100 detects a user moving one or more assemblies. At 5602, 3D editor 100 determines whether the moved assembly is in proximity to another assembly. If the determination at 5602 is the moved assembly is in proximity to another assembly, 3D editor 100 generates at 5603 a connection between the moved assembly and the proximate assembly. If the determination at 5602 is the moved assembly is not in proximity to another assembly, or after the generation at 5603, 3D editor 100 determines at 5604 whether the moved assembly is far away from an assembly that the moved assembly is connected to. If the determination at 5604 is that the moved assembly is far away, 3D editor 100 destroys at 5605 a connection between the moved assembly and the non-proximate connected assembly. If the determination at 5604 is that the moved assembly is not far away, or after the destroying at 5606, 3D editor 100 determines at 5607 whether the user is still dragging the assembly. If the determination at 5607 is the user is still dragging the assembly, 3D editor 100 returns to the determination at 5602. Otherwise, if the determination at 5607 is the user is no longer dragging the assemblies, 3D editor 100 finalizes at 5608 the connection, and renders the scene at 5609.

Some embodiments may modify one or both of the assemblies to make them easier to connect. The connection itself may be a primitive or a compound, such as a truss. It may connect two or more objects along the shortest connecting path, or it may create a connection better aligned with the nature of the object, e.g., the main axes of which align with the axes of the connected objects [Yuki Koyama, Shinjiro Sueda, Emma Steinhardt, Takeo Igarashi, Ariel Shamir, and Wojciech Matusik. 2015. AutoConnect: computational design of 3D-printable connectors. ACM Trans. Graph. 34, 6, Article 231 (October 2015), 11 pages. DOI=http://dx.doi.org/10.1145/2816795.2818060]

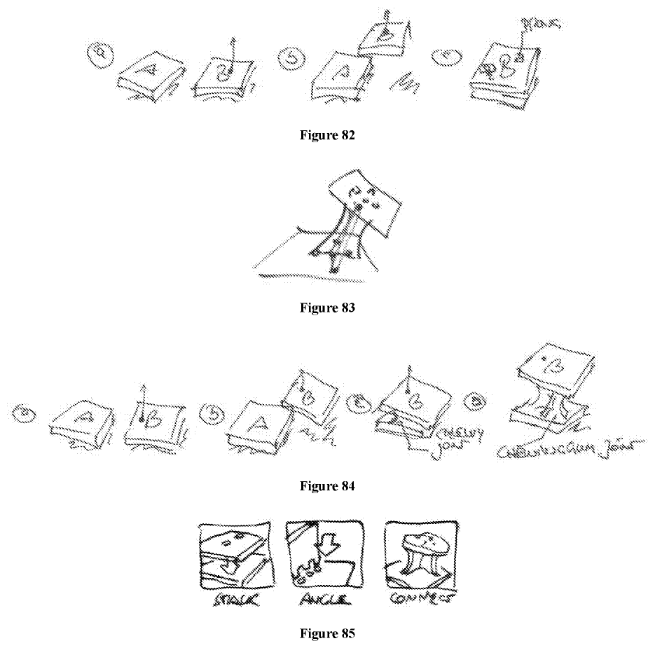

There are many ways to connect assemblies. FIG. 81 is a diagram illustrating one way to connect assemblies that employs a version of the gravity-based tilt tool to connect two assemblies according to some embodiments. FIG. 82 is a diagram illustrating another use of that same gravity-based tilt tool according to some embodiments. Here the shown plate is picked up so as to hover vertically, here resulting in the tool generating a stack.

The chewing gum tool is shown in FIG. 83, which is a diagram illustrating a chewing gu tool allows connecting two assemblies across a distance and at an angle, according to some embodiments. There are multiple ways to implement it, e.g., as described in FIG. 80 but without the destruction and instead an additional phase at the end that allows positioning the dragged assembly on pulling away (FIG. 84 is a diagram illustrating two assemblies connected using a chewing gum tool according to some embodiments). This type of tool is also easy to implement using 6 DoF virtual reality controllers: as before, the connection is established by getting close to the target object; then the dragged assembly is positioned in space and released.

Another embodiment of a chewing gum tool comprises distinct phases. The tool first connects an assembly to another assembly; this phase ends by the user ending the drag interaction, e.g., by lifting the finger off the touch screen or releasing the mouse button. Then, as a second phase, the user picks up the assembly again and drags it into its intended position, whereby the tool (continuously) creates the necessary connector.

The functionality of connecting can also be offered using multiple tools, in order to improve discoverability. In FIG. 85, which is a diagram illustrating a graphical user interface (GUI), according to some embodiments, that offers three separate connect functions, each of which either is limited to a certain type of connection (here parallel connections between assemblies, angled connection between assemblies, free positioning).

Another approach to connecting two assemblies is by marking what areas the user wants joined. The user may start by applying a mark to the first assembly and then a mark to the second assembly. The system 100 now determines how to move one of the assemblies so as to make its mark touch the mark on the other piece with a high degree of overlap.

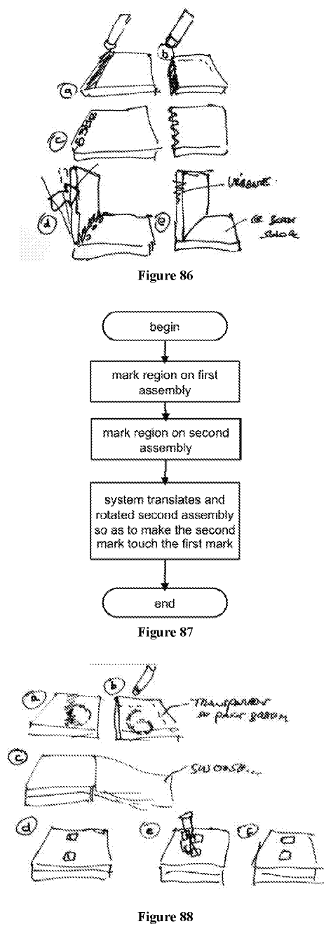

The approach to connecting two assemblies shown in FIG. 86 uses the metaphor of a glue stick. (a) The user is applying a mark to the first assembly and then (b) to the second assembly (the user “applies glue”). The system 100 now determines how to move one of the assemblies, e.g., the second assembly so as to make the second mark touch the first mark with a high degree of overlap. (c) The system 100 creates a joint on the two assemblies that is suited for mounting one assembly onto the other. Here it inserts holes into the first assembly and creates “fingers” on the second. (d) The system 100 mounts one assembly onto the other (here the second onto the first) so as to make the second mark touch the first mark/so as to mount the joint. It may animate one or both assemblies in the process or create an afterglow effect to explain the transition. Here, for example, the assembly bearing the holes is placed at a slight angle against the first, then rectified and slid in, resulting in the assemblies to vibrate and/or snap.

FIG. 87 is a process flow diagram illustrating a glue stick tool according to some embodiments. Alternatively, the system may choose to move the first assembly (or both could be moved). In some embodiments, the tool box engine 16 and the rendering engine 24 perform some or all of the process flow. At 10101, 3D editor 100 marks a region on a first assembly. At 10102, 3D editor 100 marks a region on a second assembly. At 10103, 3D editor 100 translates and rotates the second assembly to make the second mark touch the first mark.

Among other criteria, the shape of the mark can be used to clarify how the two assemblies are supposed to be aligned. The complexity of a mark depends on the amount of ambiguity in the scene. A point-shaped mark, e.g., created by the user clicking or tapping each assembly once determines two locations are supposed to touch, but leaves the rotation undefined. This is sufficient if one or both assemblies are rotationally symmetric or if the system 100 can figure what rotation the user expects, e.g., based on what is physically possible or leads to good alignment, high esthetics, etc. Such one-click/one-tap marks are also sufficient (1) if the two assemblies already bear a joint that defines the rotation or (2) if the plate to be added is symmetric, so it does not make much of a difference.

The system 100 may consider the two marks literally as two locations when determining the mapping. Alternatively, the system 100 may consider the marks only as an indication of which surface of an assembly to connect, in which case the system 100 may work out the exact mapping automatically, e.g., so as to achieve the best alignment between the two assemblies. The system 100 may also extract just enough information from the clicks/taps, so as to decide which of two edges the user might be referring to, etc.

The system 100 may allow users to enter strokes to allow users to provide additional position/rotation information to the system. This can be useful when trying to place an assembly, e.g., in a manual way overriding automatic alignment, e.g., when assembling two uncommon location or rotation (not along the edges, etc.).

FIG. 89 is a diagram illustrating another glue approach according to some embodiments. The figure shows an approach similar to FIG. 86; this version, however, creates simple posts first. (a) The user applies marks to two assemblies defining a mapping between the two. (b) In this embodiment, however, first one or both assemblies build up “posts” that may stick out. The two ends may be highlighted, here using an animated particle effect. (c) Automatically or triggered by a user action, the system 100 moves one (or both) of the assemblies so that the posts match up, resulting in one of the assemblies being mounted to the other with a non-zero distance between two. The system 100 may offer the user the opportunity to modify the two posts before and/or after mounting the assemblies in order to influence the relative position between the two assemblies. The mounting may or may not be accompanied by animation and/or afterglow effects.

When connecting two assemblies, there are several different ways of setting up “posts/connectors” on the two assemblies. FIG. 90, FIG. 91, and FIG. 92 are diagrams illustration examples of connectors for various geometric cases according to some embodiments.

Once a post/connector has been added, the system 100 may allow users to modify post/connector. FIG. 93 is a diagram illustrating an assembly after a connector has been added according to some embodiment. The addition may change the type of connector as desired: (a) Connector and a user dragging its top results in (b) the connector top to translate. (c) Further dragging may drag it past the edge of the object it is connected to and (d)

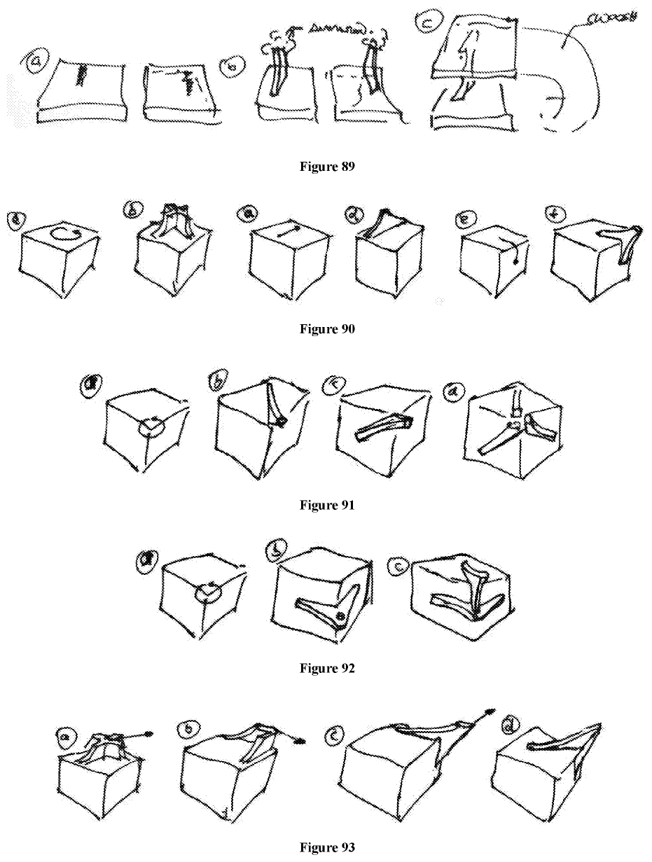

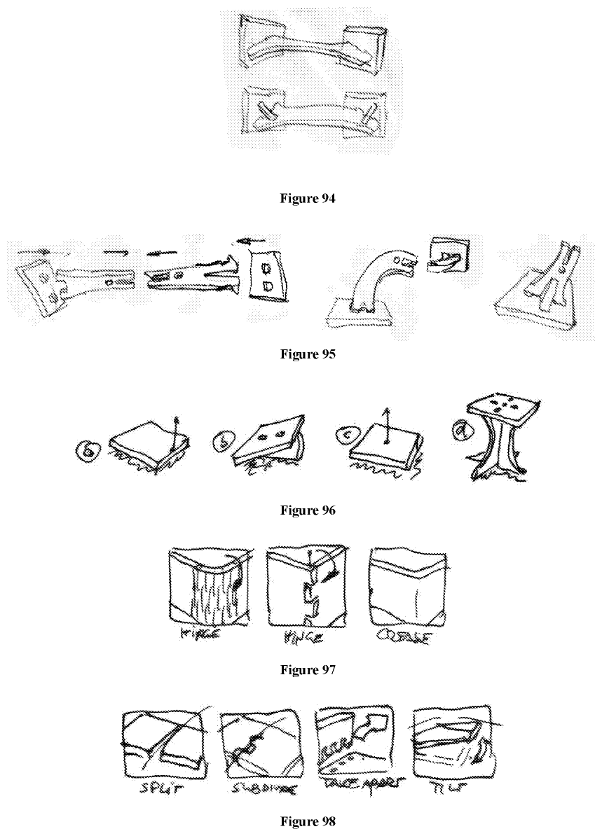

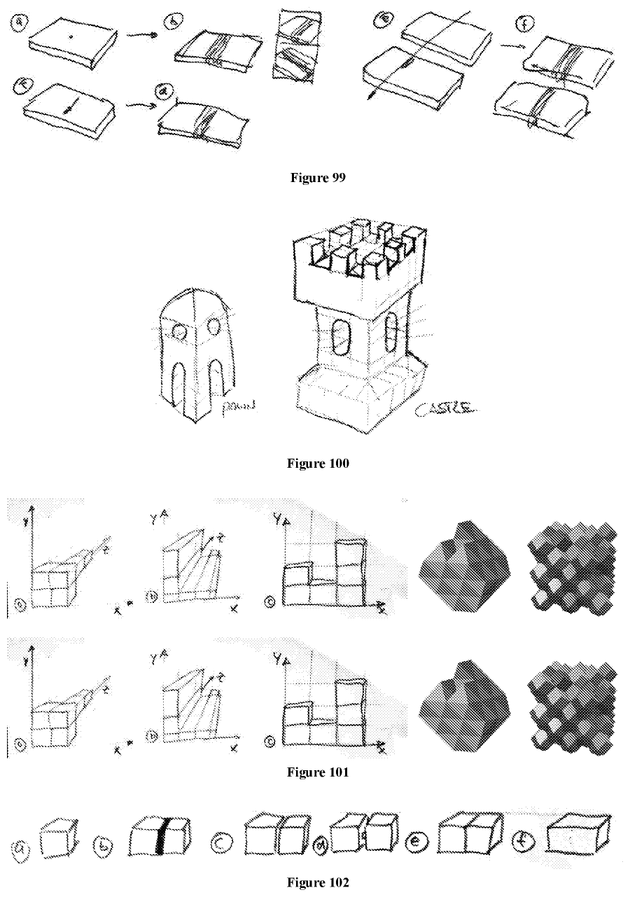

As shown in FIG. 94 and FIG. 95, embodiments may reinforce connections by creating pairs of orthogonal plates connected as cross joint/notch joints.

If the user “connects” an object resting on the ground, the system 100 may still generate a (special type of) “connector” as shown in FIG. 96. (a) Pulling up one side of a plate, (b) creates a support structure that holds the object in this position. (c) Pulling up a plate into the air (d) may create a support structure that holds the object in that position (this and similar support structures are examples; many other types of support structures are possible).

Automatic construction of support structures. If users create structures that involve large forces there is a risk of breakage. When creating a chair, for example, sheering forces when the user is pushing backwards may break off the chair's legs. Embodiments may analyze such forces (e.g., using finite element analysis) and automatically create support structures where it deems them necessary.

The following figures show tools for combining multiple parts into a single part and for subdividing a part into multiple parts.

### 5.8. Boxels

To allow users to create assemblies that are largely defined on a grid even faster, some embodiments offer what are refer to herein as boxels. Boxels are components, with their height, width, and depth being integer units on some grid. Most embodiments will define boxels on a 3-dimensional, Cartesian grid, as illustrated by FIG. 101a. As used herein, boxels defined on such a grid are referred to as cubic boxels, as illustrated by FIG. 100, which is an isometric view illustrating cubic boxels according to some embodiments.

They do not have to though and might instead be defined on a rectilinear grid (FIG. 101b), a 2D Cartesian grid (FIG. 101c), a tetrahedron octahedron honeycomb (FIG. 101d), a rhombic dodecahedral honeycomb (FIG. 101e), etc. instead, or some other space filling tessellation. Most boxels will measure a single 1×1×1 volumetric grid unit, but they do not have to; they might occupy multiple units and, in exceptional cases fractions of a unit. As referred to herein, assemblies consisting purely of boxels are referred to as pure boxel assemblies. If they can contain non-boxel parts as well we will refer to them as boxel assemblies.

Boxel assemblies can be manufactured using a wide range of fabrication machines, including additive devices, such as 3D printers. That said, many of them, such as the cubic boxels mentioned above can also be manufactured using subtractive devices, such as milling machines and laser cutters, etc. They can also be manufactured using 2- or 3-axis subtractive devices, such as 2-3 axis laser cutters, milling machines, water jet cutters etc. A cubic boxel, for example, may by assembling from six plates, e.g., using by gluing the plates together or using any types of joints that allow plates to be mounted at the required angles, e.g., finger joints, bending, living hinges, miter joints, dowels, and internal skeleton, welding, etc.

Boxels come in different types, but they all feature at least one, but typically multiple standard connectors that allows them to be connected to another boxel of compatible type. Different embodiments may offer different types of connectors, such as round holes that allow the boxel to be connected to another boxel using a dowel, 3D printed pins, treads, snap fits, Velcro, gluing, etc. Alternatively, on appropriate machines, connectors may offer no particular joint mechanism and instead they are “connected” in software by uniting the geometries of the adjacent boxels, so as for the resulting geometry to simply be manufactured in one piece.

5.8.1. Building with Cubic Boxels

In this disclosure, the focus is on cubic boxels. This particular design allows two boxels to be connected in many of the various ways listed above, some of which are illustrated by FIG. 102, which is an isometric view illustrating joining of two boxels, according to some embodiments. (a) The image shows a first boxel. Now a second boxel is added, which may, depending on embodiment, result in (b) two boxels connected by a wall of double thickness, (c) two walls glued together, (d) two walls connected by a dowel or such, (e) by uniting the two walls, or even (f) my removing the interfacing walls. In most of these, but specifically the last case, the two boxels are actually connected by the coplanar walls in the two boxels being united into a single bigger wall, resulting in a strong connection that does not require additional manual assembly when manufactured using 3-axis subtractive devices, such as laser cutters, etc. In the following, this particular embodiment illustrates boxels; however, all other connections shall be understood as included as well and many embodiments will support of these as well (such as shared walls for extra stiffness).

While we will continue to illustrate the concept at the example of cubic boxels that tessellate space in the arrangement of a 3D Cartesian grid, other embodiments may offer other types of boxels and tessellations, such as tetrahedral boxels and octahedral boxels that tessellate 3D space in the form of a tetrahedral/octahedral honeycomb structure (e.g., using their triangular walls as connectors), or any other set of 3D primitives that together allow tessellating 3-space.

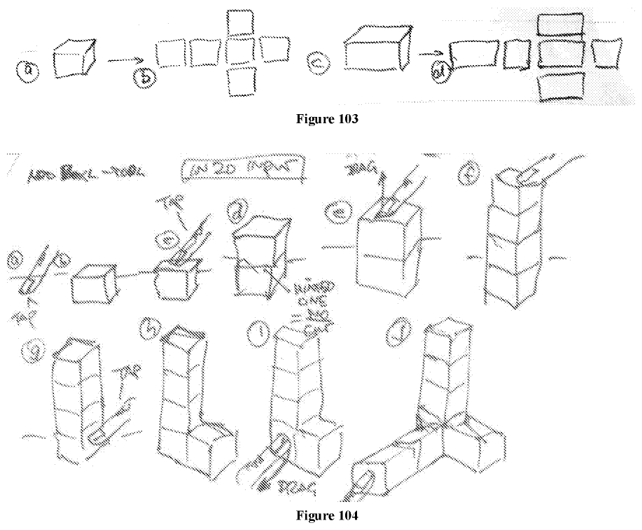

FIG. 103 is a diagram illustrating exporting a single boxel and an assembly of two boxels according to some embodiments. The figure shows how (a) a single boxel is (b) exported to a 2-3 axis subtractive devices, such as a laser cutter and (c) how an assembly consisting of two boxels is (d) exported to such a device (joints, such as finger joints, welding, etc. left our in the interest of visual clarify)

Boxels can be added to a scene in many ways and using a wide range of input devices. FIG. 104 is a diagram illustrating adding a boxel to a new assembly according to some embodiments. As shown in FIGS. 104a and b. A boxel to start a new assembly may, for example, simply be placed at a specific x/y coordinate in the scene, where some embodiments may, for example, simply place it onto the ground. This can, for example, be accomplished using a 2D pointing device, such as a mouse, pen, touch, etc. Embodiments that have access to higher DoF input devices, such as a 6 DoF virtual reality controller or similar, may offer additional control, such to place the new boxel anywhere in a scene and rotate into position.

Some embodiments may make such a first isolated boxel already align itself into some sort of global grid. Other embodiments more aligned with the multiple assemblies approach discussed throughout this disclosure may use local grids instead, thus allow for arbitrary placement of such first isolated boxels. However, such a boxel will then typically define a coordinate system for boxels subsequently added to this boxel.

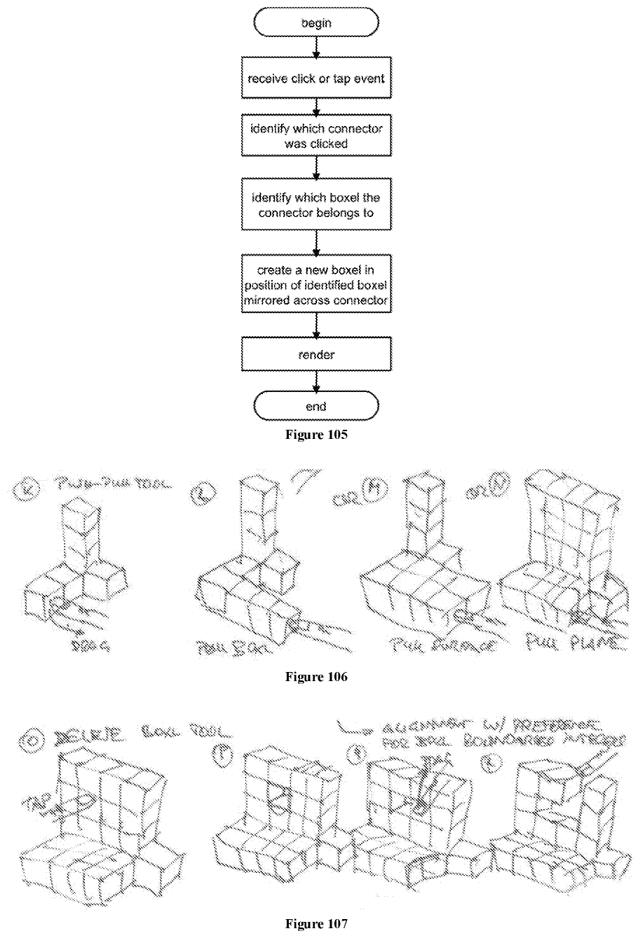

The main strength of boxels comes to fruition when additional boxels are added to an assembly and in particular to boxels added previously. FIGS. 104c and d illustrate a tool that allows placing additional boxels particularly efficiently. As illustrate by FIGS. 104c and d, this tool allows adding a new boxel to an assembly using a single click or tap operation. This click or tap may, for example, specify a connector of an existing boxel (referred to herein also as “base boxel” or just “base”), resulting in the new boxel being mounted to that base at this connector. For the particular type of cubic boxel shown, this mounting may, for example, be achieved by uniting the four coplanar pairs of plates; the plates at the connection may be left in or, maybe more commonly go out. In the illustration, we drew a line at the connection between the two boxels for visual clarity; this line may be visible in actuality (e.g., engraved) or may not be there at all, i.e., the result of connecting the two shown boxel would simply be a larger box. FIG. 105 is a process flow diagram illustrating an add boxel tool according to some embodiments. In various embodiments, the boxel engine 26 and the rendering engine performs some or all of the process flow. At 9001, the 3D editor 100 receives a click or tap event from a user. At 9002, the 3D editor 100 identifies which connector was selected. At 9003, the 3D editor 100 identifies which boxel the connector belongs to. At 9004, the 3D editor creates a new boxel in the position of the identified boxel mirrored across the connector. At 9005, the 3D editor 100 renders the scene. Instead of mirroring the newly inserted boxel, the newly inserted boxel more commonly may be translated to its new location (in case of symmetric boxels this may not make a difference). For some boxel geometries, placing the new boxel may require a new translation and rotation. For boxel sets that consist of two or more geometries, such as tetrahedra and octahedra, the newly inserted boxel might be of a different geometry than its neighbor; the new boxel then has to be created on the connector.

The interaction of adding a boxel to an existing assembly of boxels is as simple as it is for a number of reasons. First, the existing boxel defines a grid (or is itself part of a grid) and that uniquely reduces the act of placing a new boxel to the act of selecting a connector. This, however, can be accomplished very quickly even with a reasonably inaccurate input device (e.g., a touch screen), because a boxel surface will often be large to allow for easy targeting. Second, selecting a connector can typically be accomplished with a 2D pointing device, despite the scene being 3D, e.g., by means of ray casting the pointer into the scene, as someone of skill in the art would appreciate. This reduces 3D targeting to 2D targeting, making targeting easy. Third, if the new boxel is fully symmetric, i.e., if all surfaces are identical and themselves fully symmetric, then it does not matter how the boxel is rotated, so that attaching a boxel is all it takes.

In order to allow adding boxels that are not fully symmetric, tools may either allow users to select a connector on the new boxel as part of the operation (e.g., using a higher DoF controller as input device to rotate the new boxel into position before attaching it), or attach the new boxel by some default of guessed connector and in some default or guessed orientation and offer additional tools or mechanisms that rotating the boxel so as to connect using other connectors or in different orientations afterwards.

Different embodiments of the system 100 may choose different strategies for making the union of two boxels work with the global grid. A particularly simple strategy aligns the planes in the centers of each boxel walls with the grid, so that walls of adjacent cubic boxels line up automatically.

FIGS. 104e and f continue the example by demonstrating a more efficient way of adding multiple boxels at once. The shown interaction starts by attaching a boxel using any of the mechanics discussed above, but then continues with movement of the input device. This leads the system to dispense and attach additional boxels along the way, thus allowing users to create entire 1D arrangements of boxels using a single drag gesture. Given that this tool is based on dragging, while the previous tool was based on tapping, some embodiments may choose implement both as a single tool.

As shown in FIG. 104g, h, i, and j, users may add boxels to any visible connector, here the one facing to the right.

FIG. 106 is a process flow diagram illustrating an add boxel tool according to some embodiments.

FIG. 106 is a diagram illustrating scaling a boxel according to some embodiments. The figure shows one of many possible ways to modify boxel assemblies. (k) Here the user applies a variation of a push-tool to a connector of a boxel. Different tools may respond to this by (l) scaling the select boxel, (m) scaling the entire multi-boxel surface coplanar with and adjacent to the selected connection, (n) or any boxel located in that plane. In these illustrations we show discrete versions of the push/pull tool, i.e. these tools scale in integral increments of full boxels, thereby producing additional boxels. Other versions of push/pull tools will produce fractions or a continuum of boxels. By using an appropriate alignment method, such as space curvature introduced earlier, both fractions and integral values can be achieved in a single tool.

As illustrated by FIG. 107, which is a diagram illustrating scaling a boxel according to some embodiments, some embodiments of the system 100 may also include delete boxel tools. In analogy to the add boxel tools discussed above, the delete boxel tools may delete a single boxel by tapping or clicking it. The same or other tools may delete multiple boxels by means of a drag interaction.

Removing boxels may cause an assembly to become disconnected (in particular when users remove an entire plane). Some embodiments of the system 100 may offer tools that respond by indeed breaking the assembly in two or more smaller assemblies. Other embodiments of the system 100 may include tools that automatically shift the otherwise separated boxels towards the rest of the assembly and reconnect them there. A separate knife tool may instead be used to actually break down assemblies into multiple smaller assemblies.

The boxel tools described in this disclosure may refer to a single boxel—as are used in most of our illustrations. However, to enable more efficient manipulation, many embodiments may allow configuring tools to instead apply to larger “scopes”. This can be accomplished using a range of interfaces, including simple graphical user interface dialogs, such as the one shown in FIG. 108, which is a diagram illustrating a GUI dialog for boxels according to some embodiments, using dropbox-downs and combo boxes, etc.; this dialog allows users to choose between boxel, surface, and plane, but more scopes are possible, such as brush, assembly, and scene. (a) When boxel scope has been selected, subsequent operations affect only the boxel/connector pointed to as part of the operation. (b) When surface scope has been selected, subsequent operations affect the boxel/connector pointed to and all boxels that can be reached by traversing the assembly surface starting at the selected connector and while staying in the same plane. (c) When plane scope has been selected, subsequent operations will affect the boxel/connector pointed to as part of the operation, as well as all boxels in the plane spanned by the orientation of the selected connector. Other tools may allow users to pre-specify which plane should be affected, such as x/y, y/z, or x/z plane. (d) When assembly scope has been selected, subsequent operations affect the boxel pointed to and the entire assembly it belongs to. (e) When scene scope has been selected, subsequent operations affect the entire scene.

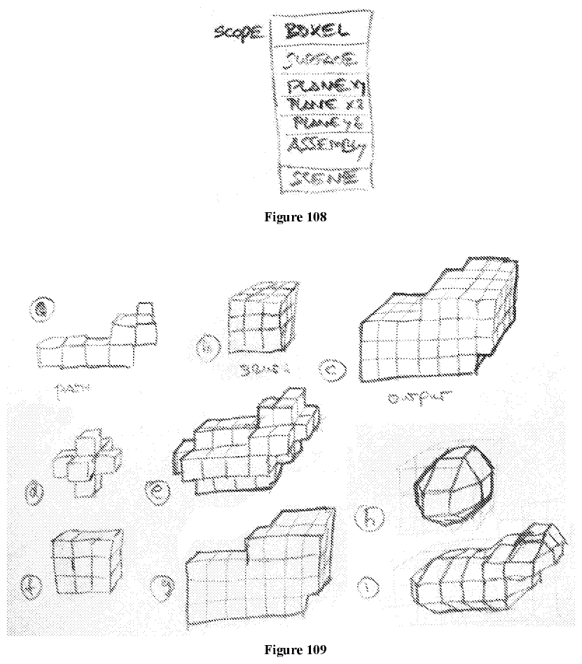

(f) When brush scope has been selected, subsequent operations will affect the boxel/connector pointed to, as well as additional boxels in its immediate vicinity. Which boxels are affected is defined by a brush, which users typically select before performing the operation. FIG. 109 is a diagram illustrating example brushes for boxels according to some embodiments. (a) When this 3×3×3 boxel brush has been selected, all subsequent operations will affect the boxel pointed to and its immediate neighbors in eight-connectivity. (b) When this 3D-+-shaped brush has been selected, all subsequent operations will affect the boxel pointed to and its immediate neighbors in four-connectivity. (c) When this 3D—3×3×1 brush has been selected, all subsequent operations will affect the boxel pointed to and its immediate neighbors in eight-connectivity located in the same plane. (d) When this 3×3×3 shaped brush with rounded corners has been selected, all subsequent operations affect the boxel pointed to and its immediate neighbors in eight-connectivity, albeit the neighbors located at a diagonal will be affected to a lesser extent. (Other embodiments may use reduced opacity instead of rounding to illustrate boxels affected to a lesser extent).

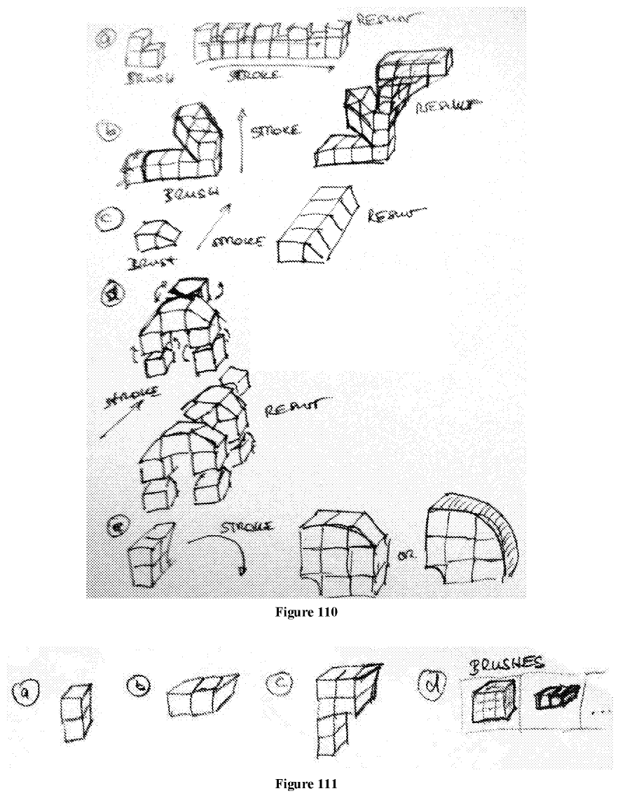

In the examples shown in FIG. 109, embodiments created the resulting boxel assemblies by creating a first copy of the brush at the starting location, then moving the brush by one pixel in some direction, then uniting the current assembly with another copy of the brush placed there, and so on. As illustrated by FIG. 110, which is a diagram illustrating some further example brushes for boxels according to some embodiments, however, the offsets between copies of the brush may be larger than a pixel and they may involve rotations in between as well. (a) Example of a brush that is moved by more than a single boxel per unit length of path, (b) asymmetric brushes, (c) brushes that deposit boxels patterns across the cross section of the path, (d) patterns also along the length of the path, such as a static geometry from regular boxels, combined with robot legs (see below), (e) a truss with hollow spaces, etc.

Different embodiments of the system 100 may use different ways of offering brushes to the user, e.g., in menus of sorts that contains swatches each of which represents a brush.

Different embodiments of the system 100 may include different ways for defining a brush. Simpler embodiments may allow users to generate a brush by defining a small number of parameters, e.g., radius in boxels, roundness, i.e., whether boxels in the perimeter are automatically rounded etc. Some embodiments of the system 100 may allow users to enter these parameters using a collection of GUI widgets, such as combo boxes, numerical text entry field, sliders, etc.

FIG. 111 is a diagram illustrating an alternative workflow for creating brushes according to some embodiments: it allows users to use the editor itself to produce custom brushes. (a) Assembly to be modified on the left and assembly to be used as brush on the right. (b) The user picks use as brush and points to the right assembly. (c) The subsequent add boxel operation on the left assembly now adds multiple boxels at once. (d) If an assembly is expected to be used as a brush repeatedly, users may prefer to define it as a brush, making it available in a brushes menu of sorts that the respective embodiment may offer to users.

While it is conceivable to apply add boxel on a brush by indeed stacking the brush geometry onto the assembly pointed to it may not always produce the best results. The interaction shown in FIG. 111 therefore uses a different interaction mode in which only some reference boxel, typically in the center of the brush is stacked onto the assembly pointed to and then the rest of the brush is merged with the assembly my merging brush boxels with base assembly boxels on a boxel-by-boxel basis. This particular interaction uses such a reference boxel to be defined before the operation. While some embodiments may allow users to select the reference boxel manually, other embodiments of the system 100 determine the reference boxel automatically, e.g., the boxel closest to the center of bounding box or center of mass of the brush. To avoid confusion, some embodiments of the system 100 may therefore require brushes to have odd dimensions.

In addition, some embodiments of the system 100 may allow annotating brushes with additional parameters. A defined front boxel allows tools to rotate the brush during use so as to always have the front facing forward during a stroke/drag interaction or when tracing a path. This allows creating well-defined effects at the beginning and end of such paths.

Some embodiments of the system 100 may instead or in addition achieve a similar effect by offering a convolve tool. We can use FIG. 111 to illustrate it. The user picks the convolve tool, then the assembly shown in (b) and then applies it to the assembly shown in (a). This would produce the top half of the assembly shown in (c).

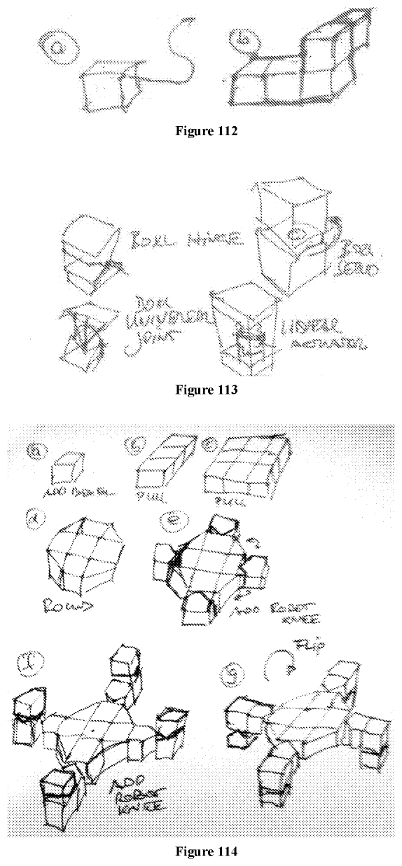

As illustrated by FIG. 112, which is a diagram illustrating adding boxels entering a path according to some embodiments, some embodiments of the system 100 include tools that allow adding multiple boxels in the form of a “painting-like” interaction. (a) The user applies the tool to a connector of an assembly, and (b) interactively draws a path that is covered with boxels, typically while it is being created. 3D or better input devices allow creating such a 3D path in one go. 2D input devices can be used to define a 2D path in a given plane; someone skilled in the art will also know how to obtain a 3D path from a 2D input device, e.g., by interpreting movement parallel to edges going into the depth of the image as a movement in that direction. While the shown example starts by attaching to an existing assembly, embodiments may also allow starting from scratch.

There are many different ways for covering a path with boxels, such as Bresenham's line algorithm and its large number of variants. Preferably, we would pick a variant that results in a path of boxels connected under 4-connectivity, i.e., so that each boxel except the first and last have at least one of their up/down/left/right/front/back neighbors as predecessor and one as successor, which prevents the fabricated result from falling apart. Other embodiments use algorithms from 2D or 3D painting programs. Some embodiments may also allow stroking the path with a brush, using all the concepts disclosed earlier.

### 5.8.2. Using Boxels to Wrap Functionality

The boxel concept offers an excellent mechanism for users to add functionality to their assemblies. As illustrated by FIG. 113, which is a diagram illustrating mechanical boxels according to some embodiments, one approach is to wrap mechanisms specialized boxels, such as (a) a hinge, (b) servo motor, (c) a universal joint, (d) a linear actuator, and the same concept allows wrapping screws, and any other type of mechanism or component. Some of these boxels may be implemented completely by the respective fabrication device; others may include foreign components, such as metal screws or hinged. Some functional boxels may occupy a single boxel only while others may fill multiple boxels or a fraction thereof.

FIG. 114 is a diagram illustrating a boxel-based workflow that results in turtle-like robot according to some embodiments. It uses two servomotor-actuated hinges, here referred to as robot knees.

As illustrated by FIG. 115, which is a diagram illustrating electronic boxels according to some embodiments, functional boxels may also wrap electronics, such as (a) power supplies, here batteries, (b) actuators, here an LED, (c) microcontrollers, (d) sensors, here a photo sensor, (e and f) electric connections, such as cables or busses, (g) plugs, and so on.

Unlike traditional construction kits that out electronics in boxes, most embodiments of the present invention will optimize boxels for the context of their current assembly before fabricating them. For example, as already mentioned boxels will generally not be fabricated as individual boxes, but as an assembly where only the outer walls will be produced. Also, a cubic battery boxel may deliver electricity to any of six neighbors; when fabricated, however, only those connectors will be executed that do actually connect to something. Also, some embodiments may hint at the presence of electric connectors between boxels during editing, yet run a single long cable pair through many boxels when fabricating, thus leaving out any electric plugs that users may assume to connect boxels (the same way that many embodiments will leave out the center walls between two boxels). Similarly, boxels may offer optional axles that only manifest themselves if something is connected to them.

FIG. 116 is a diagram illustrating electronic boxels according to some embodiments. The figure shows even more boxels that wrap (a) DC motors, (b) gear boxes, (c) bevel gears (or any other, (d) wheels, (e) omniwheels, (f) solenoids

Note that many boxels refer to an abstract concept, rather than to a specific implementation. Many embodiments will prefer this approach because (1) the actual implementation may not be of importance to the users, so leaving out the detail may make for a cleaner user interface.

The same concept also holds for decorative boxels, such as boxels engraved with the depiction of one or more eyes, boxel with engraved patterns, boxels with cut patterns, etc.

Specific applications tend to be based on certain characteristic sets of boxels and optionally other assemblies, which we call boxel kits. FIG. 119 shows one way of offering boxel kits, by placing them on stage. While some of the boxel assemblies may be individual boxels, commonly kits would also contain multiple boxel assemblies consisting of enough boxels etc. so as to fulfil some of the functionalities the kit is trying to enable. The boxel kit shown in FIG. 119, for example, was designed with the objective to enable users to create walking robots of various shapes. Consequently, the kit offers a few types of robotic platforms, two types of arms, two types of tails, and a few heads, allowing users to create a decent number of different robots walking robots by merely combining the offered boxel assemblies in a “Mr. Potatoe”-like fashion. At the same time, users can personalize their creations by adding any number of non-premade assemblies or even to ignore the affordance of the kit and create their entire robot creature from scratch.

Mirrors: In order to allow users to design even faster, many embodiments tend to include components that help user replicate similar structures quickly. FIG. 117 shows a particular easy-to-use approach. (a) This Cartesian mirror boxel will replicate anything connected to one side on the other side. This particular boxel shows this to the user by rendering a (e.g., may be translucent, may be partly reflective) sheet onto the symmetry plane, so as to reach a little bit past the boxels it affects; other embodiments may use different visual cues. (b) A diagonal mirror boxel works similarly to the Cartesian mirror, except it does so at an angle. (c) Mirror boxels may contain multiple mirrors. This one contains two and produces three copies of the original geometry. This boxel may be offered as is by the system and/or the system may allow users to create it by embedding a diagonal mirror boxel into one that already contains a diagonal mirror boxel. (d) Two mirrors embedded at a 45 degree angle with respect to each other produce seven copies. This particular mirror boxel could be offered as is and/or, for example, be produced by embedding cartesian and diagonal mirrors into a single boxel. (e) Unlike the mirror boxels shows so far, this mirror boxel features a mirror aligned with one of its connectors, resulting in “even” boxel assemblies, i.e., assemblies without a boxel in the center. (f) Boxels may offer mirrors along/across any dimension. (g) If mirrors are placed into a geometry featuring local neighbors in the plane of the mirror, most embodiments will extend the mirror to cut across everything crossing the plane (i.e., mirrors here actually represent an infinite plane, independent of the fact that a particular embodiment may choose to visualize them as patches of finite size).

Some embodiments may choose to consider one side of the mirror at the original and one as the copy. They proceed by deleting everything on the copy side and replacing it with a (mirrored) copy of the original side. In order to eliminate the need for users to make this choice, many embodiments will bypass this decision by instead considering both sides “original”, i.e., mirror both sides to the other side and uniting with any geometry present there.

Some tools may execute the functionality of mirror boxels only once, typically at the moment the boxel is added or embedded. Such immediate tools create the copy, unite it with the assembly, (optionally show some brief (visual) explanation of what took place, e.g., by flashing the mirror plane) and be done. Changes applied to the assembly at a later point will then typically not be mirrored/may require embedding the mirror boxel again in order to update the sides. In contrast, the mirror boxels added or embedded using persistent tools stay in the assembly (often including their visualization), so that geometry added later will appear on all sides of the mirror at once.

Some embodiments of the system 100 allow manipulating mirror just like any other part of geometry, some even with the same tools, such as moving mirrors, rotating them, or even bending mirrors. At the same time, some embodiments of the system 100 may include a good selection of different predefined mirror boxels to cover a wide range of cases without requiring such tweaking.

Different embodiments of the system 100 may choose different ways of implementing mirror boxels. Those built on a scene graph model (FIG. 129) may create the copies produced by a mirror by simply adding a copy (for immediate tools) or symbolic links (for persistent tools) to the geometry on the other side and a transform node representing the nature of the mirror operation. If geometries existed on both sides, such systems may add a union operator that combines the two geometries or compute the geometry during insertion.

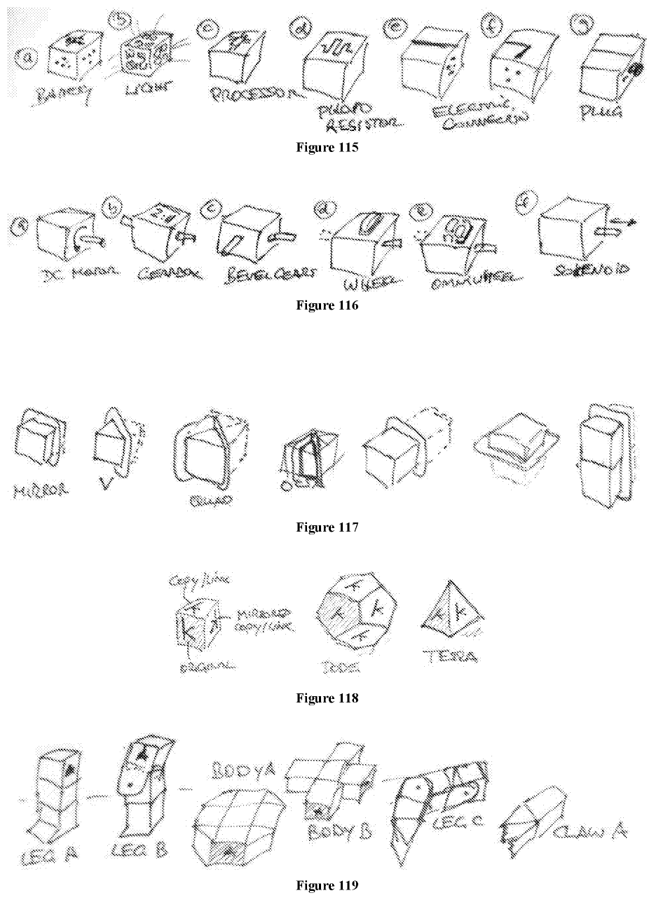

Some embodiments will push the concept of copies/symbolic links further by extending the metaphor of a mirror to something more like what might be called a portal. As illustrated by FIG. 118, this lower abstraction layer deals with connectors, rather than boxels. (a) This example cubic boxel has one original connector, here visualized as a hatched surface, and one or more clone connectors, here shown with a white background. The shown design will cause copies of anything connected to the original connector to also appear at the clone connectors. Furthermore, connectors may be marked with icons to represent the transformation the cloned geometry will undergo, such as translation, rotation, scale, skew, affine transformations, homographies, etc. Here this icon is a lowercase “k”, but it could also be a 3D object or assembly that illustrates the transformation or some other description of the transformation. The clone connector on top, for example, produces a mere rotation, while the clone connector on the right also mirrors, as illustrated by the mirrored ‘k’. (b) The concept (like all of the concepts above) applies to arbitrary geometries. Attaching an LED boxel to the original connector of this dodecahedron, for example, will create a lamp with twelve LEDs. (c) The same applies to any other geometry, here a tetrahedron.

If multiple different originals should be used, a different icon should be used for each. Along the lines of what we said about computing unions earlier, the portal-based approach also works without a dedicated original connector, i.e., all connectors belonging to the same set then bear the same type of icon without any specific one being highlighted. Here, users may connect geometry to any connector and it will simply appear on all other sides in the respective orientation.

Connector-based symmetry tools can be implemented just like what we discussed for mirrors, i.e., by adding copies and/or symbolic links and transform nodes into the scene graph.

The approach of placing and transforming labeled connectors can be used to implement new symmetry tools and boxels, including the mirror tools discussed earlier. Some embodiments may offer tools that allow users to start with any assembly that features two or more connectors, place (2D or 3D) ‘icons’ onto at least two of the connectors and transform from. The result may then be stored, shared, and used as a new type of mirror “boxel” (with optional visual effects added for illustration). In particular, all of the mirror boxels shown in FIG. 117 can be produced this way.

Two or more mirrors generally lead to a series of infinite reflections, thus an infinite amount of geometry may be produced. Infinite geometry is generally not tractable. However, there are special cases where systems can handle this case. With the mirror boxels shown in FIG. 117, for example, this conceptually also takes place; however, for the shown examples, subsequent reflections spatially coincide with already existing geometry, thus eliminating the need to consider any subsequent copies.

Another approach to handling infinite reflections is to scale down subsequent copies, so that the scale of new geometry quickly drops below a threshold and can be eliminated from further processing. The result is fractals—a useful approach to creating complex geometry quickly. In some embodiments, the system 100 may include fractals by using boxels or other assemblies bearing connectors, with the icons on the clone connectors being scaled down.

Another approach is to limit geometry generation by (manually) adding a maximum recursion depth. Instead of this (recursive) approach to generating geometry, we may also generate geometry using an iterative approach, e.g., clone boxels that produce a defined number of copies.

Another approach is to create clones until the generated geometry spatially collides with some end boxel. This allows users to control the generation of boxels, e.g., by creating infinite geometry, and then embedding an end boxel into it. By allowing users to tweak the end boxel, we can allow users to tween boxels, i.e., to create a sequence of boxels the tweaked parameter(s) of which form some sort of interpolation from clone boxel to end boxel.

Some embodiments of the system 100 help users create objects for a known specific purpose by offering collections of predefined assemblies, which we call building blocks into what we call kits. FIG. 119 shows an example kit designed to help users create walking robotic creatures. This particular kit consists of boxel-based building blocks, but would not have to. As typical, this kit contains multiple building blocks and in particular multiple building blocks of multiple types (three legs, two bodies, and one claw) in a way that building blocks of different types can be combined to form an object in a “Mr. PotatoHead” style. Here users may combine legs with bodies; additional robotic creatures may be given claws. While not every building block may be compatible with every other building blocks and while users may have to make some of what they need themselves (here the arms to hold the claws), a kit will typically allow creating an exponential number of objects, here at least number of legs x number of bodies.

To help users figure out how to proceed, building blocks may bear pairs of (2D or 3D) ‘icons’ conceptually similar to the ones we discussed in the context of clone connectors. These icons are hints to the user that suggest how building blocks can/should be connected. The two legs to the left of FIG. 119, for example, each show icons in the form of an ‘A’, while the two robot bodies in the center show the counterpart versions of that ‘A’, suggesting that either leg can be attached to either body at any of the shown positions.

The orientation of the ‘A’ furthermore defines a suggested transformation under which the legs should be mounted. Here these icons make sure that all legs will attach to the body in the same “downwards” orientation. However, icons can do more in that they may specify any of the transformations discussed earlier, such as translation, rotation, scale, skew, affine transformations, homographies, etc. Scale, for example, could be used to make legs shrink automatically when mounted to a small body or for robotic creatures with smaller front legs.

This particular example chooses a symmetric icon; this makes sense in the context of leg C, which is functionally symmetric along this dimension. With respect to legs A and B this could be improved by using an asymmetric icon, which would then also give legs a default orientation, so that some of the leg would be mirrored automatically when mounted to as to all (roughly) face the same direction.

Icons serve two purposes, i.e., first, to inform users about suggested options and second, to help mount building blocks. The latter is particularly useful on systems operated using low DoF input devices, where the icons can take care of what might otherwise require substantial tweaking. Still, icons define defaults only—intended to serve as suggestions, so that users may tweak the transformations of building blocks after mounting. Also, most embodiments will allow users to add or embed building blocks anywhere else as well, so as to produce an even larger set of choices.

Some embodiments may clone building blocks automatically when added to an assembly to as to always have a spare building blocks at hand; others may expect users to do this manually.

The icons on building blocks can be implemented similarly to how clone connectors can be implemented and again icons define the default transformation. Similarly, building blocks may be copied or linked, causing subsequent operations to one leg to affect to just affect this one leg or all legs of this type.

One approach to creating kits is to allow users to simply create a scene consisting of multiple assemblies, optionally placing groups of icons onto connectors, and to save the scene.

Ultimately, specialized boxels are just special cases of building blocks and can be handled the same way. To make their use predictable, embodiments may want to make sure specialized boxels are mounted in a standardized way, such as in an orientation making whichever side is considered “functional” to face away from the side mounted, which also assures that the functional side is visible afterwards, etc. This can be accomplished by having boxel designers place ‘icons’ (as described above) onto their creations. During these are then places onto a default corresponding icon that is (automatically) placed on the clicked/tapped connector. If the user should be dissatisfied with this orientation, appropriate tools allow users to rotate boxels afterwards.

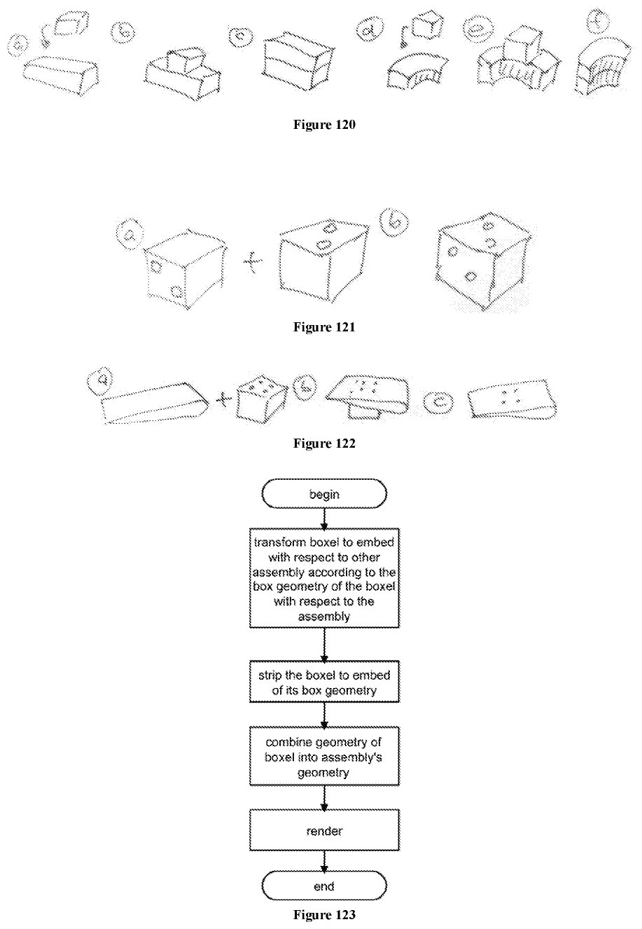

As shown in FIG. 120, when (a) mounting boxels components into distorted boxel assemblies, such as a stretched assembly, (b) some boxel component will remain non-stretched, and will position themselves inside the boxel, e.g., by centering, (c) others will stretched accordingly. (d) When embedded into a curved space, (e) some will remain straight and simply merge as such with the connector, (f) while others will curve accordingly. Yet others will refuse being mounted. To achieve the correct behavior, the creator of the boxel component may classify a boxel component as stretchable and/or bendable, may define upper and lower bounds for maximum stretch and bent, default layout rules inside the bent geometry.

Often times, a single boxel may be enough to offer multiple functionalities (as long as these do not physically collide). Of course it is possible to offer such compound functional boxels, e.g., a boxel that contains two servo motors. Since this tends to lead to an exponential inflation in the number of specialized boxels offered to the user, some embodiments will allow users to combine the functionality of two boxels into one instead. As illustrated by FIG. 121, (a) the left boxel already contains a two-magnet magnet connector. (b) Instead of using an add boxel tool, the user here uses an embed boxel tool, which merges the functionality of the new boxel with the functionality already present in the boxel in the base assembly, resulting in a boxel with magnet connectors on two sides.

Boxel embedding is a very powerful concept, because it elevates the concept of boxels from a rather specific construction kit to a general way of wrapping components, i.e., a way of implementing the aforementioned smart components. To allow boxels to play the role of generic smart components, the respective embodiments embed boxels, such that they first strip the embedded boxel of the “blank” boxel it is built on, and then embedding only what is left over, i.e., the functional geometry. When embedding into a boxel this makes no difference as the boxel geometry of the embedded boxel would not add anything when combining both blank boxels by, for example, computing their union. When embedding into the surface of a non-boxel assembly, however, stripping the embedded boxel of its box geometry is useful, because it prevents the box geometry from sticking out the resulting assembly. FIG. 122 is a diagram illustrating embedding a boxel into non-boxel geometry according to some embodiments. Here a four-magnet connector is embed into the underside of an airplane wing. (b) While uniting the geometry of the boxel with the assembly might cause the boxel to stick out, (c) reducing the boxel to its non-box geometry causes it to embed itself just like a regular smart component. FIG. 123 shows the corresponding algorithm.

How the algorithm combines geometry depends on the underlying implementation of the boxel. Boxels may, for example, maintain one data structure to hold additive geometry (such as an stl file that shows the appearance of the boxel), in which case the additive geometries of both boxels would be combined (e.g., by performing a Union/OR of their geometries). Similarly, the algorithm would unity the subtractive geometries of both boxels, such as to create the necessary cut outs for both functionalities.

Defining the smart component as a boxel in the first place is useful for two reasons. First, it allows instantiating its contents on its own, i.e. it allows placing the smart component into the scene by itself, because it now has its own assembly; by itself, the four magnet smart component would fall apart. This matters, for example, when we want to offer smart components as part of kits. Second, the blank boxel serves as geometric reference. By embedding into a boxel, the creator of the boxel demonstrates how to translate, rotate, tilt, etc. with respect to at least this one standard geometry. This defines a default transform note that can often be applied as is when embedding,

This approach also makes it easy to define functional boxels. Users simply embed their functional contents into a default boxel, optionally place icons to define how the component is to be mounted to other boxels, and invoke some make boxel function that groups the result into a boxel and/or stores it as a single boxel.

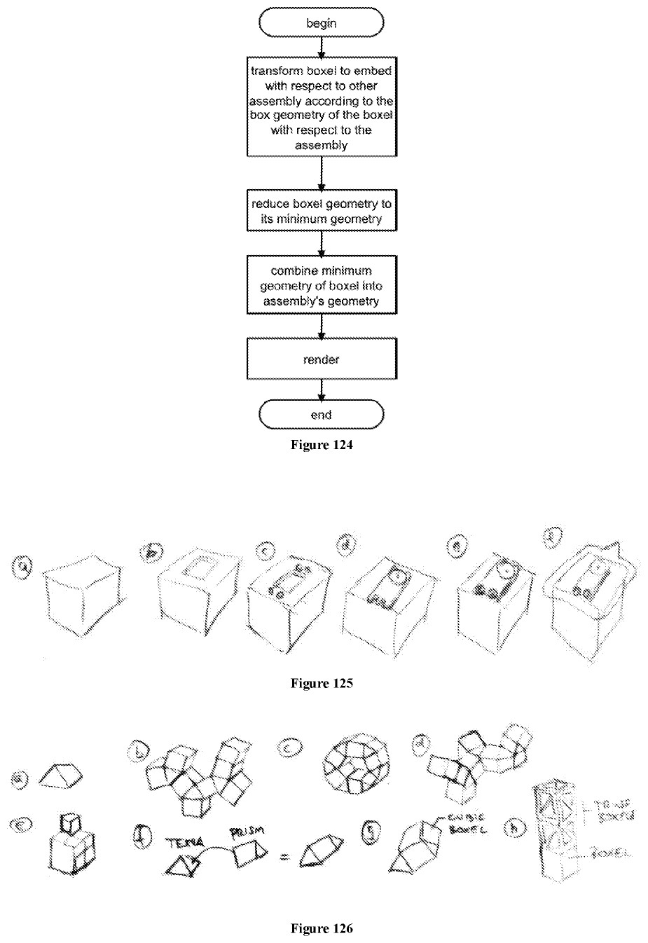

FIG. 123 is a process flow diagram illustrating the operation of embedding a boxel according to some embodiments. The algorithm assumes that all parts of the smart components are mounted to a single connector and that the assembly to embed into offers a solid plate. In various embodiments, the boxel engine 26 and the rendering engine performs some or all of the process flow. At 10801, the 3D editor 100 positions the boxel to be embedding into another boxel according to the box geometry of the boxel to be embedded. At 10802, the 3D editor 100 strips the box geometry of the boxel to be embedded. At 10804, the 3D editor 100 combines the box geometry of the boxel to be embedded into the box geometry of the other boxel. At 10804, the 3D editor 100 renders the scene with the embedded boxel therein. For cases where this is not the case, it may be necessary to merge some of the boxel's geometry into the assembly as shown in FIG. 124, which is a process flow diagram illustrating the operation of embedding a boxel according to some embodiments. The minimal geometry may be defined manually by the creator of the boxel or automatic by routing the bosses/mounts/fixtures of the functional components to the top plate and creating plates along these routes. In various embodiments, the boxel engine 26 and the rendering engine performs some or all of the process flow. At 10901, the 3D editor 100 transforms the boxel to be embedded with response to another assembly according to the box geometry of the boxel with respect of the assembly. At 10902, the 3D editor 100 reduces the box geometry to its minimum geometry. At 10904, the 3D editor 100 combines the minimum geometry of the boxel to the geometry of the assembly. At 10904, the 3D editor 100 renders the scene with the embedded boxel therein.

Finally, some embodiments of the system 100 will implement the approach discussed above not based on boxels, but based on connectors, i.e., users create afunctional connector, by embedding into a connector-shaped plate, embedding the functional connector into an assembly produces largely the same effect. However, adding the functional connector to the scene plate being added to the scene.

The system 100 may offer a large number of such specialized boxel components. Many embodiments will therefore choose to handle these boxels not as part of the core system but as add-ons that can be added, modifying, and deleted without recompiling or redeploying the core system. These are referred to as boxel assets. Assets can be stored in modular and easy-to-modify ways, e.g., as combinations of graphics, mark-up, and code, etc. and they can typically be loaded dynamically on demand and if properly indexed they can be searched.

There are many ways to construct or allow users to construct boxel assets. FIG. 125 is a diagram illustrating the construction of boxel assets according to some embodiment. (a) The user has created a boxel assembly (or one that the system can automatically convert or subdivide into boxels, e.g., a single box). Here just a simple box. (b-e) The user modifies at least one of the boxels, here by cutting an opening for the servo, openings for the screws, placing the servomotor, and attaching it using screws. (f). (f) Now the user applies a make this a boxel tool to the boxel containing the servomotor. This causes the system 100 to extract all relevant information from the boxel—in the shown example, this would include the servomotor, i.e., its 3D model, ability to move, animation sequences, links to code to drive the motor, model number for part list export, etc. and its relative position within the boxel, resulting cutout required to for the servo to be mounted, etc. The system 100 accomplishes this efficiently by simply exporting the scene graph of this boxel (assuming the servomotor is itself a smart component; otherwise, users may need to enter that information for the servo motor by hand, retrieve it from on online library, etc). The make this a boxel tools of some embodiments guess which connector is of relevance; others require users to manually enter this information, e.g., by placing a highlight (such as the shown frame with tip) around the main connector, here the upwards facing connector. The system 100 may now annotate the asset file further with additional meta information, such as creation date/time and the ID of the user who created it and it may or may not offer a dialog that allows users to add additional meta information, such as to name the newly created asset and to add a description and/or search terms.

The asset may now be stored in a file system or asset database, shared, indexed, searched for, and most of all inserted into other 3D scenes, where it can now help users construct quickly.

### 5.8.3. Breaking the Raster

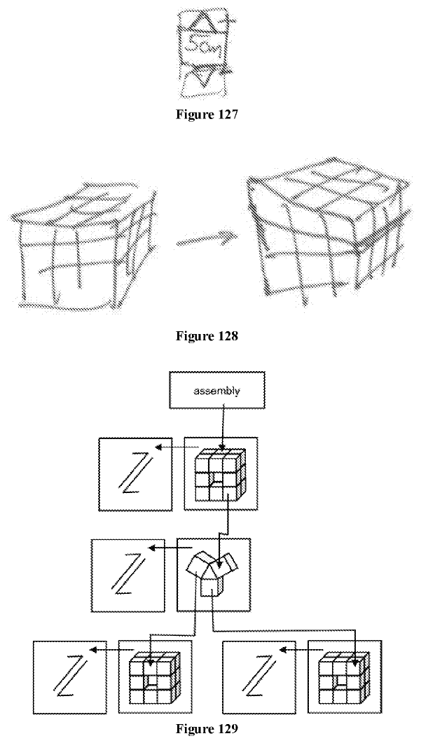

While most boxels fit into one grid, i.e., they simply continue the coordinate system they fit into, some embodiments may (also) offer boxels that deliberately break with the raster. This allows users to generate specific 3D structures, and generally break out of the raster paradigm instead implement aspects of vector-based/beam-based construction. FIG. 126 shows examples. (a) This prism-shaped boxel offers three rectangular connectors (as well as two triangular ones) and can serve as a bifurcation, allowing users to construct (b) tree structures. (c)) It also allows users to construct rings or (d) graph structures in 3D. (e) The two-scale boxel at the bottom offers connectors of two different sizes, here allowing users to connect half-scale boxels. (f) Connecting a prism to an element of a tetro/octa honeycomb, (here a tetrahedron boxel) allows subassemblies based on cubic boxels to connect to subassemblues based on tetro/octa honeycomb. (g) This truss voxel allows users to construct trusses efficiently.

FIG. 127 is a diagram illustrating building with boxels of different sizes according to some embodiments. Picking boxels of appropriate size is subject to a tradeoff, in that larger boxels allow for more efficient building and also allow embedding larger elements, such as servomotors, while smaller boxels allow representing additional detail. Consequently, many embodiments of the system 100 allow users to configure the size of the boxels used. This can be accomplished in a number of ways, including a simple graphical user interface, such as the one shown in FIG. 127a. The shown GUI element may, for example, be configured to allows doubling boxel size, cutting it in half, or entering a new boxel in some scale dimension, here centimeters. This dialog may for example be used for regular cubic or tetra/octahedral boxels; other boxels would use appropriate and typically more complex dialogs. After this dialog has been operated, new boxels subsequently placed into empty space will be of the entered size. When building by attaching boxels to an existing boxel assembly, different embodiments may offer different strategies, including the ones listed in the section where we talk about adding boxels to non-boxel geometry; in addition, some embodiments may offer the option to switch the default boxel size automatically (back) to the size of the base geometry currently built on.

Mixing boxels of different sizes allows creating structures of varying level of detail, thereby combining the benefits of small and large boxels, i.e., speed and detail. One possible approach is to combine boxels the sizes of which form a geometric row, i.e., boxels measuring 1×1×1 of some unit, ½×½×½ units, and so on, as this allows creating structures shaped like octrees (FIG. 127b).

As illustrated by FIG. 127c, some embodiments offer efficient subdivide/upsample tools and merge/down-sample tools that allow adjusting the level of detail in an assembly locally. One way of applying this is by brushing over a subassembly with a volumetric brush, which replaces affected boxels with larger of or smaller boxels.

FIG. 127c illustrates a generalization of a scale tool, e.g., a version of a push/pull brush tool. Rather than addressing a single boxel, this tool is configured to represent a certain brush (e.g., brush diameter, intensity, and hardness, i.e., how quickly intensity fades towards the perimeter) and now addresses all boxels brushed over by the respective intensity. Especially in assemblies where space has been subdivided multiple times and/or in an irregular fashion, this tool helps users sculpt efficiently and in an interaction style known from software tools, such as zBrush.

FIGS. 127d and e illustrate scale assembly tools. Finally, embodiments may also offer tools that allow entire assemblies to be scaled. Scale by resampling tools may accomplish this by maintaining boxel sizes and instead resampling the assembly, while scale by scaling boxel tools may maintain the number and configuration of boxels by simply scaling all boxels (and other geometry) inside the assembly.

### 5.8.4. Combining Boxel and Non-Boxel Assemblies and Tools

The most common workflow involving boxels is such that users start by designing their overall geometry using boxels—as this is very fast, and then refine the resulting geometry. This workflow is already supported by the above description of how to create a boxel assembly from scratch and in that the other tools discussed earlier do not mind if the assembly manipulated consists of boxels.

The challenge thus is how to continue applying boxel tools to a boxel assembly after it has been processed using non-boxel tools (or how to even to assemblies created entirely using non-boxel tools). (Another reasons for enabling this is that it allows using the same tools for boxel and non-boxel assemblies, resulting in a simpler user interface than if all tools have be offered as generic and boxel-specific tools.)

If the existing base assembly offer a connector matching the boxel to be added (e.g., a plate of the right size in the case of cubic boxels), the add boxel tool can simply apply to it and this connector thereby defines the coordinate system/grid for all subsequent boxel operations branching off it.

Otherwise, the existing base assembly does not offer a matching connector, i.e., there is a mismatch between the coordinate system/grid required by the boxel to be added and coordinate system/grid suggested by the base assembly. Embodiments may handle this situation by supporting one or more of the following approaches.

First approach: butt both coordinate system together. If the existing assembly offers a sub-assembly that generally allows mounting the boxel to be added, yet leaves one or more dimensions of how exactly to do it undefined, most embodiments will allow their users to still perform the operation by guessing the underdetermined parameters based on analyzing the base assembly or by reverting to default values, such as to center the added boxel, etc. Users may correct incorrect guesses or default values subsequently using appropriate tools, such as yaw tools and move tools.

For example, an embodiment may allow users to mount a cubic boxel to a large square plate, by rotating the boxel so as to align with the square plate in terms of yaw rotation. However, the exact position in terms of x/y translation of the boxel with respect to the large square plate would be unspecified. Some embodiments may here mount to a default position, such as the center of the plate or the position clicked or tapped by the user, etc., and users may tweak that position later.

Similarly, adding a cubic boxel to a round plate may leave (translation and) orientation unspecified. Again, the embodiment may pick a default (position and) orientation and users may tweak (position and) orientation manually afterwards.

Second approach: base coordinate system wins. In this approach, the system may modify the boxel to be added so as to fit the coordinate system defined by the connector of the base assembly. If the connector of the base geometry is a large square plate, the system may scale at least the two relevant dimensions of the boxel so as to fit that size (optionally also the third dimension, e.g., to preserve the boxel's aspect ratio, etc.). Following this approach, a user attempting to add a cube boxel to a round plate, may find the boxel morphed into the shape of an appropriately sized cylinder before mounted.

Third approach: boxel coordinate system wins. Change the geometry of the base assembly so as to fit the boxel. This is possible, but will probably find less application.

Finally, if the existing base assembly should not offer a connector and if even an improvised connection seems to result in a poor overall construction (e.g., arguably, mounting a cubic boxel to a living hinge base geometry) some embodiments will let the add boxel operation indeed fail (and instead prompt the users to first create some sort of connector). Other embodiments may go ahead adding the boxel by either automatically mounting a connector into the base geometry or by simply creating the poorly constructed connection (if only for the purpose of giving the user the chance to understand the issue, before undoing the operation, fixing the issue and redoing it).

### 5.8.5. Modifying Boxel Assemblies by Deforming the Grid

To allow users to continue applying boxels tools later on, some embodiments offer tools to address specific boxel subsets. FIG. 128 is a diagram illustrating a deformation of a boxel assembly according to some embodiments. As illustrated, for example, users may select a slice for a boxel assembly (here the middle slice) and then apply a push/pull edge tool, resulting in the system achieving the deformation by (preferably) modifying the selected boxels. In the shown example this results in the middle layer of boxels being deformed, while the layer above is being skewed. Had the middle layer not been selected, the system might have deployed some default strategy, such as to accomplish the deformation while minimizing the overall number of boxels affected (which would here have caused the top layer to deform). Based on the same strategy, the system may avoid deforming layers to which additional geometry is attached.

There are many different ways of storing boxel-based assemblies in computer memory. While it is possible to store boxels one at a time in an arbitrary data structure (array, list, look-up table, hash, scene graph, etc.) many embodiments will try to capture the overall structure of each assembly in order to achieve a data structure that makes it computationally inexpensive to modify large numbers of boxels at once.

One particularly efficient approach is shown in FIG. 129. This particular scene graph structure stores all boxels that fit on a single (regular or deformed) 3D grid in a 3D table or compatible data structure (array or arrays, arrays or arrays or arrays, hash etc.), here depicted as an icon on a 3×3×2 3D grid. To give this 3D grid additional flexibility, the scene graph allows combining 3D grid nodes with transform nodes (shown as double arrays icons, here pointed to by the 3D grid node, but someone skilled in the art will appreciate that there are other ways of combining nodes). Depending on embodiment, transform nodes may include linear transformations, affine transformations, homographies, non-linear transformations, etc. Some embodiments may also allow the transform to refer to individual subsets of rows, columns, etc., such as (some of these embodiment will instead or also allow for transform matrices in the 3D grid nodes that refer to rows, columns etc.).

(Many embodiments will choose to show boxel boundaries all the time or at least when the user has selected a boxel tool, as seeing boxel boundaries can help users make sense of the geometry and target the right connectors in subsequent operations. Some embodiments will offer the option to show the boxel grid in the fabricated result, e.g., by engraving otherwise invisible boxel boundaries.)

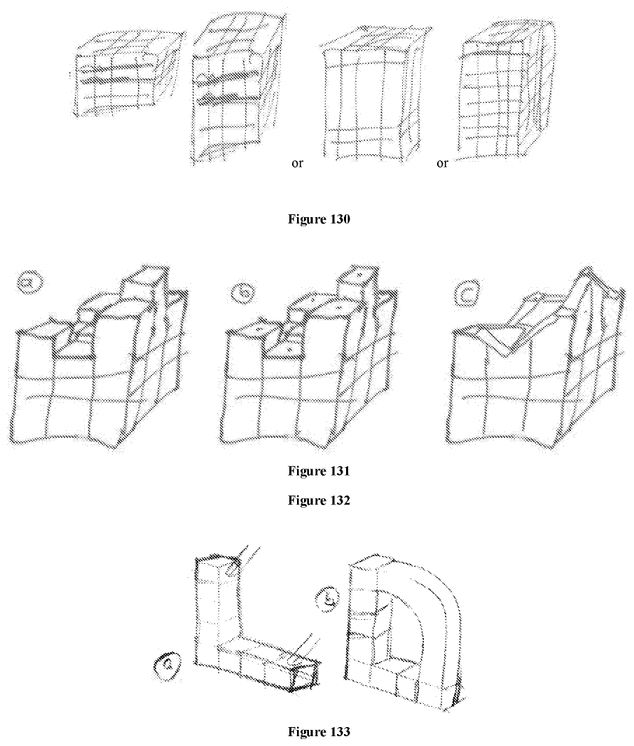

FIG. 130 is a diagram illustrating a deformation of a boxel assembly using a push/pull tool according to some embodiments. The Figure shows a similar example, except that this time a boxel layer is being stretched, e.g., using a push/pull tool (or any other tool that allows for such a deformation, such as handles, etc.). Different embodiments may choose different strategies. (a) The boxel assembly (in the shown case the second layer from the top was selected using an appropriate tool, but this really only matters for one of the subsequent cases). (b) All boxels are stretched by the same amount; this strategy has the benefit that all boxels are still identical to each other afterwards. (c) The system minimizes the number of boxels affected in order to maximize the number of boxels that maintain their original boxel properties. Here this means that only a subset of layers is being stretched (here the selected one; it could also be a layer chosen by the system), while the rest remains unchanged. (d) The system re-rasterizes the assembly into an appropriate number of boxels. If the final size does not correspond to an integer number of boxels, one layer (e.g., a layer (roughly) corresponding to the position of the previously selected one) will have a non-standard height. In order to help users avoid this case and generally achieve an integer number of boxels as a result, a properly chosen alignment aid may be applied, such as the aforementioned space curvature, which helps users achieve an integer number or a fractional number (without having to manually control any modes).

Boxels also allow users to sculpt terrain or entire 3D models based on a 2D or 3D raster. FIG. 131 is a diagram illustrating an example of creating a terrain according to some embodiments. (a) The user has already a 3×3×3 boxel assembly (e.g., by laying down a single boxel and then scaling it up one dimension at a time using a push-pull tool configured to apply to the entire assembly) and is now scaling individual boxels (e.g., by pulling handles attached to each boxel, by using a push-pull tool configured to apply to individual boxels, or by using a push/pull tool that applies to multiple adjacent boxels, e.g., specified by a 2D brush, etc.). The result is a block featuring some sort of discrete “elevation map”. Such maps can be used to sculpt a wide range of 2½D geometries, such as faces, etc. Some embodiments of the system 100 may apply an appropriate alignment method, such as space curvature, to make it easier to scale a boxel to integer lengths or to lengths already present in this assembly (especially length already present in the same row or column of the boxel assembly). This can help users construct well-defined structures, such as symmetric structures, etc. (b, c) If users prefer a smoother surface, they may apply an appropriate smoothing tool. In this example, the user invokes a smooth surface tool; there are many ways to implement such smoothing tools. The shown one determines the centers of the tops of boxel and interpolates linearly between them, resulting in top surface without discontinuities. Other smoothing tools may apply to subsets of boxels and may, for example, smooth the top surface by brushing across boxel tops.

Other smoothing tools may offer different types of smoothing operations, such as smooth curves in one dimension. Someone skilled in the art will appreciate that these can be implemented using Bezier or B-spline interpolation. On 2-3 axis subtractive machines, such as laser cutters, the result can be implemented, for example, using long strips of living hinges. Other smoothing tools may locally subdivide boxels into smaller and smaller boxels, the length of which is determined by (linear, bilinear, bicubic, etc.) interpolation between the length of the original-size boxels. Yet other tools may smooth by interpolating in 2D, e.g., using NURBS. On 2-3 axis subtractive machines, such as laser cutters, the result can be implemented, for example, by placing a 2D-stretched (auxetic) façade over the top surface.

Many embodiments will allow users to edit smooth terrain structures as well, e.g., using the same modeling tools as before smoothing.

This sculpting process can be applied to multiple or even all sides of a boxel assembly, allowing users to sculpt 3D structures. Users may model an approximation of a sphere, for example, by starting with a multi-boxel cube and successively pulling out surface centers and pushing in corners.

### 5.8.6. Smoothing Boxels

Some embodiments may offer additional tools for shaping boxels, typically to shape the façade of a boxel assembly. FIG. 132 illustrates the use of a round tool according to some embodiments. (a) start with an arrangement of 3×3 boxels and remove the center boxel as demonstrated earlier. Brushing the perimeter of the assembly with the round tool causes all corner boxels along the tool's path to become “rounded”. In this first step, this may, for example, simply mean to replace the cube-shape boxel with one with a cut-off edge, i.e. a prism. The algorithm may determine this as follows: start drawing path. While drawing path: if crossing an edge of a boxel that is not shared with any other boxels (i.e., the algorithm has encountered an outside edge), round that edge by removing material ELSE if crossing an edge of a boxel that is shared with two neighboring boxels (i.e., the algorithm has encountered an inside edge) round that edge by adding material.

Brushing the perimeter again (c) causes the tool to implement the next level of roundness, here, for example, rounded corners implemented as living hinges.

Brushing the perimeter yet again (d) causes the tool to implement the yet next level of roundness, here, for example, rounded corners that start to cut into the immediately adjacent boxels along the edge. In the shown case this results in a cylindrical assembly, so no more rounding can be achieved and additional applications of the round tool would have no effect; for larger assemblies the process could be continued though.

Instead, brushing the surface on the inside of the assembly (e) causes the inside to be rounded (e.g. again using prisms then quarter circles, etc.)

Alternatively, clicking/tapping individual edges will round that particular edge (which most embodiments will implement by allowing users to click/tap close to the edge up to a Voronoi tessellation of the screen surface area of the assembly (and some surrounding blank space) into only edges)

Some embodiments of the system 100 simply increment some “roundness” counter associated with each boxel edge and look up an associated rounding style from an array, look-up table, or similar. In order to help users achieve a homogeneous look, other embodiments will offer tools that increment only the first boxel edge they encounter and will increment subsequent edges only if they that would get them to the same level of roundness as the first one (or, yet another version of the tool, if that gets them to the same or lower level of roundness).

What this particular round tool accomplished by means of multiple applications, other embodiments will accomplish with multiple tools, such as a separate miter edge tool, a rounded edge tool, and so on.

FIG. 132f (shown in top right) shows the use of an erode tool. Tapping a boxel surface one shortens the boxel by a certain amount. Most embodiments will offer versions of that tool that shorten the entire connected surface across neighboring boxels. Brushing can erode multiple boxels and that also modifies corner boxels along the way so as to keep the contour simple; here the inside of the boxel was brushed, causing the hole to grow. Not shown: the corresponding dilate tool performs the opposite of the erode tool.

The create bend tool allows creating curved sub-assemblies. As shown in FIG. 133 users pick two connectors and the tool computes a spline in between and traces it with the shape of a boxel.

The boxel clone tool is similar to the add boxel tool in that it allows adding additional boxels to an assembly. However, the boxel clone tool adds boxels of the type the user is building on, i.e., it proceeds as follows: user pointing input, determine which connector was clicked or tapped, determine the “reference” boxel the connector belongs to, determine the type of the reference boxel, create a new boxel of that type, give that new boxel the same orientation as the reference boxel, translate it so as to be adjacent to the clicked or tapped connector, attach the new boxel to the reference boxel. For asymmetric boxels, this may try to mount incompatible connector types to each other. To overcome this, the boxel clone tool may mirror the new boxel before attaching it. Clone boxel tools may support all the additional interactions discussed earlier, such as dragging, painting, or brushing. The clone tool thereby, to a certain extent, generalizes the concept of boxels in that it allows picking a wide range of assemblies and building with them in a boxel-like fashion.

Consequently the flowchart of the clone boxel tool is identical to add boxel tool, except that add boxed is replaced with clone boxel.

### 5.9. Repository and Workflow

The 3D editor 100 described above can be provided to the user in various forms and embodiments. The 3D editor 100 can be stand-alone or integrated into a system. The 3D editor 100 may be implemented in various forms, including, but not limited to a native application, a networked application, an app, a web app, etc. (when we say “app” we will refer to any of these.)

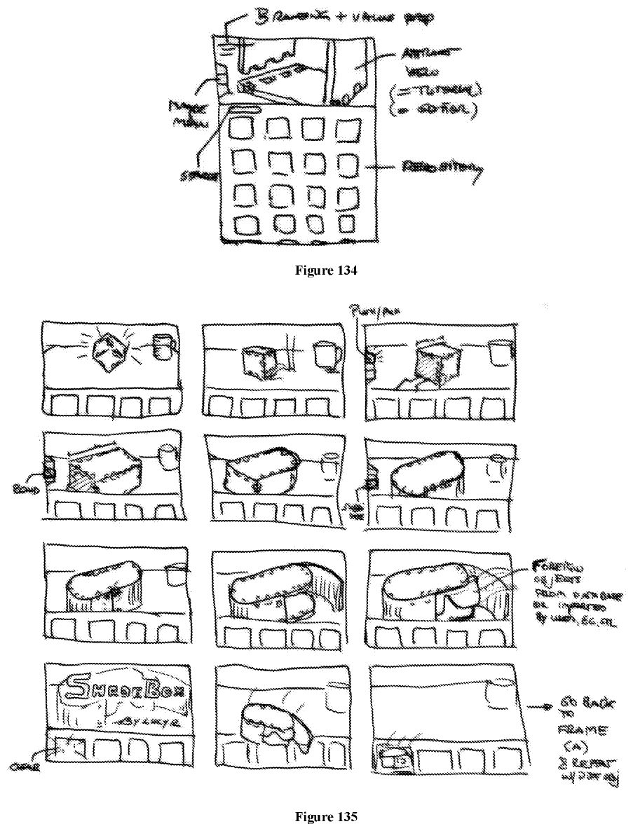

FIG. 134 is a user interface illustrating a web page of a 3D editor implemented as a web app according to some embodiments. This can, for example, be implemented using Javascript or Coffeescript (a language that compiles into JavaScript) based on webGL and Node.JS.

The shown embodiment integrates the editor with a central location in which 3D models are stored and managed (aka a repository). In this particular example, editor and repository may focus exclusively on specific types of models (e.g., 3D models) for a specific type of machine (such as 3-axis laser cutting of flat sheets), but other embodiments may offer different selections.

There are many ways how embodiments may integrate the editor into an app. The editor may be linked from the home/landing page, can be started from a menu, can be visible by default, and so on. The same holds for the repository, which may be linked from the home/landing page, can be started from a menu, can be visible by default, be invoked through a search function, and so on.

FIG. 134 shows one specific embodiment that features a detail view (which may or may not contain the editor) and an overview of multiple models (which may or may not provide access to the repository) on the home screen/landing page (it may contain any number of other elements). Here the detail view occupies the top part of the page and the overview part occupies the bottom, but this would not have to be this way (could be left vs. right, one inside the other, etc).

The detail view may perform one of several different routines featuring one or more models. FIG. 135 is a view of landing pages for detail views according to some embodiments. For example, the landing pages demonstrate how to create selected objects, here at the example of a laser-cut plywood box that allows keeping sunglasses. (a) A box is appears/is added, (b) here drops down, illustrating the physical nature of the view. (c) An editing function is invoked, here a push/pull tool to enlarge the box. (d) A rounding tool is selected and (e), (f) is applied to round the box. A split tool is selected, (g) cutting the front open, (h) causing the box to flip open because of the springiness of the living hinge element. (i) A pair of sunglasses animate into the box and (j) the result is labeled (k) and (l) and is stored into the overview/repository element on the page. At this point, this object has been completed and this or a different process may (re)start with the same or a different object.

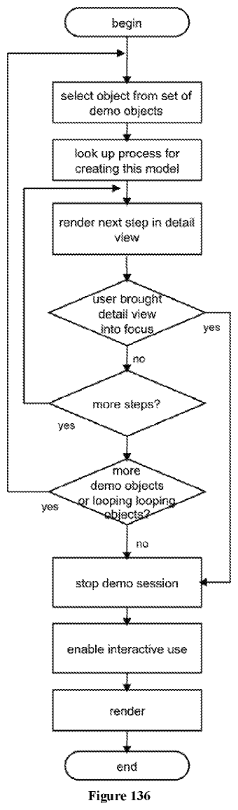

FIG. 136 is a process flow diagram illustrating a detail view operation according to some embodiments. In some embodiments, the view generating engine 32 and the rendering engine 24 performs some or all of the process flow. The “process for creating this model” may, for example, simply be recorded as a user creates this object in the editor in the first place. At 11701, 3D editor 100 receives an object selection from a set of demo objects. At 11702, 3D editor 100 looks up a process for creating the model. At 11703, 3D editor 100 renders the next step in a detail view. At 11704, 3D editor 100 determines whether the user has selected bringing the detail view into focus. If the determination at 11704 is the user has selected bringing the detail view into focus, 3D editor 100 stops at 11705 the demo session. At 11706, 3D editor 100 enables interactive use by the user. At 11707, 3D editor 100 renders the detail view scene. If the determination at 11704 is the user has not selected bringing the detail view into focus, 3D editor 100 determines at 11708 whether more steps are to be performed to bring the detail view into focus. If the determination at 11708 is that more steps are to be performed to bring the detail view into focus 11708, 3D editor 100 proceeds to render the next step at 11703. Otherwise, if the determination at 11708 is that more steps are not to be performed to bring the detail view into focus 11708, 3D editor 100 determines at 11709 whether there are more demo objects or looping objects for analysis. If the determination at 11709 is that there are more demo objects or looping objects for analysis, 3D editor 100 proceeds to select an object at 11701. Otherwise, if the determination at 11709 is that there are not more demo objects or looping objects for analysis, 3D editor 100 stops the demo at 11705 and proceeds accordingly.

This particular embodiment of the detail view may be used to perform some or all of the following functions (other embodiments may choose to perform this using multiple elements or implement only a subset). (1) Get users interested (in video games en.wikipedia.org/wiki/Glossary_of_video_game_terms, this is called attract mode). (2) Contents: over time it may show one or more actual models. (3) It teaches users the use of tools and how to create certain models. (4) It may serve as editor. If users bring the focus area into focus (e.g., move the pointer over the detail view area, or if users touch the detail view area, or they focus on the detail view in a virtual reality view, etc.) this embodiment may allow them to edit the model. In one embodiment, the action in the detail view may simply stop, allowing users to take it from there and make their own objects.

This particular embodiment also integrates the detail view (in particular the editor) with the overview (in particular the repository) in that users can transfer contents from one to the other. For example, the system 100 may allow users to select objects from the repository to be loaded into the detail view/editor. Selection may take place by clicking a model in the overview/repository, by tapping an associated button, by dragging it into the detail view, selecting a function from a menu, performing a gesture, etc. The loaded contents may replace the current contents or it may be added to the contents as additional contents, next to whatever is being worked on. Note how this also helps create content from multiple existing models (aka “remixing”), in that users may drag in multiple models to then assemble them or their parts into a new model.

Similarly, objects may move from the overview/repository into the detail view, e.g., to demonstrate this object and/or the editing process behind it.

Similarly, objects may move from the detail view to the overview, e.g., to offer one or more demonstrated objects to the user (as shown in FIG. 135).

Similarly, users may drag models from the 3D editor 100 into the repository. This may include models the users edit, i.e., new, original contents. When this happens, the system 100 may display the model in the overview (e.g., by moving existing contents aside or my removing a model from this view). The 3D editor 100 may also save the model more permanently, e.g., on the server with the other models or locally on the user's computer. As part of this the system 100 may ask the user to log in or create an account. (File formats may contain 3D geometry and/or 2D geometry and/or target machine-specific information; may be saved in the same file).

While the above illustrates this at the example of 3D models for laser cutting, the entire process around the home screen/landing page, detail view and overview may be performed with models for other fabrication processes and/or generic 3D editing.

When switching from an imported 2D layout, parts may animate towards their positions in the 3D model. Similarly, when exporting the 2D layout, parts may animate into their export layout.

### 5.10. System

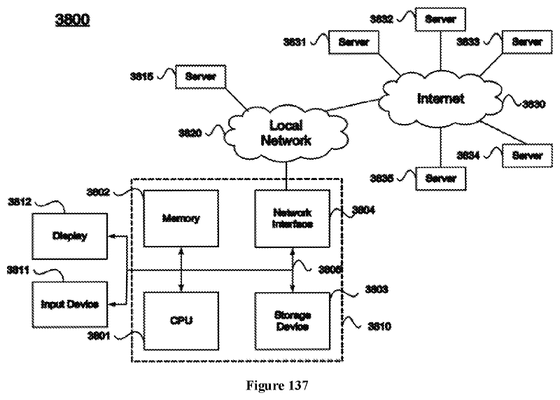

FIG. 137 illustrates hardware of a special-purpose computing machine configured with a process according to the above disclosure. The following hardware description is merely one example. It is to be understood that a variety of computers topologies may be used to implement the above described techniques. An example computer system 510 is illustrated in FIG. 5. Computer system 510 includes a bus 505 or other communication mechanism for communicating information, and one or more processor(s) 501 coupled with bus 505 for processing information. Computer system 510 also includes a memory 502 coupled to bus 505 for storing information and instructions to be executed by processor 501, including information and instructions for performing some of the techniques described above, for example. This memory may also be used for storing programs executed by processor 501. Possible implementations of this memory may be, but are not limited to, random access memory (RAM), read only memory (ROM), or both. A storage device 503 is also provided for storing information and instructions. Common forms of storage devices include, for example, a hard drive, a magnetic disk, an optical disk, a CD-ROM, a DVD, a flash or other non-volatile memory, a USB memory card, or any other medium from which a computer can read. Storage device 503 may include source code, binary code, or software files for performing the techniques above, for example. Storage device and memory are both examples of non-transitory computer readable storage mediums.

Computer system 510 may be coupled via bus 505 to a display 512 for displaying information to a computer user. An input device 511 such as a keyboard, touchscreen, and/or mouse is coupled to bus 505 for communicating information and command selections from the user to processor 501. The combination of these components allows the user to communicate with the system. In some systems, bus 505 represents multiple specialized buses, for example. The user may be, for example, the User or System Administrator.

Computer system 510 also includes a network interface 504 coupled with bus 505. Network interface 504 may provide two-way data communication between computer system 510 and a local network 520. The network interface 504 may be a wireless or wired connection, for example. Computer system 510 can send and receive information through the network interface 504 across a local area network, an Intranet, a cellular network, or the Internet, for example. One example implementation may include a browser executing on a computing system 510 that renders interactive presentations that integrate with remote server applications as described above. In the Internet example, a browser, for example, may access data and features on backend systems that may reside on multiple different hardware servers 531-535 across the network. Servers 531-535 and server applications may also reside in a cloud computing environment, for example. Servers 531-535 may execute the Algorithm and the 3D editor system 100 and store the associated code and the databases described above. Servers 531-535 may have a similar architecture as computing system 510.

Reference in the specification to “one embodiment”, “an embodiment”, “various embodiments” or “some embodiments” means that a particular feature, structure, or characteristic described in connection with these embodiments is included in at least one embodiment of the invention, and such references in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps (instructions) leading to a desired result. The steps are those requiring physical manipulations of physical quantities. Usually, though not necessarily, these quantities take the form of electrical, magnetic or optical signals capable of being stored, transferred, combined, compared and otherwise manipulated. It is convenient at times, principally for reasons of common usage, to refer to these signals as bits, values, elements, symbols, characters, terms, numbers, or the like. Furthermore, it is also convenient at times, to refer to certain arrangements of steps requiring physical manipulations of physical quantities as modules or code devices, without loss of generality.

However, all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system memories or registers or other such information storage, transmission or display devices.

Certain aspects of the present invention include process steps and instructions described herein in the form of an algorithm. It should be noted that the process steps and instructions of the present invention could be embodied in software, firmware or hardware, and when embodied in software, could be downloaded to reside on and be operated from different platforms used by a variety of operating systems.

The present invention also relates to an apparatus for performing the operations herein. This apparatus may be specially constructed for the required purposes, or it may comprise a general-purpose computer selectively activated or reconfigured by a computer program stored in the computer. Such a computer program may be stored in a non-transitory computer readable storage medium, such as, but is not limited to, any type of disk including magnetic memory, solid state memory, optical disks, CD-ROMs, magnetic-optical disks, randomly memories (ROMs), random access memories (RAMs), EPROMs, EEPROMs, magnetic or optical cards, application specific integrated circuits (ASICs), or any type of media suitable for storing electronic instructions, and each coupled to a computer system bus. Furthermore, the computers referred to in the specification may include a single processor or may be architectures employing multiple processor designs for increased computing capability.

The algorithms and displays presented herein are not inherently related to any particular computer or other apparatus. Various general-purpose systems may also be used with programs in accordance with the teachings herein, or it may prove convenient to construct more specialized apparatus to perform the required method steps. The required structure for a variety of these systems will appear from the description below. In addition, the present invention is not described with reference to any particular programming language. It will be appreciated that a variety of programming languages may be used to implement the teachings of the present invention as described herein, and any references below to specific languages are provided for disclosure of enablement and best mode of the present invention.

In addition, the language used in the specification has been principally selected for readability and instructional purposes, and may not have been selected to delineate or circumscribe the inventive subject matter. Accordingly, the disclosure of the present invention is intended to be illustrative, but not limiting, of the scope of the invention, which is set forth in the claims.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise. Also, as used in the description herein and throughout the claims that follow, the meaning of “on” includes “in” and “on” unless the context clearly dictates otherwise.

While particular embodiments and applications of the present invention have been illustrated and described herein, it is to be understood that the invention is not limited to the precise construction and components disclosed herein and that various modifications, changes, and variations may be made in the arrangement, operation, and details of the methods and apparatuses of the present invention without departing from the spirit and scope of the invention as it is defined in the appended claims.

All publications, patents, and patent applications cited herein are hereby incorporated by reference in their entirety for all purposes to the same extent as if each individual publication, patent, or patent application were specifically and individually indicated to be so incorporated by reference.

1. A method of editing 3D scenes comprising:
applying functions to one or more objects based on characteristics of the object and physics
applied to the objects; and
generating data of the objects for graphics editors after application of the functions.

2-151. (canceled)
